(19) United States
(12) Patent Application Publication
(10) Pub. No.: US 2025/0172872 A1
(43) Pub. Date: May 29, 2025

(54) CHEMICALLY AMPLIFIED POSITIVE-TYPE PHOTOSENSITIVE COMPOSITION, METHOD OF MANUFACTURING SUBSTRATE WITH TEMPLATE, AND METHOD OF MANUFACTURING PLATED ARTICLE

(71) Applicant: TOKYO OHKA KOGYO CO., LTD., Kawasaki-shi (JP)

(72) Inventors: Daisuke Ojima, Kawasaki-shi (JP); Yasushi Kuroiwa, Kawasaki-shi (JP)

(21) Appl. No.: 18/840,850

(22) PCT Filed: Jan. 24, 2023
(86) PCT No.: PCT/JP2023/002109

§ 371 Date: Aug. 22, 2024

(30) Foreign Application Priority Data
Feb. 24, 2022 (JP) 2022-027262
Jan. 13, 2023 (JP) 2023-003623

(51) Int. Cl. G03F 7/039; G03F 7/004; G03F 7/16

(52) U.S. Cl. CPC G03F 7/0392; G03F 7/0045; G03F 7/0048; G03F 7/168

(57) ABSTRACT

A chemically amplified positive-type photosensitive composition for forming a pattern serving as a template in a process of forming a plated article on a substrate having a metal layer on a surface thereof, the chemically amplified positive-type photosensitive composition being capable of easily forming a resist pattern having a cross-sectional shape in which a large undercut is formed and footing is suppressed. The chemically amplified positive-type photosensitive composition includes an acid generating agent that generates an acid by irradiation with an active ray or radiation, a resin having an alkali solubility that increases under action of an acid, a sulfur-containing compound containing a sulfur atom capable of coordinating with the metal layer, an acid diffusion suppressing agent, and an organic solvent, the resin containing an acrylic resin which contains a specific constituent unit, and the decomposition ratio (%) of the acid generating agent determined using specific steps is more than 0.5 and less than 10.

### TECHNICAL FIELD

The present invention relates to a chemically amplified positive-type photosensitive composition, a method of manufacturing a substrate with a template using the chemically amplified positive-type photosensitive composition and a method of manufacturing a plated article using the substrate with the template.

### BACKGROUND ART

Photofabrication is presently the mainstream of a microfabrication technique. Photofabrication is a generic term for a technology used for manufacturing a wide variety of precision components such as a semiconductor package by applying a photoresist composition to the surface of an article to be processed so as to form a photoresist layer, patterning the photoresist layer by a photolithographic technique and then performing, for example, electroforming based mainly on chemical etching, electrolytic etching or electroplating using the patterned photoresist layer (photoresist pattern) as a mask.

In recent years, as electronic devices have been downsized, high density packaging technologies on semiconductor packages have progressed, and thus packaging density has been developed based on multi-pin thin film packaging in packages, reduction of package sizes, two-dimensional packaging technologies in flip chip systems and three-dimensional packaging technologies. In these types of high density packaging techniques, as connection terminals, for example, protruding electrodes (mounting terminals) such as bumps which protrude on a package, metal posts which connect rewiring extended from a peripheral terminal on a wafer and the mounting terminals and the like are highly accurately arranged on the surface of a substrate.

A photoresist composition is used for the photofabrication as described above. As the photoresist composition, a chemically amplified photoresist composition containing an acid generating agent is known (see Patent Documents 1 and 2 and the like). In the chemically amplified photoresist composition, an acid is generated from the acid generating agent by irradiation (exposure). Heat treatment after exposure promotes diffusion of the generated acid. As a result, an acid-catalyzed reaction occurs in a base resin or the like in the composition, which changes alkali solubility of the composition.

Such a photoresist composition is used in the formation of a plated article, such as bumps, metal posts, and Cu rewiring, for example, by a plating process, in addition to patterned insulating film or formation of etching masks. Specifically, first, a photoresist layer having a desired film thickness is formed on a support such as a metal substrate (substrate having a metal layer on a surface thereof) by using a chemically amplified photoresist composition. The photoresist layer is then exposed through a predetermined mask pattern. The exposed photoresist layer is developed, and a portion to be filled with copper or the like by plating is selectively removed (detached). In this manner, a photoresist pattern to be used as a template for forming a plated article is formed. A conductor such as copper is embedded by plating in a portion (nonresist portion) of the template removed by development, and then a photoresist pattern around the portion is removed, whereby bumps, metal posts, and Cu rewirings can be formed.

### CITATION LIST

### Patent Document

Patent Document 1: Japanese Unexamined Patent Application, Publication No. H9-176112
Patent Document 2: Japanese Unexamined Patent Application, Publication No. H11-52562

### DISCLOSURE OF THE INVENTION

### Problems to be Solved by the Invention

After forming a plated article such as a bump, a metal post, or a wiring, the surface of the substrate is rinsed with a rinse solution, a gas is blown to the surface of the substrate for the purpose of drying or the like, a chemical treatment such as etching is performed, or a material for forming another member is applied or filled on the substrate for the purpose of providing the another member on the substrate. In this case, a load such as various types of force is applied to the plated article on the substrate. In particular, when a load is applied to a fine plated article, the plated article may collapse down. For this reason, it is desirable that the plated article is less likely to collapse even when a load applied to the plated article varies. That is, a plated article having an excellent collapse margin is desirable.

In order to form a plated article having an excellent collapse margin, it is conceivable to make the plated article have a footing shape, whereby the plated article is less likely to collapse. The phrase “a plated article has a footing shape” means that the plated article protrudes toward a region where the plated article is not formed on a contact surface between the plated article and the substrate. When a cross-sectional shape of a plated article is a footing shape, for example, a width of the plated article on a side (bottom) in contact with the substrate is wider than a width of the plated article on a side opposite (top) to the side in contact with the substrate. It is considered that the plated article is less likely to collapse when the plated article considerably protrudes into the region where the plated article is not formed, in other words, when the footing of the plated article is large. In order for the plated article to have a footing shape, it is desirable that a resist pattern (a resist portion 2 and a nonresist portion 3) serving as a template for the plated article have an undercut shape as shown in FIG. 1A. The phrase “a resist pattern has an undercut shape” means that the nonresist portion 3 of the resist pattern extends into the resist portion 2 on the front surface side of the substrate 1. When the cross-sectional shape of the resist pattern has an undercut shape, for example, a width of the resist portion 2 of the resist pattern on a side (bottom side) in contact with the substrate 1 is narrower than a width of the resist portion 2 on a side opposite (top side) to the side in contact with the substrate 1. As described above, it is considered that the footing of the plated article can be increased by increasing the degree to which the nonresist portion extends into the resist portion in a vicinity of the substrate surface, whereby the plated article can be made more unlikely to collapse. On the other hand, as shown in FIG. 1B, when “footing” in which the resist portion 2 protrudes toward the nonresist portion 3 side on the contact surface between the surface of the substrate 1 and the resist pattern occurs in the resist pattern serving as a template for a plated article, the plated article formed has an undercut shape, and thus the plated article is likely to collapse. The footing is a phenomenon in which the width of the bottom is narrower than the width of the top in the nonresist portion 3, for example. Further, as shown in FIG. 1C, even if the resist pattern has an undercut shape, when footing occurs in the resist pattern, the plated article formed is likely to collapse due to its cross-sectional shape. FIGS. 1A to 1C are view schematically showing a cross section of a resist pattern parallel to a thickness direction of a substrate. Therefore, in order to form a plated article which is less likely to collapse even when various types of force are applied and has an excellent collapse margin, it is desirable that a large undercut is formed and footing is suppressed, in the cross-sectional shape of the resist pattern serving as a template of a plated article.

However, it is often difficult to form a resist pattern having a cross-sectional shape in which a large undercut is formed and footing is suppressed when a conventionally known chemically amplified positive-type photoresist composition such as disclosed in Patent Documents 1 and 2, or the like is used.

The present invention has been made in view of the above problems, and an object of the present invention is to provide a chemically amplified positive-type photosensitive composition for forming a pattern serving as a template in a process of forming a plated article on a substrate having a metal layer on a surface thereof, the chemically amplified positive-type photosensitive composition being capable of easily forming a resist pattern having a cross-sectional shape in which a large undercut is formed and footing is suppressed; a method of manufacturing a substrate with a template by using the chemically amplified positive-type photosensitive composition; and a method of manufacturing a plated article using the substrate with a template.

### Means for Solving the Problems

As a result of intensive studies to achieve the object, the present inventors have found that the above problems can be solved by a chemically amplified positive-type photosensitive composition comprising: an acid generating agent (A) that generates an acid by irradiation with an active ray or radiation, a resin (B) having an alkali solubility that increases under action of an acid, a sulfur-containing compound (E) containing a sulfur atom capable of coordinating with a metal layer of a substrate, an acid diffusion suppressing agent (F), and an organic solvent(S); the resin (B) including an acrylic resin (B3) including the following specific constituent unit (B3-1); the chemically amplified positive-type photosensitive composition satisfying the following requirement 1, thereby completing the present invention. Specifically, the present invention provides the following.

### [Requirement 1]

A decomposition ratio (%) of the acid generating agent (A) determined by the following steps 1) to 4) is more than 0.5 and less than 10:
1) a resin film having a thickness of 8.5 μm is formed by applying the chemically amplified positive-type photosensitive composition to a substrate having a copper layer formed on a surface thereof by sputtering;
2) the substrate having the resin film formed thereon is heated at 140° C. for 300 seconds;
3) a part of the resin film after the heating is scraped off, the scraped off resin film is dissolved in propylene glycol monomethyl ether acetate (PM) so as to have a solid content concentration of 20% by mass, then acetonitrile having a mass 15 times the mass of the scraped off resin film is added, and a solution obtained by removing a precipitate is determined as a test liquid; and
4) the chemically amplified positive-type photosensitive composition is diluted with propylene glycol monomethyl ether acetate (PM) so as to have a solid content concentration of 20% by mass, then acetonitrile having a mass 15 times the mass of the solid content of the chemically amplified positive-type photosensitive composition is added, and a solution is obtained by removing a precipitate; the resulting solution and the test liquid are each analyzed by liquid chromatography to determine the decomposition ratio (%) of the acid generating agent (A) represented by the following formula (a):

$$decomposition ratio ( \% ) of acid generating agent ( A ) = ( 1 - ( x / y ) ) \times 100 \qquad ( a )$$

(in the formula (a), x is a content (% by mass) of the acid generating agent (A) in the resin film, and
y is a content (% by mass) of the acid generating agent (A) in the solid content of the chemically amplified positive-type photosensitive composition).

A first aspect of the present invention relates to a chemically amplified positive-type photosensitive composition for forming a pattern serving as a template for a process of forming a plated article on a substrate having a metal layer on a surface thereof. The composition includes: an acid generating agent (A) that generates an acid by irradiation with an active ray or radiation, a resin (B) having an alkali solubility that increases under action of an acid, a sulfur-containing compound (E) containing a sulfur atom capable of coordinating with the metal layer, an acid diffusion suppressing agent (E), and an organic solvent(S). The resin (B) includes an acrylic resin (B3), and the acrylic resin (B3) includes a constituent unit (B3-1) derived from an acid dissociable (meth)acrylic acid alicyclic ester. In the acid dissociable (meth)acrylic acid alicyclic ester, the alicyclic group includes a tertiary carbon atom as a ring constituent element, and the tertiary carbon atom of the alicyclic group is bonded to an oxygen atom other than carbonyl oxygen in an ester group in the acid dissociable (meth)acrylic acid alicyclic ester to form a C—O bond, and the following requirement 1 is satisfied:

[requirement 1]
a decomposition ratio (%) of the acid generating agent (A) determined by the following steps 1) to 4) is more than 0.5 and less than 10:
1) a resin film having a thickness of 8.5 μm is formed by applying the chemically amplified positive-type photosensitive composition to a substrate having a copper layer formed on a surface thereof by sputtering;
2) the substrate having the resin film formed thereon is heated at 140° C. for 300 seconds;
3) a part of the resin film after the heating is scraped off, the scraped off resin film is dissolved in propylene glycol monomethyl ether acetate (PM) so as to have a solid content concentration of 20% by mass, then acetonitrile having a mass 15 times the mass of the scraped off resin film is added, and a solution obtained by removing a precipitate is determined as a test liquid; and
4) the chemically amplified positive-type photosensitive composition is diluted with propylene glycol monomethyl ether acetate (PM) so as to have a solid content concentration of 20% by mass, then acetonitrile having a mass 15 times the mass of the solid content of the chemically amplified positive-type photosensitive composition is added thereto, and a solution is obtained by removing a precipitate; the resulting solution and the test liquid are each analyzed by liquid chromatography to determine the decomposition ratio (%) of the acid generating agent (A) represented by the following formula (a):

$$decomposition ratio ( \% ) of acid generating agent ( A ) = ( 1 - ( x / y ) ) \times 100 \qquad ( a )$$

(in the formula (a), x is a content (% by mass) of the acid generating agent (A) in the resin film, and
y is a content (% by mass) of the acid generating agent (A) in the solid content of the chemically amplified positive-type photosensitive composition).

A second aspect of the present invention relates to a method of manufacturing a substrate with a template. The method includes laminating the photosensitive layer including the chemically amplified positive-type photosensitive composition of the first aspect on the substrate having a metal layer on a surface thereof,
heating the photosensitive layer,
irradiating the heated photosensitive layer position-selectively with an active ray or radiation, and
developing the photosensitive layer after the irradiation to form a template having a pattern shape for forming a plated article.

A third aspect of the present invention relates to a method of manufacturing a plated article, including plating a substrate with a template produced according to the second aspect to form a plated article in the template.

### Effects of the Invention

According to the present invention, it is possible to provide a chemically amplified positive-type photosensitive composition for forming a resist pattern to serve as a template in a process of forming a plated article on a substrate having a metal layer on a surface thereof, the chemically amplified positive-type photosensitive composition being capable of easily forming a resist pattern having a cross-sectional shape in which a large undercut is formed and footing is suppressed on a substrate having a metal layer on a surface thereof; a method of manufacturing a substrate with a template by using the chemically amplified positive-type photosensitive composition, and a method of manufacturing a plated article using the substrate with a template.

### BRIEF DESCRIPTION OF THE DRAWINGS

FIGS. 1A to 1C are view schematically showing a cross section parallel to a thickness direction of a substrate of a resist pattern; and

FIGS. 2A to 2C are view schematically showing a cross section parallel to the thickness direction of the substrate, with regard to the resist pattern of which footing and undercut were observed with a scanning electron microscope in the Examples and the Comparative Examples.

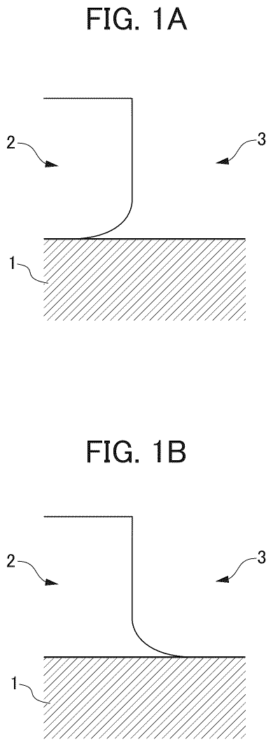

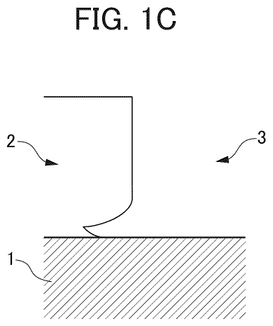

### PREFERRED MODE FOR CARRYING OUT THE INVENTION

### <<Chemically Amplified Positive-Type Photosensitive Composition>>

A chemically amplified positive-type photosensitive composition (hereinafter, also referred to as a photosensitive composition) is a chemically amplified positive-type photosensitive composition for forming a pattern to serve as a template in a process of forming a plated article on a substrate having a metal layer on a surface thereof. The photosensitive composition includes an acid generating agent that generates an acid by irradiation with an active ray or radiation (A) (hereinafter also referred to as an acid generating agent (A)), a resin having an alkali solubility that increases under action of an acid (B) (hereinafter also referred to as a resin (B)), a sulfur-containing compound containing a sulfur atom capable of coordinating with the metal layer (E) (hereinafter also referred to as a sulfur-containing compound (E)), an acid diffusion suppressing agent (F), and an organic solvent(S). The resin (B) includes an acrylic resin (B3). The acrylic resin (B3) includes a constituent unit (B3-1) derived from an acid dissociable (meth)acrylic acid alicyclic ester, and in the acid dissociable (meth)acrylic acid alicyclic ester, the alicyclic group contains a tertiary carbon atom as a ring constituent element, and the tertiary carbon atom of the alicyclic group is bonded to an oxygen atom other than carbonyl oxygen in an ester group in the acid dissociable (meth)acrylic acid alicyclic ester to form a C—O bond. The photosensitive composition satisfies the following requirement 1.

### [Requirement 1]

A decomposition ratio (%) of the acid generating agent (A) determined by the following steps 1) to 4) is more than 0.5 and less than 10;
1) a resin film having a thickness of 8.5 μm is formed by applying the chemically amplified positive-type photosensitive composition to a substrate having a copper layer formed on a surface thereof by sputtering;
2) the substrate having the resin film formed thereon is heated at 140° C. for 300 seconds;
3) a part of the resin film after the heating is scraped off, the scraped off resin film is dissolved in propylene glycol monomethyl ether acetate (PM) so as to have a solid content concentration of 20% by mass, then acetonitrile having a mass 15 times the mass of the scraped off resin film is added, and a solution obtained by removing a precipitate is determined as a test liquid; and
4) the chemically amplified positive-type photosensitive composition is diluted with propylene glycol monomethyl ether acetate (PM) so as to have a solid content concentration of 20% by mass, then acetonitrile having a mass 15 times the mass of the solid content of the chemically amplified positive-type photosensitive composition is added thereto, and a solution is obtained by removing a precipitate; the resulting solution and the test liquid (test solution) are each analyzed by liquid chromatography to determine the decomposition ratio (%) of the acid generating agent (A) represented by the following formula (a):

$$decomposition ratio ( \% ) of acid generating agent ( A ) = ( 1 - ( x / y ) ) \times 100 \qquad ( a )$$

(in the formula (a), x is a content (% by mass) of the acid generating agent (A) in the resin film, and
y is a content (% by mass) of the acid generating agent (A) in the solid content of the chemically amplified positive-type photosensitive composition).

By using such a photosensitive composition, as shown in the Examples described later, a resist pattern having a cross-sectional shape in which a large undercut is formed and footing is suppressed can be formed on a substrate having a metal layer on a surface thereof. The reason why a resist pattern having a cross-sectional shape in which a large undercut is formed and footing is suppressed can be formed on a substrate having a metal layer on a surface thereof is unclear, but it is presumed as follows. When a photosensitive layer formed on a substrate having a metal layer on a surface thereof using the above-described photosensitive composition having the above-described components and satisfying the requirement 1 is heated, the acid generating agent (A) reacts with the metal layer on the substrate surface to partially decompose and generate an acid, and this reaction is promoted by the acid diffusion suppressing agent (F). When this reaction occurs, the acrylic resin (B3) having the constituent unit (B3-1) derived from a specific acid-dissociable (meth)acrylic acid alicyclic ester has increased solubility in alkali, in the region near the substrate surface. Thereafter, the acid generating agent (A) is decomposed by exposure that generates an acid, whereby the acrylic resin (B3) having a constituent unit (B3-1) derived from a specific acid-dissociable (meth)acrylic acid alicyclic ester in the exposed portion has increased solubility in alkali. Therefore, in the resist pattern formed by the subsequent development, a nonresist portion greatly extends into the inside of a resist portion on the substrate surface side, which increases an undercut amount, resulting in large undercut. In addition, the photosensitive composition satisfying the above requirement 1 includes the sulfur-containing compound (E) containing a sulfur atom capable of coordinating with a metal layer of a substrate, in addition to the acrylic resin (B3) having a constituent unit (B3-1) derived from a specific acid dissociable (meth)acrylic acid alicyclic ester, whereby footing of the resist pattern can be suppressed, resulting in a resist pattern with no footing or with a small footing.

On the other hand, when the photosensitive composition that does not satisfy the requirement 1 is used, it is difficult to form a resist pattern having a cross-sectional shape in which a large undercut is formed and footing is suppressed. Specifically, it is the case where the following photosensitive composition is used: the photosensitive composition, in which the decomposition ratio (%) of the acid generating agent (A) in the requirement 1 is 0.5 or less or more than 10 and/or an acrylic resin (B3) having a constituent unit (B3-1) derived from a specific acid dissociable (meth)acrylic acid alicyclic ester is not contained. For example, when a photosensitive composition containing no acrylic resin (B3) having a constituent unit (B3-1) derived from a specific acid-dissociable (meth)acrylic acid alicyclic ester is used, the formed resist pattern is likely to cause footing and is unlikely to have an undercut shape. When a photosensitive composition in which the decomposition ratio (%) of the acid generating agent (A) of the requirement 1 is 0.5 or less is used, an undercut shape is unlikely to be formed. In addition, when a photosensitive composition having a decomposition ratio (%) of the acid generating agent (A) of the requirement 1 of 10 or more is used, pattern detaching occurs during development, and thus a resist pattern cannot be formed on the substrate having a metal layer on a surface thereof.

Here, the photosensitive composition satisfying the requirement 1 can be produced by adjusting types and blending amounts of the components (particularly, those of the acid generating agent (A), the resin (B), and the acid diffusion suppressing agent (F)). The decomposition ratio (%) of the acid generating agent (A) of the requirement 1 depends not only on the acid generating agent (A) contained in the photosensitive composition but also on the acid diffusion suppressing agent (F) and/or the resin (B). Specifically, for example, when an onium compound containing a sulfonium ion in which one or two alkyl groups are bonded to S⁺ as a cation moiety or a naphthalic acid derivative is used as the acid generating agent (A) and a basic compound containing a tertiary amine skeleton such as trialkylamine is used as the acid diffusion suppressing agent (F), the decomposition ratio (%) of the acid generating agent (A) in the requirement 1 can be easily made more than 0.5 and less than 10. For example, in the photosensitive composition, when a content of an onium compound containing a sulfonium ion in which one or two alkyl groups are bonded to S⁺ as cation moieties or a naphthalic acid derivative is increased, the decomposition ratio (%) of the acid generating agent (A) in the requirement 1 tends to increase, and when a content of a basic compound containing a tertiary amine skeleton such as trialkylamine is increased, the decomposition ratio (%) of the acid generating agent (A) in the requirement 1 tends to increase.

It is sufficient for the decomposition ratio (%) of the acid generating agent (A) of the requirement 1 to be more than 0.5 and less than 10, and the lower limit thereof is preferably 1 or more, more preferably 4 or more, and still more preferably 5 or more, and the upper limit thereof is preferably 9 or less, and more preferably 8 or less.

A thickness of the resist pattern formed using the photosensitive composition is not particularly limited. Specifically, a film thickness of the resist pattern formed using the photosensitive composition is preferably 0.5 μm or more, more preferably 0.5 μm or more and 300 μm or less, still more preferably 0.5 μm or more and 200 μm or less, and particularly preferably 0.5 μm or more and 150 μm or less. The upper limit of the film thickness may be, for example, 100 μm or less. The lower limit of the film thickness may be, for example, 1 μm or more, or 3 μm or more.

Hereinafter, essential or optional components included in the photosensitive composition and a method of manufacturing the photosensitive composition are described.

### <Acid Generating Agent (A)>

The acid generating agent (A) is not particularly limited as long as the photosensitive composition satisfies the above-described requirement 1. The acid generating agent (A) is a compound that generates an acid by irradiation with an active ray or radiation, and is a compound that generates an acid directly or indirectly by light. Examples of the acid generating agent (A) include the acid generating agents of the first to fifth aspects described below.

The first aspect of the acid generating agent (A) may be a compound represented by the following formula (a1).

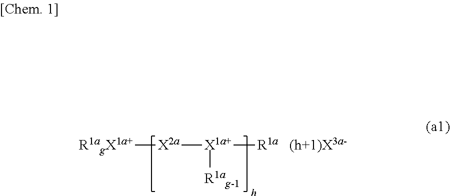

In the above formula (a1), X^{1a} represents a sulfur atom or iodine atom respectively having a valence of g, and g represents 1 or 2.

h represents the number of repeating units in the structure within parentheses. R^{1a} represents an organic group that is bonded to X^{1a}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms or an alkynyl group having 2 or more and 30 or less carbon atoms; and R^{1a} may be substituted with at least one selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group, and halogen atoms. The number of R^{1a}s is g+h(g−1)+1, and the Rias may be the same as or different from each other. Furthermore, two or more R^{1a}s may be bonded to each other directly or via −O—, —S—, —SO—, —SO₂—, —NH—, —NR^{2a}—, —CO—, —COO—, —CONH—, an alkylene group having 1 or more and 3 or less carbon atoms or a phenylene group, and may form a ring structure including X^{1a}. R^{2a} represents an alkyl group having 1 or more and 5 or less carbon atoms or an aryl group having 6 or more and 10 or less carbon atoms.

X^{2a} represents a structure represented by the following formula (a2).

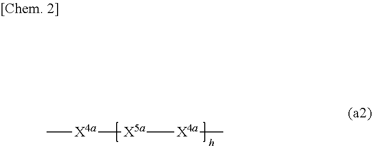

In the above formula (a2), X^{4a} represents an alkylene group having 1 or more and 8 or less carbon atoms, an arylene group having 6 or more and 20 or less carbon atoms or a divalent group of a heterocyclic compound having 8 or more and 20 or less carbon atoms; and X^{4a} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group, and halogen atoms. X^{5a} represents —O—, —S—, —SO—, —SO₂—, —NH—, —NR^{2a}—, —CO—, —COO—, —CONH—, an alkylene group having 1 or more and 3 or less carbon atoms or a phenylene group.

h represents the number of repeating units of the structure in parentheses. Examples of h include an integer of 0 or more. (h+1) X^{4a}s and (h) X^{5a}s may be identical to or different from each other. R^{2a} has the same definition as described above.

X^{3a-} represents a counterion of an onium, and examples thereof include a fluorinated alkylfluorophosphoric acid anion represented by the following formula (a17) or a borate anion represented by the following formula (a18).

[Chem. 3]

[(R^{3a})ⱼPF₆₋ⱼ]⁻ (a17)

In the above formula (a17), R^{3a} represents an alkyl group having 80% or more of the hydrogen atoms substituted by fluorine atoms.

j represents the number thereof and is an integer of 1 or more and 5 or less.

(j) R^{3a}s may be identical to or different from each other.

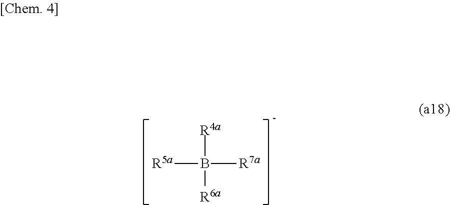

In the above formula (a18), R^{4a} to R^{7a} each independently represent a fluorine atom and a phenyl group, and part or all of the hydrogen atoms of the phenyl group may be substituted by at least one selected from the group consisting of a fluorine atom and a trifluoromethyl group.

Examples of the onium ion in the compound represented by the above formula (a1) include triphenylsulfonium, tri-p-tolylsulfonium, 4-(phenylthio)phenyldiphenylsulfonium, bis[4-(diphenylsulfonio)phenyl]sulfide, bis[4-{bis[4-(2-hydroxyethoxy)phenyl]sulfonio}phenyl]sulfide, bis{4-[bis(4-fluorophenyl)sulfonio]phenyl}sulfide, 4-(4-benzoyl-2-chlorophenylthio)phenylbis(4-fluorophenyl)sulfonium, 7-isopropyl-9-oxo-10-thia-9,10-dihydroanthran-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfonium, 2-naphthylmethyl(1-ethoxycarbonyl)ethylsulfonium, 4-hydroxyphenylmethylphenacylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, and the like.

Examples of the onium ion in the compound represented by the formula (a1) include a sulfonium ion represented by the following formula (a19). However, from the viewpoint of easily obtaining a photosensitive composition satisfying the requirement 1 described above, the photosensitive composition preferably contains, as the acid generating agent (A), a sulfonium ion represented by the following formula (a19) together with another acid generating agent, or does not contain the sulfonium ion represented by the following formula (a19).

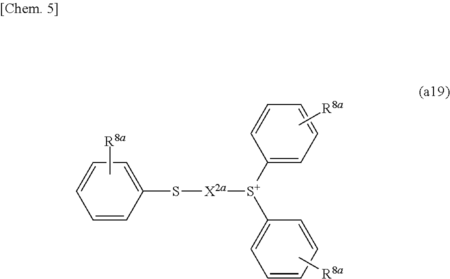

In the above formula (a19), R^{8a}s each independently represents a hydrogen atom or a group selected from the group consisting of alkyl, hydroxyl, alkoxy, alkylcarbonyl, alkylcarbonyloxy, alkyloxycarbonyl, a halogen atom, an aryl, which may be substituted, and arylcarbonyl. X^{2a} has the same definition as X^{2a} in the above formula (a1).

Specific examples of the sulfonium ion represented by the above formula (a19) include 4-(phenylthio)phenyldiphenylsulfonium, 4-(4-benzoyl-2-chlorophenylthio)phenylbis(4-fluorophenyl)sulfonium, 4-(4-benzoylphenylthio)phenyldiphenylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, diphenyl[4-(p-terphenylthio)phenyl]diphenylsulfonium, and the like.

In regard to the fluorinated alkylfluorophosphoric acid anion represented by the above formula (a17), R^{3a} represents an alkyl group substituted with a fluorine atom, a preferred number of carbon atoms is 1 or more and 8 or less and a more preferred number of carbon atoms is 1 or more and 4 or less. Specific examples of the alkyl group include: linear alkyl groups such as methyl, ethyl, propyl, butyl, pentyl and octyl; branched alkyl groups such as isopropyl, isobutyl, sec-butyl and tert-butyl; and furthermore, cycloalkyl groups such as cyclopropyl, cyclobutyl, cyclopentyl and cyclohexyl, and the proportion of hydrogen atoms substituted by fluorine atoms in the alkyl groups is normally 80% or more, is preferably 90% or more and is more preferably 100%. When the substitution rate of fluorine atoms is 80% or less, the acid strength of the onium fluorinated alkylfluorophosphate represented by the above formula (a1) is lowered.

A particularly preferred example of R^{3a} is a linear or branched perfluoroalkyl group having 1 or more and 4 or less carbon atoms and a substitution ratio of fluorine atoms of 100%, and specific examples thereof include CF₃, CF₃CF₂, (CF₃)₂CF, CF₃CF₂CF₂, CF₃CF₂CF₂CF₂, (CF₃)₂CFCF₂, CF₃CF₂ (CF₃)CF, and (CF₃)₃C.

j which is the number of R^{3a}s represents an integer of 1 or more and 5 or less, preferably represents an integer of 2 or more and 4 or less and particularly represents 2 or 3.

Preferred specific examples of the fluorinated alkylfluorophosphoric acid anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻ and [(CF₃CF₂CF₂)₃PF₃]⁻, and among them, [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻, and [((CF₃)₂CFCF₂)₂PF₄]⁻ are particularly preferable.

Preferred specific examples of the borate anion represented by the above formula (a18) include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl)borate ([(C₆F₅)₂BF₂]⁻), trifluoro(pentafluorophenyl)borate ([(C₆F₅)₂BF₃]⁻), and tetrakis(difluorophenyl)borate ([B(C₆H₃F₂)₄]⁻). Among these, tetrakis(pentafluorophenyl)borate ([B(C₆F₅)₄]⁻) is particularly preferable.

The second aspect of the acid generating agent (A) includes: halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy) styrylphenyl-s-triazine, 2,4-bis-trichloromethyl-6-(3-bromo-4-methoxy) styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine, and tris(2,3-dibromopropyl)-1,3,5-triazine; and halogen-containing triazine compounds represented by the following formula (a3) such as tris(2,3-dibromopropyl) isocyanurate.

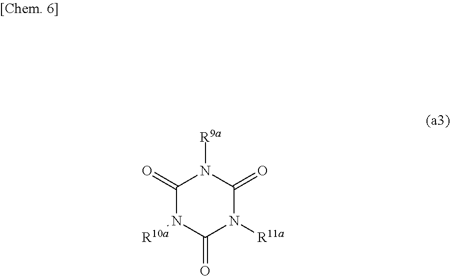

In the above formula (a3), R^{9a}, R^{10a} and R^{11a} each independently represent a halogenated alkyl group.

The third aspect of the acid generating agent (A) includes α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile, and α-(ethylsulfonyloxyimino)-1-cyclopentenylacetonitrile and compounds represented by the following formula (a4) containing an oximesulfonate group.

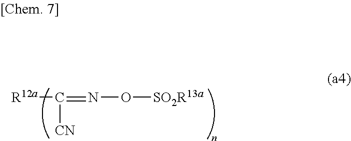

In the above formula (a4), R^{12a} represents a monovalent, bivalent or trivalent organic group, R^{13a} represents a substituted or unsubstituted saturated hydrocarbon group, an unsaturated hydrocarbon group, or an aromatic group, and n represents the number of repeating units of the structure in the parentheses.

In the above formula (a4), the aromatic group indicates a group of compounds having physical and chemical properties characteristic of aromatic compounds, and examples thereof include aryl groups such as a phenyl group and a naphthyl group and heteroaryl groups such as a furyl group and a thienyl group. These groups may have one or more appropriate substituents such as a halogen atom, an alkyl group, an alkoxy group and a nitro group on the rings. Furthermore, Ria is particularly preferably an alkyl group having 1 or more and 6 or less carbon atoms, and examples thereof include a methyl group, an ethyl group, a propyl group and a butyl group. In particular, compounds in which R^{12a} is an aromatic group and in which and Ria is an alkyl group having 1 or more and 4 or less carbon atoms are preferable.

Examples of the acid generating agent represented by the above formula (a4) include compounds in which R^{12a} is any one of a phenyl group, a methylphenyl group and a methoxyphenyl group, and in which Rule is a methyl group when n=1, and specific examples thereof include α-(methylsulfonyloxyimino)-1-phenylacetonitrile, α-(methylsulfonyloxyimino)-1-(p-methylphenyl) acetonitrile, α-(methylsulfonyloxyimino)-1-(p-methoxyphenyl) acetonitrile, [2-(propylsulfonyloxyimino)-2,3-dihydroxythiophene-3-ylidene] (o-tolyl) acetonitrile, and the like. Specifically, when n=2, the acid generating agent represented by the above formula (a4) is an acid generating agent represented by the following formulae.

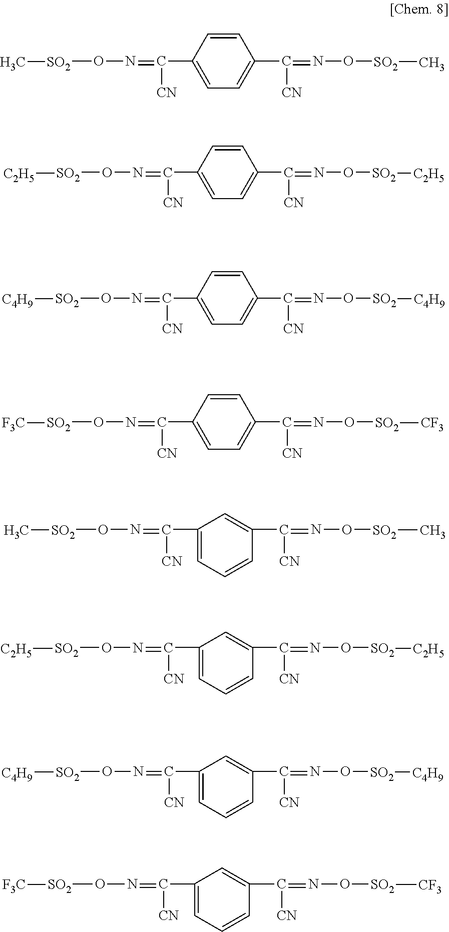

In addition, the fourth aspect of the acid generating agent (A) includes onium salts that have a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 or more and 6 or less carbon atoms, a hydroxyl group, and a linear or branched alkoxy group having 1 or more and 6 or less carbon atoms or the like. The structure derived from the naphthalene ring, which may be of a monovalent group (one free valence) or of a bivalent group (two free valences), is desirably of a monovalent group (in this regard, the number of free valences is counted except for the portions connecting with the substituents described above). The number of naphthalene rings is preferably 1 or more and 3 or less.

Preferably, the cation moiety of the onium salt having a naphthalene ring at the cation moiety is of the structure represented by the following formula (a5).

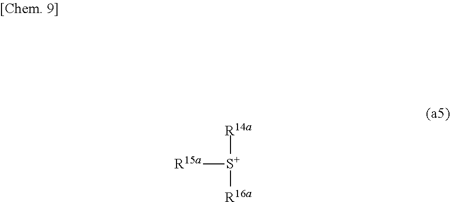

In the above formula (a5), at least one of R^{14a}, R^{15a} or R^{16a} represents a group represented by the following formula (a6), and the rest represent(s) a linear or branched alkyl group having 1 or more and 6 or less carbon atoms, at least a part of the hydrogen atoms of which may be substituted with a fluorine atom, a phenyl group which may have a substituent, a hydroxy group, or a linear or branched alkoxy group having 1 or more and 6 or less carbon atoms. Alternatively, one of R^{14a}, R^{15a}, or R^{16a} is a group represented by the following formula (a6), and the remaining two are each independently a linear or branched alkylene group having 1 or more and 6 or less carbon atoms, and ends of these may be bonded to form a ring.

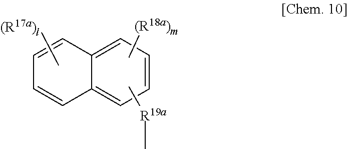

In the above formula (a6), R^{17a} and R^{18a} each independently represent a hydroxyl group, a linear or branched alkoxy group having 1 or more and 6 or less carbon atoms, or a linear or branched alkyl group having 1 or more and 6 or less carbon atoms, and R^{19a} represents a single bond or a linear or branched alkylene group having 1 or more and 6 or less carbon atoms that may have a substituent.

1 and m each independently represent an integer of 0 or more and 2 or less, and 1+m is 3 or less. In this regard, when there exists a plurality of R^{17a}, they may be the same as or different from each other. Furthermore, when there exists a plurality of R^{18a}, they may be the same as or different from each other.

Preferably, among R^{14a}, R^{15a} and R^{16a} as above, the number of groups represented by the above formula (a6) is one in view of the stability of the compound, and the remaining are linear or branched alkylene groups having 1 or more and 6 or less carbon atoms of which the terminals may bond to form a ring. In this case, the two alkylene groups described above form 3 or more and 9 or less membered rings including sulfur atom(s). Preferably, the number of atoms to form the ring (including sulfur atom) is 5 or more and 6 or less.

The substituent, which the alkylene group may have, is exemplified by an oxygen atom (in this case, a carbonyl group is formed together with a carbon atom that constitutes the alkylene group), a hydroxyl group or the like.

Alternatively, the substituent, which the phenyl group may have, is exemplified by a hydroxyl group, a linear or branched alkoxy groups having 1 or more and 6 or less carbon atoms, linear or branched alkyl groups having 1 or more and 6 or less carbon atoms, or the like.

Examples of suitable cation moiety include those represented by the following formulae (a7) and (a8), and in particular, the structure represented by the following formula (a8) is preferable.

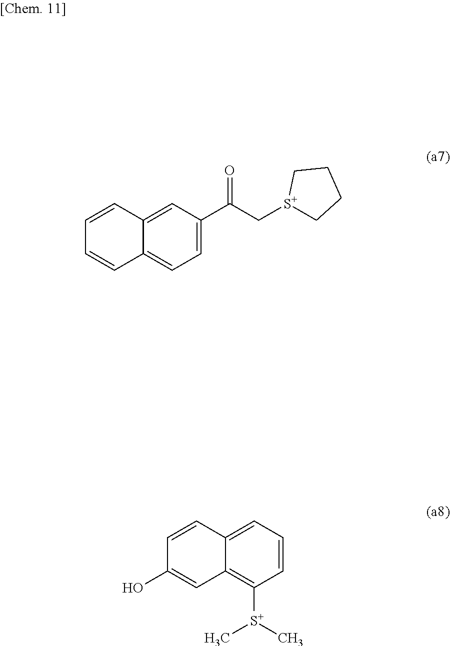 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in view of acid-producing efficiency.

Therefore, as a preferable example of the anion moiety of the onium salt having a naphthalene ring at the cation moiety, an anion capable of forming a sulfonium salt is preferable.

The anion moiety of the acid generating agent as described above is a fluoroalkylsulfonic acid ion or an aryl sulfonic acid ion in which part or all of hydrogen atoms are fluorinated.

The alkyl group of the fluoroalkylsulfonic acid ion may be a linear, branched or cyclic group having 1 or more and 20 or less carbon atoms, and preferably, the number of carbon atoms is 1 or more and 10 or less in view of bulkiness and diffusion distance of the produced acid. In particular, branched and cyclic groups are preferable due to shorter diffusion length. Also, methyl, ethyl, propyl, butyl, octyl groups and the like are preferable due to being inexpensively synthesizable.

The aryl group of the aryl sulfonic acid ion may be an aryl group having 6 or more and 20 or less carbon atoms, and is exemplified by a phenyl group or a naphthyl group that may not be substituted with an alkyl group or a halogen atom. In particular, aryl groups having 6 or more and 10 or less carbon atoms are preferred since they can be synthesized inexpensively. Specific examples thereof include phenyl, toluenesulfonyl, ethylphenyl, naphthyl, methylnaphthyl groups and the like.

When hydrogen atoms in the fluoroalkylsulfonic acid ion or the aryl sulfonic acid ion are partially or entirely substituted with a fluorine atom, the fluorination rate is preferably 10% or more and 100% or less, and more preferably 50% or more and 100% or less. It is particularly preferable that all hydrogen atoms are each substituted with a fluorine atom in view of higher acid strength. Specific examples thereof include trifluoromethane sulfonate, perfluorobutane sulfonate, perfluorooctane sulfonate, perfluorobenzene sulfonate, and the like.

Among these, the preferable anion moiety is exemplified by those represented by the following formula (a9).

[Chem. 12]

R^{20a}SO₃⁻ (a9)

In the above formula (a9), R^{20a} is a group represented by the following formulae (a10), (a11), or (a12).

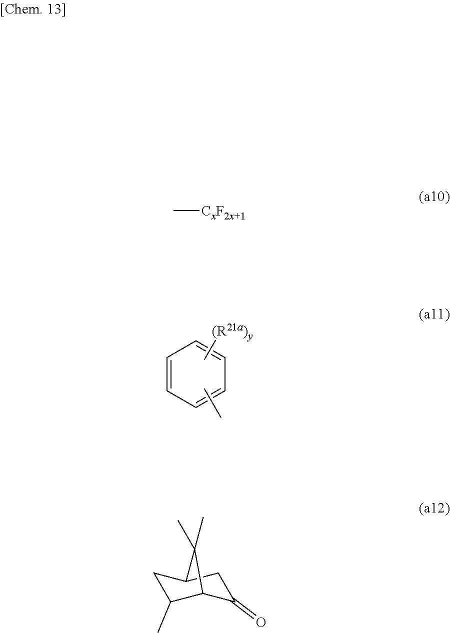

In the above formula (a10), x represents an integer of 1 or more and 4 or less. Also, in the above formula (all), R^{21a} represents a hydrogen atom, a hydroxyl group, a linear or branched alkyl group having 1 or more and 6 or less carbon atoms, or a linear or branched alkoxy group having 1 or more and 6 or less carbon atoms, and y represents an integer of 1 or more and 3 or less. Among these, trifluoromethane sulfonate and perfluorobutane sulfonate are preferable in view of safety.

In addition, a nitrogen-containing moiety represented by the following formulae (a13) or (a14) may be also be used for the anion moiety.

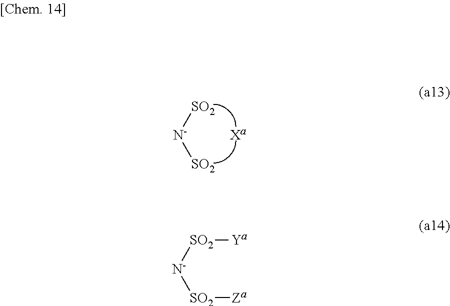

In the above formulae (a13) and (a14), X^{a} represents a linear or branched alkylene group in which at least one hydrogen atom is substituted with a fluorine atom, the number of carbon atoms of the alkylene group is 2 or more and 6 or less, is preferably 3 or more and 5 or less and is most preferably 3. In addition, Y^{a} and Z^{a} each independently represent a linear or branched alkyl group in which at least one hydrogen atom is substituted with a fluorine atom, the number of carbon atoms of the alkyl group is 1 or more and 10 or less, is preferably 1 or more and 7 or less and is more preferably 1 or more and 3 or less.

A smaller number of carbon atoms in the alkylene group of X^{a} or in the alkyl group of Y^{a} or Z^{a} is preferred since the solubility into an organic solvent is also favorable.

In addition, a larger number of hydrogen atoms each substituted by a fluorine atom in the alkylene group of X^{a} or in the alkyl group of Y^{a} or Z^{a} is preferred since the acid strength becomes greater. The percentage of fluorine atoms in the alkylene group or alkyl group, that is, the fluorination rate, is preferably 70% or more and 100% or less and is more preferably 90% or more and 100% or less, and a perfluoroalkylene group or a perfluoroalkyl group is most preferable in which all of the hydrogen atoms are substituted with fluorine atoms.

Preferable onium salts having a naphthalene ring at their cation moieties are exemplified by compounds represented by the following formulae (a15) or (a16).

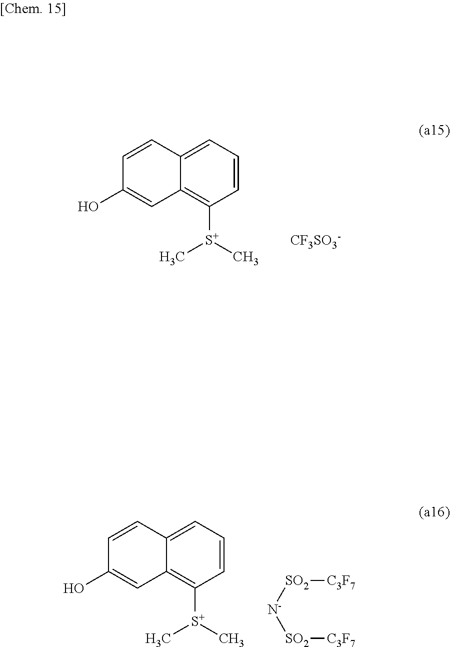

The fifth aspect of the acid generating agent (A) include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-(methylsulfonyloxy)succinimide, N-(trichloromethylsulfonyloxy)succinimide, N-(phenylsulfonyloxy)maleimide, and N-(methylsulfonyloxy)phthalimide; trifluoromethane sulfonates such as N-(trifluoromethylsulfonyloxy)phthalimide, N-(trifluoromethylsulfonyloxy)-4-phenylthiophthalimide, N-(trifluoromethylsulfonyloxy)-1,8-naphthalimide, N-(trifluoromethylsulfonyloxy)-4-butyl-1,8-naphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate, and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates; and the like.

Examples of the acid generating agent (A) include a naphthalic acid derivative represented by the following formula (a21):

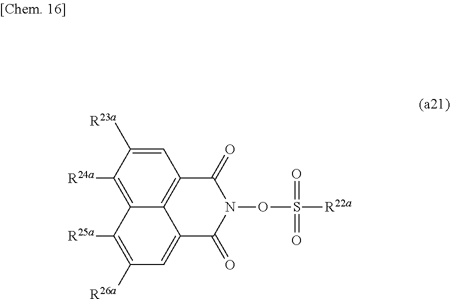

(in the formula (a21), R^{22a} represents a monovalent organic group, R^{23a}, R^{24a}, R^{25a} and R^{26a} each independently represent a hydrogen atom or a monovalent organic group and R^{23a} and R^{24a}, R^{24a} and R^{25a} or R^{25a} and R^{26a} may be bonded to each other to form a ring).

The organic group serving as R^{22a} is not particularly limited as long as the object of the present invention is not impaired. The organic group described above may be a hydrocarbon group and may include heteroatoms such as O, N, S, P and a halogen atom. The structure of the organic group may be linear, branched, cyclic or a combination of the structures thereof.

Preferred examples of the organic group serving as Raza include an aliphatic hydrocarbon group having 1 or more and 18 or less carbon atoms which may be substituted with a halogen atom and/or an alkylthio group, an aryl group having 6 or more and 20 or less carbon atoms which may have a substituent, an aralkyl group having 7 or more and 20 or less carbon atoms which may have a substituent, an alkyl aryl group having 7 or more and 20 or less carbon atoms which may have a substituent, a camphor-10-il group and a group represented by the following formula (a21a):

—R^{27a}—(O)ₐ—R^{28a}—(O)_{b}—Y¹—R^{29a} (a21a)

(in the formula (a21a), Y¹ represents a single bond or an alkanediyl group having 1 or more and 4 or less carbon atoms, R^{27a} and R^{23a} each represent an alkanediyl group having 2 or more and 6 or less carbon atoms which may be substituted with a halogen atom, or an arylene group having 6 or more and 20 or less carbon atoms which may be substituted with a halogen atom. R^{29a} represents an alkyl group having 1 or more and 18 or less carbon atoms which may be substituted with a halogen atom, an alicyclic hydrocarbon group having 3 or more and 12 or less carbon atoms, an aryl group having 6 or more and 20 or less carbon atoms which may be substituted with a halogen atom or an aralkyl group having 7 or more and 20 or less carbon atoms which may be substituted with a halogen atom. Each of a and b is 0 or 1 and at least one of a and b is 1).

When the organic group serving as R^{22a} has a halogen atom, examples of the halogen atom include a chlorine atom, a bromine atom, an iodine atom and a fluorine atom.

When the organic group serving as R^{22a} is an alkyl group having 1 or more and 18 or less carbon atoms substituted with an alkylthio group, the number of carbon atoms in the alkylthio group is preferably 1 or more and 18 or less. Examples of the alkylthio group having 1 or more and 18 or less carbon atoms include a methylthio group, an ethylthio group, an n-propylthio group, an isopropylthio group, an n-butylthio group, a sec-butylthio group, a tert-butylthio group, an isobutylthio group, an n-pentylthio group, an isopentylthio group, a tert-pentylthio group, an n-hexylthio group, an n-heptylthio group, an isoheptylthio group, a tert-heptylthio group, an n-octylthio group, an isooctylthio group, a tert-octylthio group, a 2-ethylhexylthio group, an n-nonylthio group, an n-decylthio group, an n-undecylthio group, an n-dodecylthio group, an n-tridecylthio group, an n-tetradecylthio group, an n-pentadecylthio group, an n-hexadecylthio group, an n-heptadecylthio group and an n-octadecylthio group.

When the organic group serving as R^{22a} is an aliphatic hydrocarbon group having 1 or more and 18 or less carbon atoms which may be substituted with a halogen atom and/or an alkylthio group, the aliphatic hydrocarbon group may include an unsaturated double bond. The structure of the aliphatic hydrocarbon group is not particularly limited and may be linear, branched, cyclic or a combination of the structures thereof.

Preferred examples when the organic group serving as R^{22a} is an alkenyl group include an allyl group and a 2-methyl-2-propenyl group.

Preferred examples when the organic group serving as R^{22a} is an alkyl group include a methyl group, an ethyl group, an n-propyl group, an isopropyl group, an n-butyl group, a sec-butyl group, a tert-butyl group, an isobutyl group, an n-pentyl group, an isopentyl group, a tert-pentyl group, an n-hexyl group, an n-hexane-2-yl group, an n-hexane-3-yl group, an n-heptyl group, an n-heptane-2-yl group, an n-heptane-3-yl group, an isoheptyl group, a tert-heptyl group, an n-octyl group, an isooctyl group, a tert-octyl group, a 2-ethylhexyl group, an n-nonyl group, an isononyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

When the organic group serving as R^{22a} is an alicyclic hydrocarbon group, examples of an alicyclic hydrocarbon constituting the main skeleton of the alicyclic hydrocarbon group include cyclopropane, cyclobutane, cyclopentane, cyclohexane, cycloheptane, cyclooctane, cyclodecane, bicyclo[2.1.1] hexane, bicyclo[2.2.1] heptane, bicyclo[3.2.1] octane, bicyclo[2.2.2] octane and adamantane. As the alicyclic hydrocarbon group, groups obtained by removing one hydrogen atom from these alicyclic hydrocarbons are preferable.

Preferred examples when the organic group serving as R^{22a} is an aliphatic hydrocarbon group which is substituted with a halogen atom include a trifluoromethyl group, a pentafluoroethyl group, a 2-chloroethyl group, a 2-bromoethyl group, a heptafluoro-n-propyl group, a 3-bromopropyl group, a nonafluoro-n-butyl group, a tridecafluoro-n-hexyl group, a heptadecafluoro-n-octyl group, a 2,2,2-trifluoroethyl group, a 1,1-difluoroethyl group, a 1,1-difluoro-n-propyl group, a 1,1,2,2-tetrafluoro-n-propyl group, a 3,3,3-trifluoro-n-propyl group, a 2,2,3,3,3-pentafluoro-n-propyl group, a 2-norbornyl-1,1-difluoroethyl group, a 2-norbornyl tetrafluoroethyl group and a 3-adamantyl-1,1,2,2-tetrafluoropropyl.

Preferred examples when the organic group serving as R^{22a} is an aliphatic hydrocarbon group which is substituted with an alkylthio group include a 2-methylthioethyl group, a 4-methylthio-n-butyl group and a 2-n-butylthioethyl group.

Preferred examples when the organic group serving as R^{22a} is an aliphatic hydrocarbon group which is substituted with a halogen atom and an alkylthio group include a 3-methylthio-1,1,2,2-tetrafluoro-n-propyl group.

Preferred examples when the organic group serving as R^{22a} is an aryl group include a phenyl group, a naphthyl group and a biphenylyl group.

Preferred examples when the organic group serving as R^{22a} is an aryl group which is substituted with a halogen atom include a pentafluorophenyl group, a chlorophenyl group, a dichlorophenyl group and a trichlorophenyl group.

Preferred examples when the organic group serving as R^{22a} is an aryl group which is substituted with an alkylthio group include a 4-methylthiophenyl group, a 4-n-butylthiophenyl group, a 4-n-octylthiophenyl group and a 4-n-dodecylthiophenyl group.

Preferred examples when the organic group serving as R^{22a} is an aryl group which is substituted with a halogen atom or an alkylthio group include a 1,2,5,6-tetrafluoro-4-methylthiophenyl group, a 1,2,5,6-tetrafluoro-4-n-butylthiophenyl group and a 1,2,5,6-tetrafluoro-4-n-dodecylthiophenyl group.

Preferred examples when the organic group serving as R^{22a} is an aralkyl group include a benzyl group, a phenethyl group, a 2-phenylpropane-2-yl group, a diphenylmethyl group and a triphenylmethyl group.

Preferred examples when the organic group serving as R^{22a} is an aralkyl group which is substituted with a halogen atom include a pentafluorophenylmethyl group, a phenyldifluoromethyl group, a 2-phenyltetrafluoroethyl group and a 2-(pentafluorophenyl)ethyl group.

Preferred examples when the organic group serving as R^{22a} is an aralkyl group which is substituted with an alkylthio group include a p-methylthiobenzyl group.

Preferred examples when the organic group serving as R^{22a} is an aralkyl group which is substituted with a halogen atom and an alkylthio group include a 2-(2,3,5,6-tetrafluoro-4-methylthiophenyl)ethyl group.

Preferred examples when the organic group serving as R^{22a} is an alkyl aryl group include a 2-methylphenyl group, a 3-methylphenyl group, a 4-methylphenyl group, a 3-isopropylphenyl group, a 4-isopropylphenyl group, a 4-n-butylphenyl group, a 4-isobutylphenyl group, a 4-tert-butylphenyl group, a 4-n-hexylphenyl group, a 4-cyclohexylphenyl group, a 4-n-octylphenyl group, a 4-(2-ethyl-n-hexyl)phenyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, a 2,4-di-tert-butylphenyl group, a 2,5-di-tert-butylphenyl group, a 2,6-di-tert-butylphenyl group, a 2,4-di-tert-pentylphenyl group, a 2,5-di-tert-pentylphenyl group, a 2,5-di-tert-octylphenyl group, a 2-cyclohexylphenyl group, a 3-cyclohexylphenyl group, a 4-cyclohexylphenyl group, a 2,4,5-trimethylphenyl group, a 2,4,6-trimethylphenyl group and a 2,4,6-triisopropylphenyl group.

The group represented by the formula (a21a) is an ether group-containing group. In the formula (a21a), examples of an alkanediyl group represented by Y′ and having 1 or more and 4 or less carbon atoms include a methylene group, an ethane-1,2-diyl group, an ethane-1,1-diyl group, a propane-1,3-diyl group, a propane-1,2-diyl group, a butane-1,4-diyl group, a butane-1,3-diyl group, a butane-2,3-diyl group and a butane-1,2-diyl group. In the formula (a21a), examples of an alkanediyl group represented by R^{27a} or R^{28a} and having 2 or more and 6 or less carbon atoms include an etan-1,2-diyl group, a propane-1,3-diyl group, a propane-1,2-diyl group, a butane-1,4-diyl group, a butane-1,3-diyl group, a butane-2,3-diyl group, a butane-1,2-diyl group, a pentane-1,5-diyl group, a pentane-1,3-diyl group, a pentane-1,4-diyl group, a pentane-2,3-diyl group, a hexane-1,6-diyl group, a hexane-1,2-diyl group, a hexane-1,3-diyl group, a hexane-1,4-diyl group, a hexane-2,5-diyl group, a hexane-2,4-diyl group and a hexane-3,4-diyl group.

In the formula (a21a), when R^{27a} or R^{28a} is an alkanediyl group having 2 or more and 6 or less carbon atoms which is substituted with a halogen atom, examples of the halogen atom include a chlorine atom, a bromine atom, an iodine atom and a fluorine atom. Examples of the alkanediyl group substituted with a halogen atom include a tetrafluoroethane-1,2-diyl group, a 1,1-difluoroethane-1,2-diyl group, a 1-fluoroethane-1,2-diyl group, a 1,2-difluoroethane-1,2-diyl group, a hexafluoropropane-1,3-diyl group, a 1,1,2,2,-tetrafluoropropane-1,3-diyl group and a 1,1,2,2,-tetrafluoropentane-1,5-diyl group.

In the formula (a21a), examples when R^{27a} or R^{28a} is an arylene group include a 1,2-phenylene group, a 1,3-phenylene group, a 1,4-phenylene group, a 2,5-dimethyl-1,4-phenylene group, a biphenyl-4,4′-diyl group, a diphenylmethane-4,4′-diyl group, a 2,2,-diphenylpropane-4,4′-diyl group, a naphthalene-1,2-diyl group, a naphthalene-1,3-diyl group, a naphthalene-1,4-diyl group, a naphthalene-1,5-diyl group, a naphthalene-1,6-diyl group, a naphthalene-1,7-diyl group, a naphthalene-1,8-diyl group, a naphthalene-2,3-diyl group, a naphthalene-2,6-diyl group and a naphthalene-2,7-diyl group.

In the formula (a21a), when R^{27a} or R^{28a} is an arylene group which is substituted with a halogen atom, examples of the halogen atom include a chlorine atom, a bromine atom, an iodine atom and a fluorine atom. Examples of the arylene group substituted with a halogen atom include a 2,3,5,6-tetrafluoro-1,4-phenylene group.

In the formula (a21a), examples of an alkyl group having 1 or more and 18 or less carbon atoms which is represented by R^{29a} and may branch include a methyl group, an ethyl group, an n-propyl group, an isopropyl group, an n-butyl group, a sec-butyl group, a tert-butyl group, an isobutyl group, an n-pentyl group, an isopentyl group, a tert-pentyl group, an n-hexyl group, an n-hexane-2-yl group, an n-hexane-3-yl group, an n-heptyl group, an n-heptane-2-yl group, an n-heptane-3-yl group, an isoheptyl group, a tert-heptyl group, an n-octyl group, an isooctyl group, a tert-octyl group, a 2-ethylhexyl group, an n-nonyl group, an isononyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

In the formula (a21a), when R^{29a} is an alkyl group having 1 or more and 18 or less carbon atoms which is substituted with a halogen atom, examples of the halogen atom include a chlorine atom, a bromine atom, an iodine atom and a fluorine atom. Examples of the alkyl group substituted with a halogen atom include a trifluoromethyl group, a pentafluoroethyl group, a heptafluoro-n-propyl group, a nonafluoro-n-butyl group, a tridecafluoro-n-hexyl group, a heptadecafluoro-n-octyl group, a 2,2,2-tri fluoroethyl group, a 1,1-difluoroethyl group, a 1,1-difluoro-n-propyl group, a 1,1,2,2-tetrafluoro-n-propyl group, a 3,3,3-trifluoro-n-propyl group, a 2,2,3,3,3-pentafluoro-n-propyl group and a 1,1,2,2-tetrafluorotetradecyl group.

In the formula (a21a), when R^{29a} is an alicyclic hydrocarbon group having 3 or more and 12 or less carbon atoms, examples of an alicyclic hydrocarbon constituting the main skeleton of the alicyclic hydrocarbon group include cyclopropane, cyclobutane, cyclopentane, cyclohexane, cycloheptane, cyclooctane, cyclodecane, bicyclo[2.1.1] hexane, bicyclo[2.2.1] heptane, bicyclo[3.2.1] octane, bicyclo[2.2.2] octane and adamantane. As the alicyclic hydrocarbon group, groups obtained by removing one hydrogen atom from these alicyclic hydrocarbons are preferable.

In the formula (a21a), when R^{29a} is an aryl group, an aryl halide group, an aralkyl group and a halogenated aralkyl group, preferred examples of these groups are the same as those when R^{22a} is these groups.

A preferred group among groups represented by the formula (a21a) is a group among groups represented by R^{27a} in which a carbon atom bonded to a sulfur atom is substituted with a fluorine atom. The number of carbon atoms in the preferred group is preferably 2 or more and 18 or less.

As R^{22a}, a perfluoroalkyl group having 1 or more and 8 or less carbon atoms is preferable. Since a resist pattern with a high resolution is easily formed, a camphor-10-il group is also preferable as R^{22a}.

In the formula (a21), R^{23a} to R^{26a} are a hydrogen atom or a monovalent organic group. R^{23a} and R^{24a}, R^{24a} and R^{25a} or R^{25a} and R^{26a} may be bonded to each other to form a ring. For example, R^{25a} and R^{26a} are bonded to form a 5-membered ring together with a naphthalene ring, with the result that an acenaphthene skeleton may be formed.

Preferred examples of the monovalent organic group include: an alkyl group and an alkoxy group having 4 or more and 18 or less carbon atoms which may be substituted with an alicyclic hydrocarbon group, a heterocyclic group (heterocyclyl group) or a halogen atom and may branch; an unsaturated hydrocarbon groups having 4 or more and 18 or less carbon atoms which may be substituted with an alicyclic hydrocarbon group, a heterocyclic group (heterocyclyl group) or a halogen atom and may branch; an alkoxy group; a heterocyclyloxy group; an alkylthio group having 4 or more and 18 or less carbon atoms which may be substituted with an alicyclic hydrocarbon group, a heterocyclic group (heterocyclyl group) or a halogen atom and may branch; and a heterocyclylthio group; —O—SO₂—R^{30a} (R^{30a} is an alkyl group having 4 or more and 18 or less carbon atoms which may be branch). A group in which a methylene group in an arbitrary position that is not adjacent to an oxygen atom in the alkoxy group is substituted with —CO— is also preferable. A group in which the alkoxy group is interrupted by a —O—CO-bond or a O—CO—NH-bond is also preferable. The left end of the —O—CO-bond or the O—CO—NH-bond is a side close to a naphthalic acid matrix in the alkoxy group. Furthermore, an alkylthio group having 4 or more and 18 or less carbon atoms which may be substituted with an alicyclic hydrocarbon group, a heterocyclic group or a halogen atom and may branch is also preferable as R^{23a} to R^{26a}. A group in which a methylene group in an arbitrary position that is not adjacent to a sulfur atom in the alkylthio group is substituted with —CO— is also preferable. A group in which the alkylthio group is interrupted by a —O—CO-bond or a —O—CO—NH-bond is also preferable. The left end of the —O—CO-bond or the —O—CO—NH-bond is a side close to a naphthalic acid matrix in the alkylthio group.

In R^{23a} to R^{26a}, it is preferable that R^{23a} is an organic group and R^{24a} to R^{26a} are a hydrogen atom, or R^{24a} is an organic group and R^{23a}, R^{25a} and R^{26a} are a hydrogen atom. All R^{23a} to R^{26a} may be a hydrogen atom.

Examples when R^{23a} to R^{26a} are an unsubstituted alkyl group include an n-butyl group, a sec-butyl group, a tert-butyl group, an isobutyl group, an n-pentyl group, an isopentyl group, a tert-pentyl group, an n-hexyl group, an n-heptyl group, an isoheptyl group, a tert-heptyl group, an n-octyl group, an isooctyl group, a tert-octyl group, a 2-ethylhexyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

When R^{23a} to R^{26a} are unsaturated hydrocarbon groups having 4 or more and 18 or less carbon atoms which may be substituted with an alicyclic hydrocarbon group, a heterocyclic group (heterocyclyl group), or a halogen atom and may have a branch, the unsaturated bond of the unsaturated hydrocarbon group may be a double bond or a triple bond. As the unsaturated hydrocarbon group, an alkenyl group or an alkynyl group is preferable. Suitable examples of alkenyl groups include a but-1-en-1-yl, a but-2-en-1-yl group, a but-3-en-1-yl group, a pent-1-en-1-yl group, a pent-2-en-1-yl group, a pent-3-en-1-yl group, a pent-4-en-1-yl group, a hex-1-en-1-yl group, a hex-2-en-1-yl group, a hex-3-en-1-yl group, a hex-4-en-1-yl group, a hex-5-en-1-yl group, a hept-1-en-1-yl, an oct-1-en-1-yl group, a non-1-en-1-yl group, a dec-1-en-1-yl group, an undec-1-en-1-yl group, a dodec-1-en-1-yl group, a tridec-1-en-1-yl group, a tetradec-1-en-1-yl group, a pentadec-1-en-1-yl group, a hexadec-1-en-1-yl group, a heptadec-1-en-1-yl group, and an octadec-1-en-1-yl group. Suitable examples of alkynyl groups include a but-1-yn-1-yl group, a but-2-yn-1-yl group, a but-3-yn-1-yl group, a pent-1-yn-1-yl group, a pent-2-yn-1-yl group, a pent-3-yn-1-yl group, a pent-4-yn-1-yl group, a hex-1-yn-1-yl group, a hex-2-yn-1-yl group, a hex-3-yn-1-yl group, a hex-4-yn-1-yl group, a hex-5-yn-1-yl group, a hept-1-yn-1-yl group, an oct-1-yn-1-yl group, a non-1-yn-1-yl group, a dec-1-yn-1-yl group, an undec-1-yn-1-yl group, a dodec-1-yn-1-yl group, a tridec-1-yn-1-yl group, a tetradec-1-yn-1-yl group, a pentadec-1-yn-1-yl group, a hexadec-1-yn-1-yl group, a heptadec-1-yn-1-yl group, and an octadec-1-yn-1-yl group.

Examples when R^{23a} to R^{26a} are an unsubstituted alkoxy group include an n-butyloxy group, a sec-butyloxy group, a tert-butyloxy group, an isobutyloxy group, an n-pentyloxy group, an isopentyloxy group, a tert-pentyloxy group, an n-hexyloxy group, an n-heptyloxy group, an isoheptyloxy group, a tert-heptyloxy group, an n-octyloxy group, an isooctyloxy group, a tert-octyloxy group, a 2-ethylhexyl group, an n-nonyloxy group, an n-decyloxy group, an n-undecyloxy group, an n-dodecyloxy group, an n-tridecyloxy group, an n-tetradecyloxy group, an n-pentadecyloxy group, an n-hexadecyloxy group, an n-heptadecyloxy group and an n-octadecyloxy group.

Examples when R^{23a} to R^{26a} are an unsubstituted alkylthio group include an n-butylthio group, a sec-butylthio group, a tert-butylthio group, an isobutylthio group, an n-pentylthio group, an isopentylthio group, a tert-pentylthio group, an n-hexylthio group, an n-heptylthio group, an isoheptylthio group, a tert-heptylthio group, an n-octylthio group, an isooctylthio group, a tert-octylthio group, a 2-ethylhexylthio group, an n-nonylthio group, an n-decylthio group, an n-undecylthio group, an n-dodecylthio group, an n-tridecylthio group, an n-tetradecylthio group, an n-pentadecylthio group, an n-hexadecylthio group, an n-heptadecylthio group and an n-octadecylthio group.

When R^{23a} to R^{26a} are an alkyl group, an alkoxy group or an alkylthio group substituted with an alicyclic hydrocarbon group, examples of an alicyclic hydrocarbon constituting the main skeleton of the alicyclic hydrocarbon group include cyclopropane, cyclobutane, cyclopentane, cyclohexane, cycloheptane, cyclooctane, cyclodecane, bicyclo[2.1.1] hexane, bicyclo[2.2.1] heptane, bicyclo[3.2.1] octane, bicyclo[2.2.2] octane and adamantane. As the alicyclic hydrocarbon group, groups obtained by removing one hydrogen atom from these alicyclic hydrocarbons are preferable.

When R^{23a} to R^{26a} are an alkyl group, an alkoxy group or an alkylthio group substituted with a heterocyclic group or when R^{23a} to R^{26a} are a heterocyclyloxy group, examples of a heterocycle constituting the main skeleton of the heterocyclic group or the heterocyclyloxy group include pyrrole, thiophene, furan, pyrane, thiopyran, imidazole, pyrazole, thiazole, isothiazole, oxazole, isooxazole, pyridine, pyrazine, pyrimidine, pyridazine, pyrrolidine, pyrazolidine, imidazolidine, isooxazolidine, isothiazolidine, piperidine, piperazine, morpholin, thiomorpholin, chroman, thiochroman, isochroman, isothiochroman, indolin, isoindrin, pyrindin, indridin, indole, indazole, purine, quinolysin, isoquinoline, quinoline, naphthylidine, phthalazine, quinoxalin, quinazoline, cinnoline, pteridine, acridin, perimidine, phenanthroline, carbazole, carboline, phenazine, antilysine, thiazylazole, oxadiazole, triazine, triazole, tetrazole, benzoimidazole, benzoxazole, benzothiazole, benzothiadiazol, benzofloxane, naphthoimidazole, benzotriazole and tetraazainden. Among these heterocyclic groups, a saturated heterocyclic group obtained by hydrogenating a ring having a conjugated bond is also preferable. As a heterocyclic group substituting an alkyl group, an alkoxy group or an alkylthio group or a heterocyclic group included in a heterocyclyloxy group, a group obtained by removing one hydrogen atom from the heterocyclic group is preferable.

Examples when R^{23a} to R^{26a} are an alkoxy group including an alicyclic hydrocarbon group include a cyclopentyloxy group, a methylcyclopentioxy group, a cyclohexyloxy group, a fluorocyclohexyloxy group, a chlorocyclohexyloxy group, a cyclohexylmethyloxy group, a methylcyclohexyloxy group, a norbornyloxy group, an ethylcyclohexyloxy group, a cyclohexylethyloxy group, a dimethyl cyclohexyloxy group, a methylcyclohexylmethyloxy group, a norbornylmethyloxy group, a trimethylcyclohexyloxy group, a 1-cyclohexylbutyloxy group, an adamantyloxy group, menthyloxy group, an n-butylcyclohexyloxy group, a tert-butylcyclohexyloxy group, a bornyloxy group, an isobornyloxy group, a decahydronaphthyloxy group, a dicyclopentadienoxy group, a 1-cyclohexylpentyloxy group, a methyleneadamantyloxy group, an adamanthylmethyloxy group, a 4-pentylcyclohexyloxy group, a cyclohexylcyclohexyl oxy group, an adamantyl ethyloxy group and a dimethyl adamantyloxy group.

Examples when R^{23a} to R^{26a} are a heterocyclyloxy group include a tetrahydrofuranyloxy group, a furfuryloxy group, a tetrahydrofurfuryloxy group, a tetrahydropyranyloxy group, a butyrolactonyloxy group and an indolyloxy group.

Examples when R^{23a} to R^{26a} are an alkylthio group including an alicyclic hydrocarbon group include a cyclopentylthio group, a cyclohexylthio group, a cyclopentylmethylthio group, a norbornylthio group and an isonorbornylthio group.

Examples when R^{23a} to R^{26a} are a heterocyclylthio group include a furfurylthio group and a tetrahydrofuranylthio group.

When R^{23a} to R^{26a} represent a group represented by —O—SO₂—R^{30a} (R^{30a} represents an optionally branched alkyl group having 4 or more and 18 or less carbon atoms), specific examples of the group represented by —O—SO₂—R^{30a} include a n-butylsulfonyloxy group, a sec-butylsulfonyloxy group, a tert-butylsulfonyloxy group, an isobutylsulfonyloxy group, a n-pentylsulfonyloxy group, an isopentylsulfonyloxy group, a tert-pentylsulfonyloxy group, a n-hexylsulfonyloxy group, a n-heptylsulfonyloxy group, an isoheptylsulfonyloxy group, a tert-heptylsulfonyloxy group, a n-octylsulfonyloxy group, an isooctylsulfonyloxy group, a tert-octylsulfonyloxy group, a 2-ethylhexylsulfonyloxy group, a n-nonylsulfonyloxy group, a n-decylsulfonyloxy group, a n-undecylsulfonyloxy group, a n-dodecylsulfonyloxy group, a n-tridecylsulfonyloxy group, a n-tetradecylsulfonyloxy group, a n-pentadecylsulfonyloxy group, a n-hexadecylsulfonyloxy group, a n-heptadecylsulfonyloxy group, and a n-octadecylsulfonyloxy group.

Examples when R^{23a} to R^{26a} are a group in which a methylene group in an arbitrary position that is not adjacent to an oxygen atom in an alkoxy group is substituted with —CO— include a 2-ketobutyl-1-oxy group, a 2-ketopentyl-1-oxy group, a 2-ketohexyl-1-oxy group, a 2-ketoheptyl-1-oxy group, a 2-ketooctyl-1-oxy group, a 3-ketobutyl-1-oxy group, a 4-ketopentyl-1-oxy group, a 5-ketohexyl-1-oxy group, a 6-ketoheptyl-1-oxy group, a 7-ketooctyl-1-oxy group, a 3-methyl-2-ketopentane-4-oxy group, a 2-ketopentan-4-oxy group, a 2-methyl-2-ketopentan-4-oxy group, a 3-ketoheptane-5-oxy group and a 2-adamantanone-5-oxy group.

Examples when R^{23a} to R^{26a} are a group in which a methylene group in an arbitrary position that is not adjacent to a sulfur atom in an alkylthio group is substituted with —CO— include a 2-ketobutyl-1-thio group, a 2-ketopentyl-1-thio group, a 2-ketohexyl-1-thio group, a 2-ketoheptyl-1-thio group, a 2-ketooctyl-1-thio group, a 3-ketobutyl-1-thio group, a 4-ketopentyl-1-thio group, a 5-ketohexyl-1-thio group, a 6-ketoheptyl-1-thio group, a 7-ketooctyl-1-thio group, a 3-methyl-2-ketopentane-4-thio group, a 2-ketopentan-4-thio group, a 2-methyl-2-ketopentan-4-thio group and a 3-ketoheptane-5-thio group.

Specific examples of the compound represented by the formula (a21) include the following compounds. In the following compounds, n represents an integer of 1 or more and 10 or less.

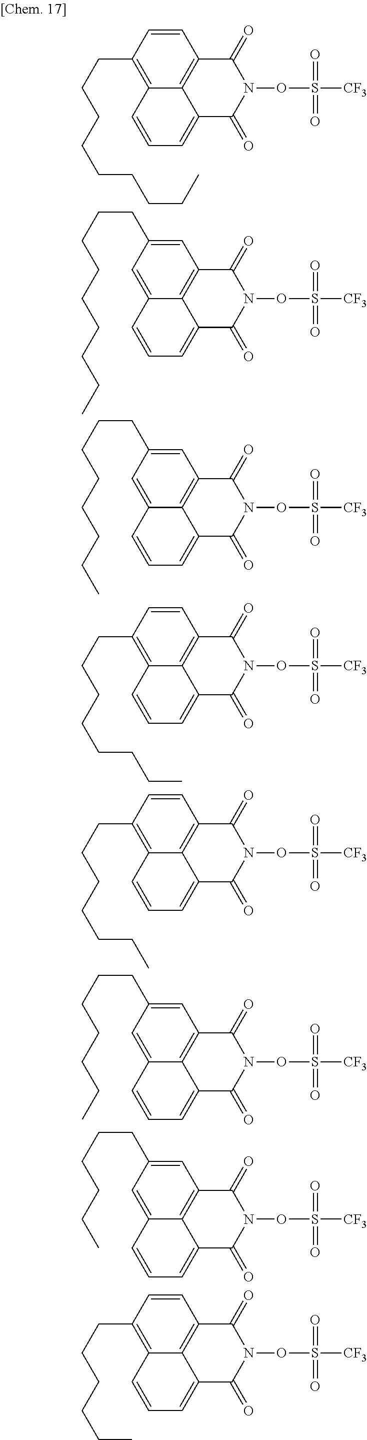

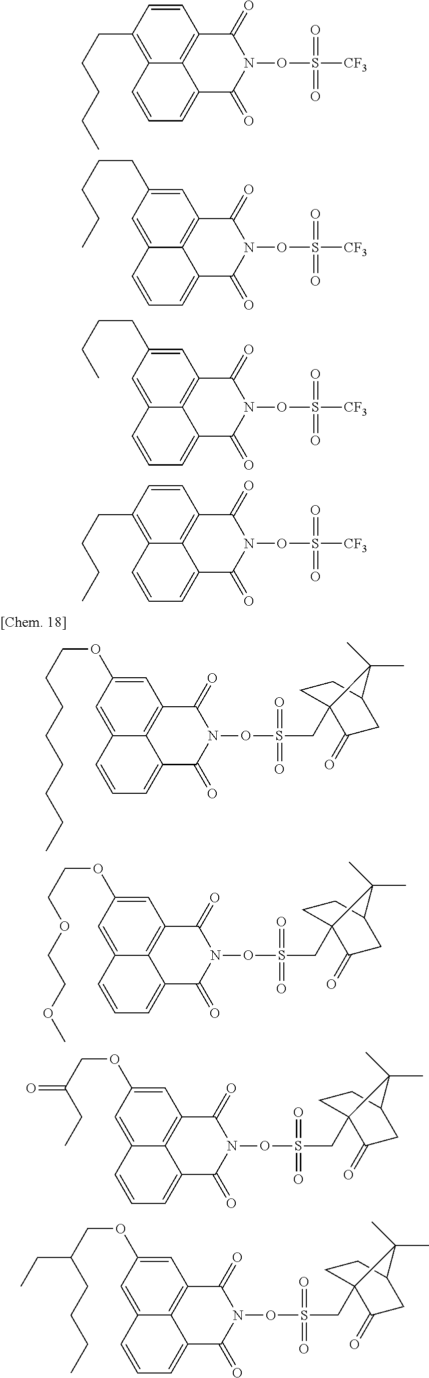

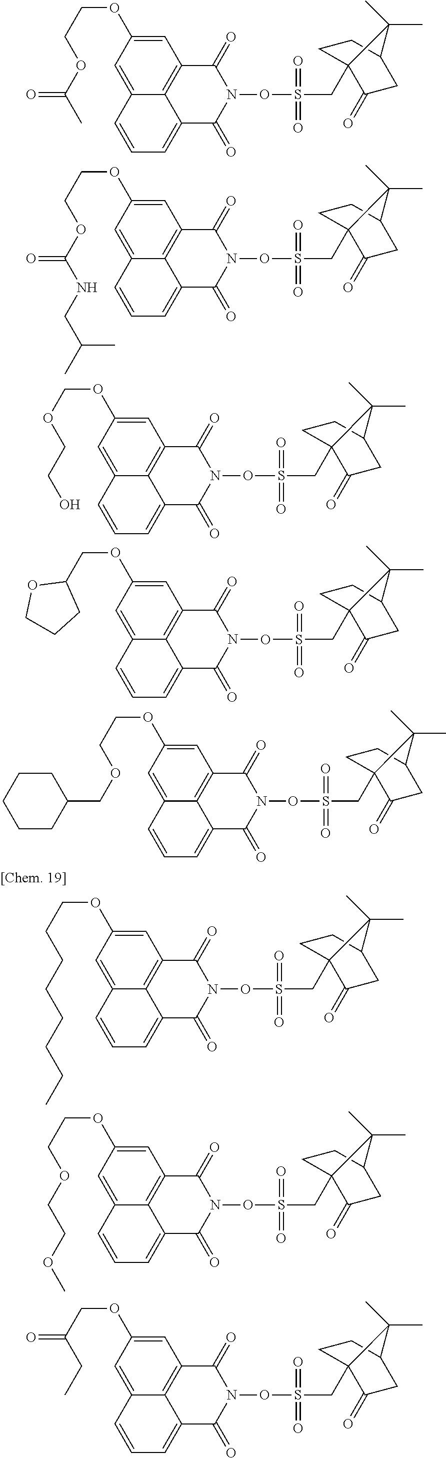

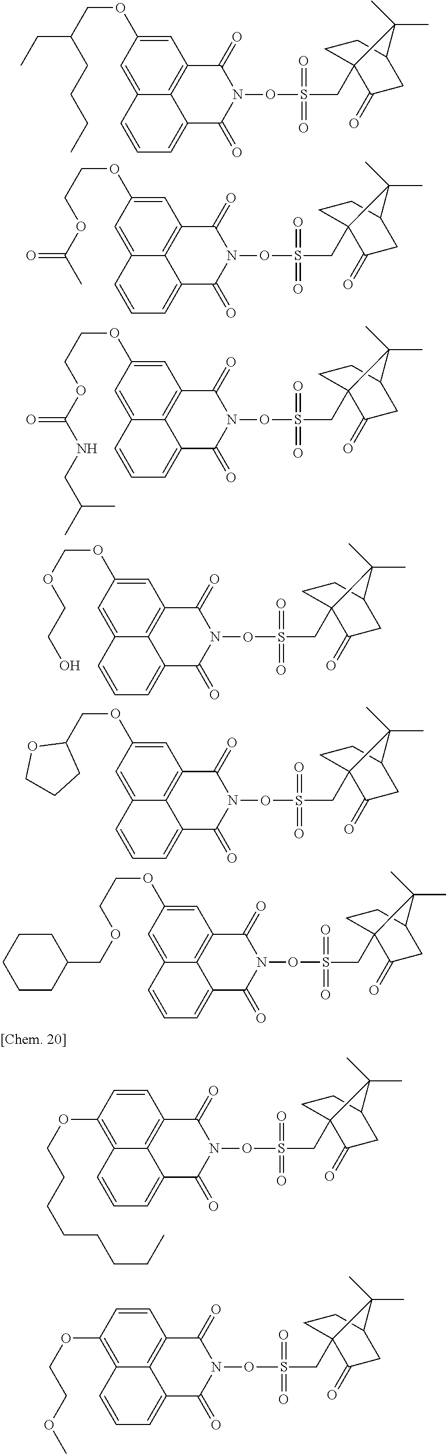

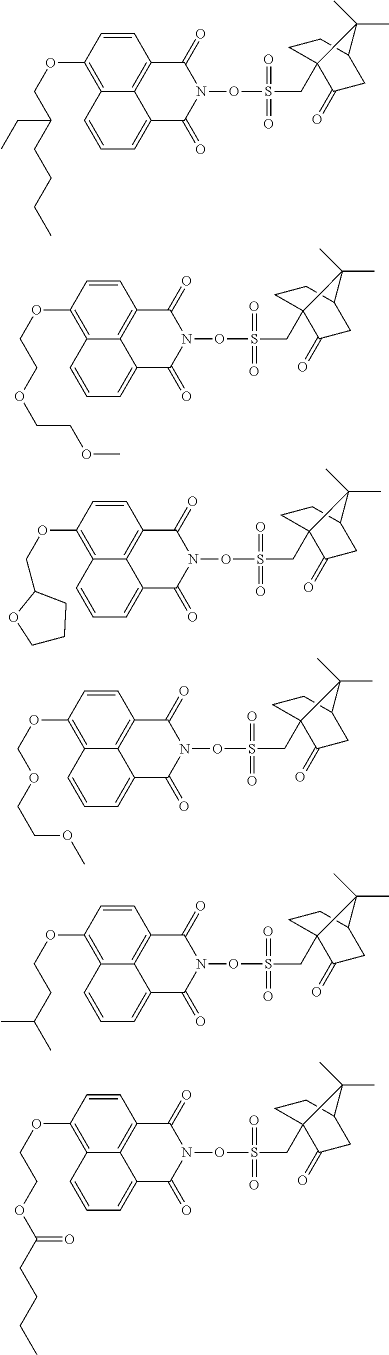

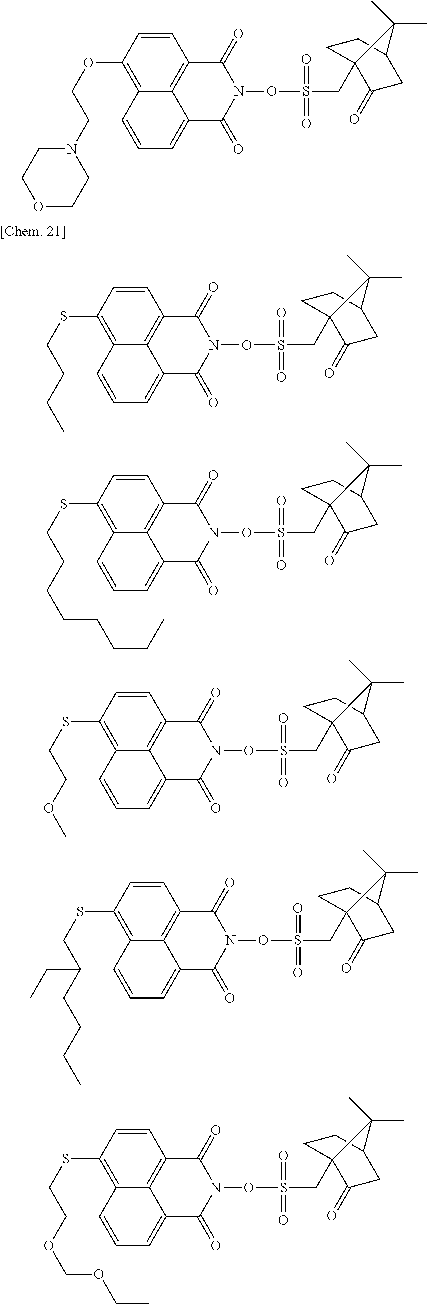

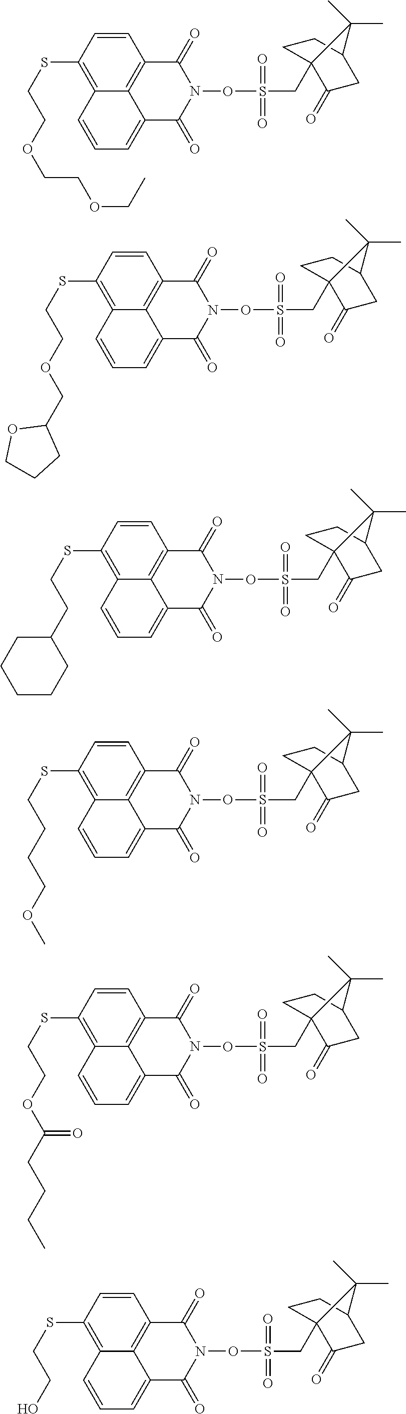 [SMILES: CCOCCOCCSc1ccc2c3c(cccc13)C(=O)N(OS(=O)(=O)CC13CCC(CC1=O)C3(C)C)C2=O ; CC1(C)C2CCC1(CS(=O)(=O)ON1C(=O)c3cccc4c(SCCOCC5CCCO5)ccc(c34)C1=O)C(=O)C2 ; CC1(C)C2CCC1(CS(=O)(=O)ON1C(=O)c3cccc4c(SCCC5CCCCC5)ccc(c34)C1=O)C(=O)C2 ; COCCCCSc1ccc2c3c(cccc13)C(=O)N(OS(=O)(=O)CC13CCC(CC1=O)C3(C)C)C2=O ; CCCCC(=O)OCCSc1ccc2c3c(cccc13)C(=O)N(OS(=O)(=O)CC13CCC(CC1=O)C3(C)C)C2=O ; CC1(C)C2CCC1(CS(=O)(=O)ON1C(=O)c3cccc4c(SCCO)ccc(c34)C1=O)C(=O)C2]

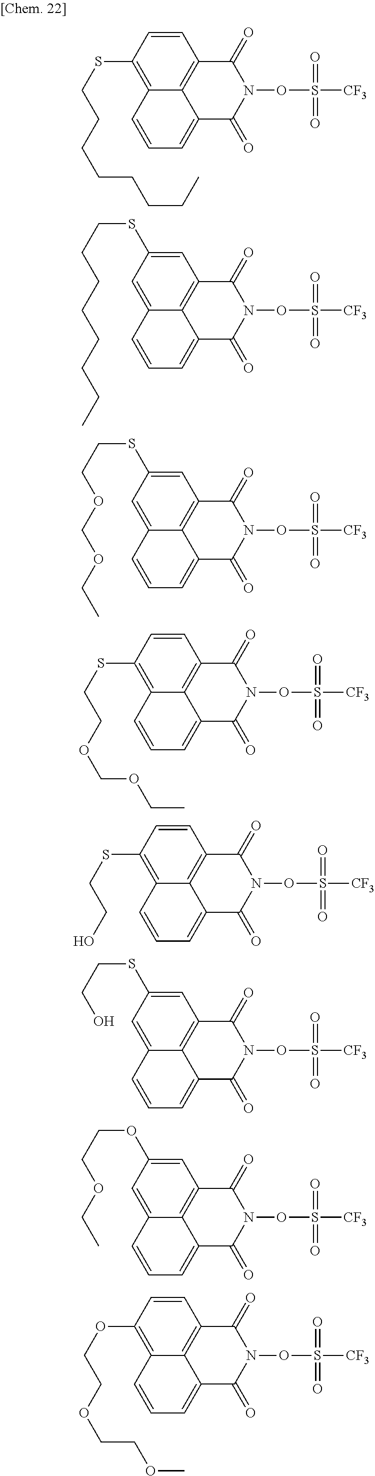

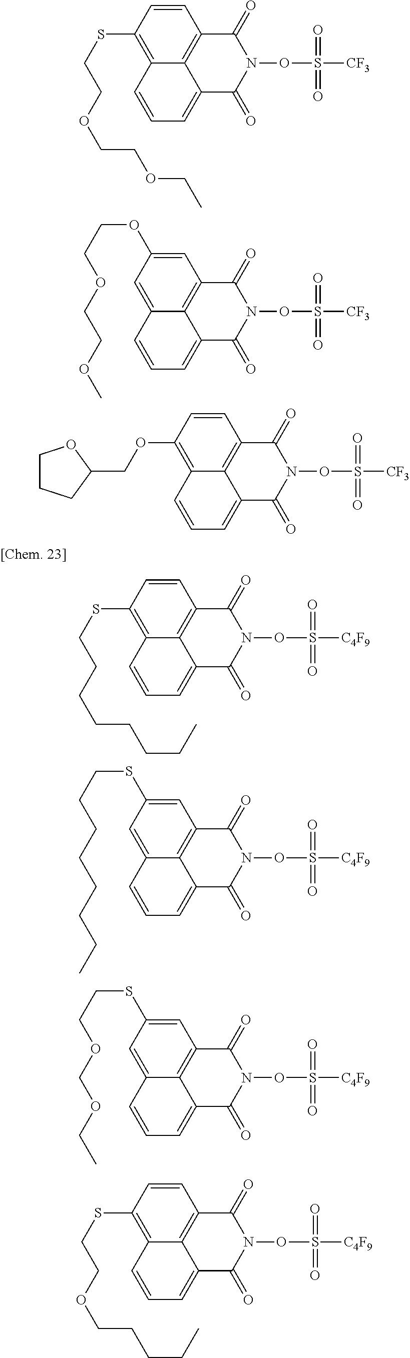

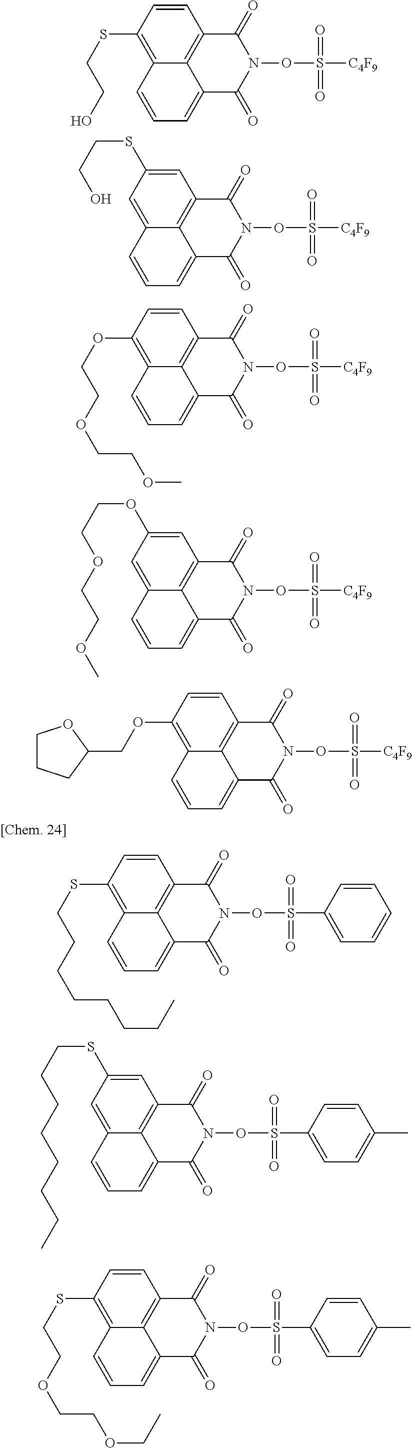

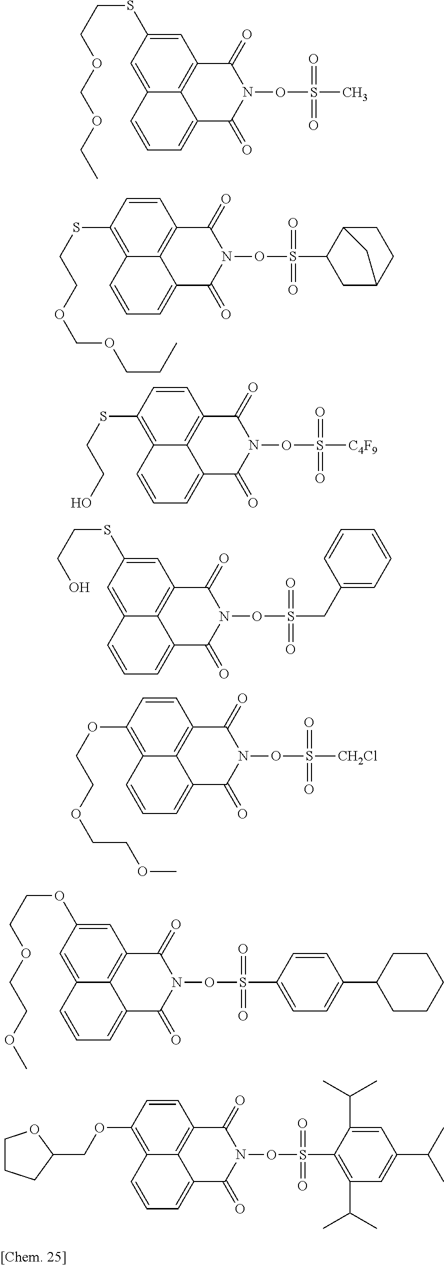

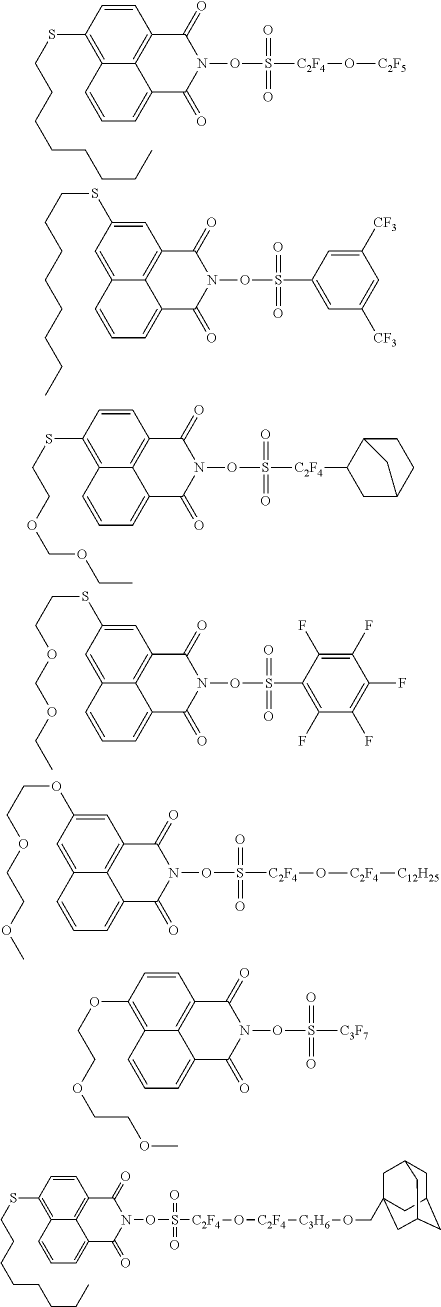

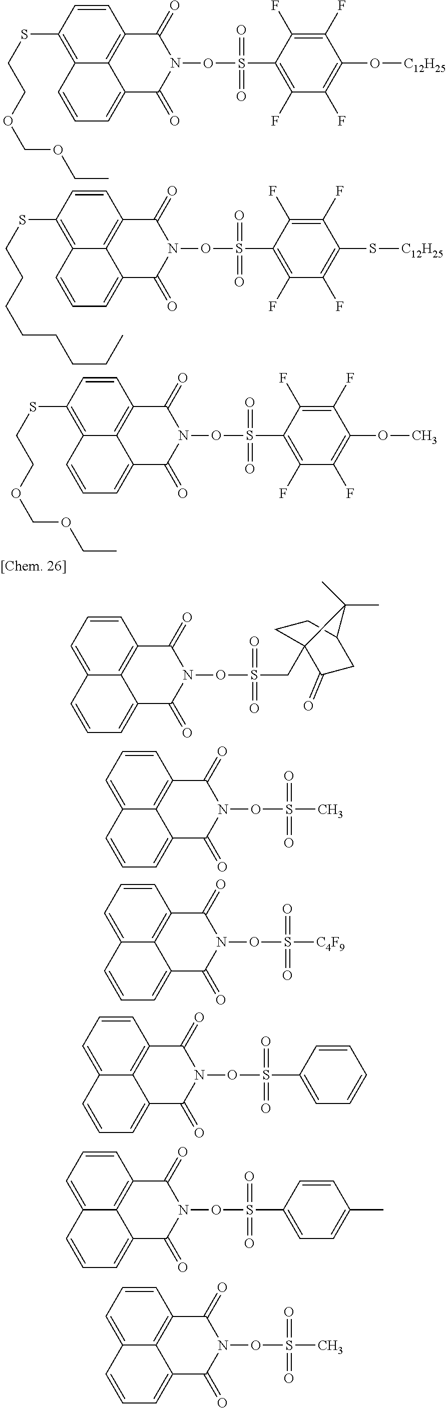

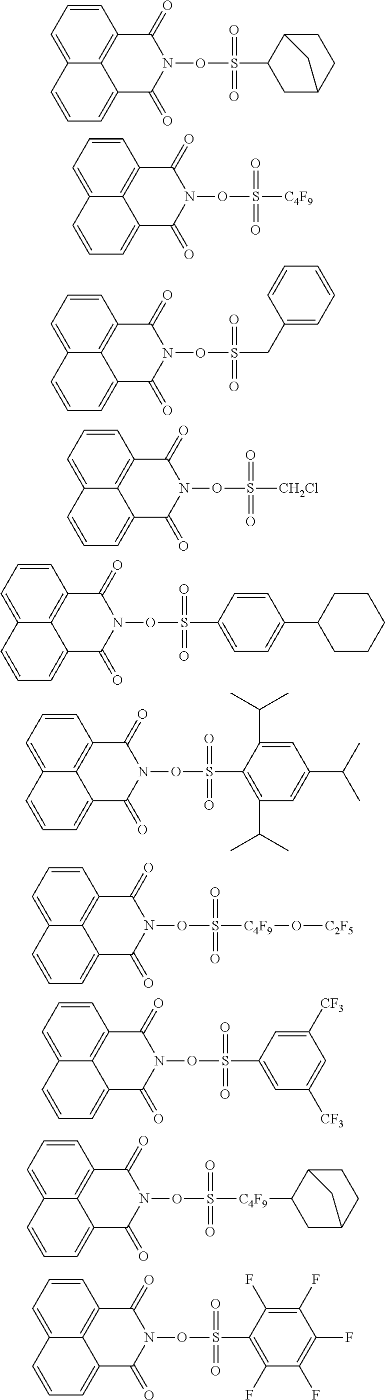

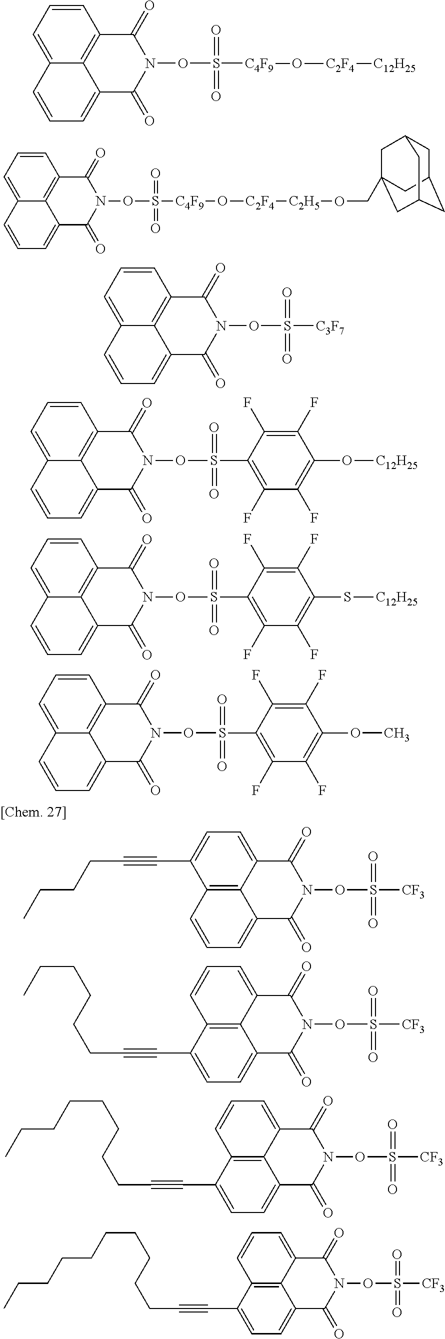

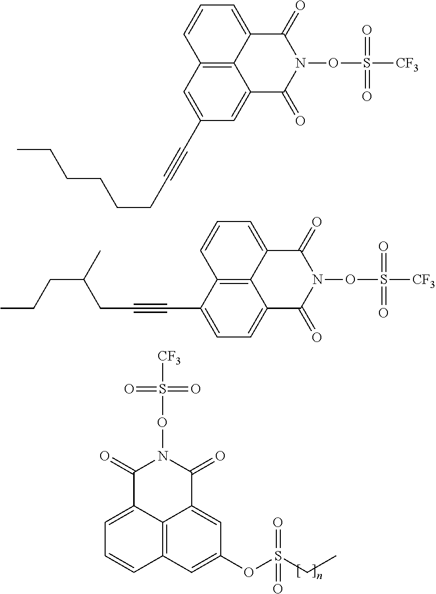

The acid generating agent (A) may be used alone, or two or more types may be used in combination. Furthermore, the content of the acid generating agent (A) is adjusted to preferably 0.1 by mass or more and 10 by mass of less, more preferably 0.? by mass or more and 6 by mass or less and even more preferably 0.5 by mass or more and 3 by mass or less, relative to the total mass of the solid content of the chemically amplified positive-type photosensitive composition. When the amount of the acid generating agent (A) used is adjusted to the range mentioned above, it is easy to prepare a photosensitive composition which is a uniform solution having satisfactory sensitivity and excellent storage stability. Note that the solid content refers to a component other than the solvent in the present specification.

### <Resin (B)>

The photosensitive composition includes an acrylic resin (B3) as an essential component, as the resin (B) having an alkali solubility that increases under action of an acid. The acrylic resin (B3) includes a constituent unit (B3-1) derived from an acid dissociable (meth)acrylic acid alicyclic ester. In the acid dissociable (meth)acrylic acid alicyclic ester, the alicyclic group includes a tertiary carbon atom as a ring constituent element, and the tertiary carbon atom of the alicyclic group is bonded to an oxygen atom other than carbonyl oxygen in an ester group in the acid dissociable (meth)acrylic acid alicyclic ester to form a C—O bond.

The resin (B) may contain, together with the acrylic resin (B3), any resin having an alkali solubility that increases under action of an acid, other than the acrylic resin (B3). However, a ratio of a mass of the acrylic resin (B3) with respect to a mass of the resin (B) is preferably 50% by mass or more, more preferably 708 by mass or more, still more preferably 90% by mass or more, and particularly preferably 100% by mass. The resin which may be included in the resin (B) and which has an alkali solubility that increases under action of an acid, other than the acrylic resin (B3) is not particularly limited as long as the photosensitive composition satisfies the above-described requirement 1, and examples thereof include a novolac resin (B1), a polyhydroxystyrene resin (B2), and an acrylic resin other than the acrylic resin (B3).

### [Novolak Resin (B1)]

As the novolak resin (B1), a resin including the structural unit represented by the following formula (b1) may be used.

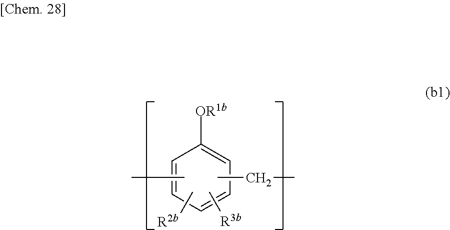

In the above formula (b1), R^{1b} represents an acid-dissociable dissolution-inhibiting group, and R^{2b} and R^{3b} each independently represent a hydrogen atom or an alkyl group having 1 or more and 6 or less carbon atoms.

The acid-dissociable dissolution-inhibiting group represented by the above Rib is preferably a group represented by the following formulae (b2) or (b3), a linear, branched or cyclic alkyl group having 1 or more and 6 or less carbon atoms, a vinyloxyethyl group, a tetrahydropyranyl group, a tetrahydrofuranyl group, or a trialkylsilyl group.

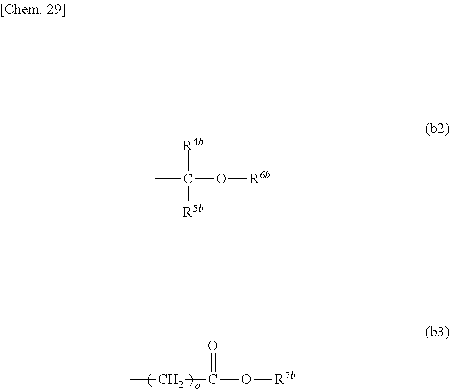

In the formulae (b2) and (b3), R^{4b} and R^{5b} each independently represent a hydrogen atom or a linear or branched alkyl group having 1 or more and 6 or less carbon atoms, Rob represents a linear, branched, or cyclic alkyl group having 1 or more and 10 or less carbon atoms, R^{7b} represents a linear, branched, or cyclic alkyl group having 1 or more and 6 or less carbon atoms, and o represents 0 or 1.

Examples of the linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Also, examples of the cyclic alkyl group include a cyclopentyl group, a cyclohexyl group, and the like.

Specific examples of the acid-dissociable dissolution-inhibiting group represented by the above formula (b2) include a methoxyethyl group, an ethoxyethyl group, an n-propoxyethyl group, an isopropoxyethyl group, an n-butoxyethyl group, an isobutoxyethyl group, a tert-butoxyethyl group, a cyclohexyloxyethyl group, a methoxypropyl group, an ethoxypropyl group, a 1-methoxy-1-methyl-ethyl group, a 1-ethoxy-1-methylethyl group, and the like. Furthermore, specific examples of the acid-dissociable dissolution-inhibiting group represented by the above formula (b3) include a tert-butoxycarbonyl group, tert-butoxycarbonylmethyl group, and the like. Examples of the trialkylsilyl group include a trimethylsilyl group and a tri-tert-butyldimethylsilyl group in which each alkyl group has 1 or more and 6 or less carbon atoms.

### [Polyhydroxystyrene Resin (B2)]

As the polyhydroxystyrene resin (B2), a resin including the structural unit represented by the following formula (b4) may be used.

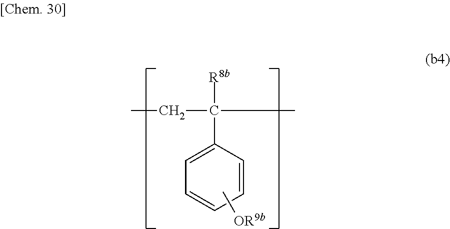

In the formula (b4), R^{8b} represents a hydrogen atom or an alkyl group having 1 or more and 6 or less carbon atoms, and Rob represents an acid-dissociable dissolution-inhibiting group.

The alkyl group having 1 or more and 6 or less carbon atoms may include, for example, linear, branched or cyclic alkyl groups having 1 or more and 6 or less carbon atoms. Examples of the linear or branched alkyl group include a methyl group, an ethyl group, a propyl group, an isopropyl group, an n-butyl group, isobutyl group, a tert-butyl group, a pentyl group, an isopentyl group, and a neopentyl group, and examples of the cyclic alkyl group include a cyclopentyl group and a cyclohexyl group.

The acid-dissociable dissolution-inhibiting group represented by the above R^{9b} may be similar to the acid-dissociable dissolution-inhibiting groups exemplified in terms of the above formulae (b2) and (b3).

Furthermore, the polyhydroxystyrene resin (B2) may include another polymerizable compound as a structural unit in order to moderately control physical or chemical properties. The polymerizable compound is exemplified by conventional radical polymerizable compounds and anion polymerizable compounds. Examples of the polymerizable compound include monocarboxylic acids such as acrylic acid, methacrylic acid, and crotonic acid; dicarboxylic acids such as maleic acid, fumaric acid, and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl (meth)acrylate, and butyl(meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide; and the like. These polymerizable compounds do not have an acid-dissociable dissolution-inhibiting group.

### [Acrylic Resin (B3)]

The acrylic resin (B3) as the resin (B) having an alkali solubility that increase under action of an acid includes a constituent unit (B3-1) derived from an acid dissociable (meth)acrylic acid alicyclic ester. In the acid dissociable (meth)acrylic acid alicyclic ester, the alicyclic group includes a tertiary carbon atom as a ring constituent element, and the tertiary carbon atom of the alicyclic group is bonded to an oxygen atom other than carbonyl oxygen in an ester group in the acid dissociable (meth)acrylic acid alicyclic ester to form a C—O bond.

The acrylic resin (B3) is a resin in which a ratio of a constituent unit derived from a monomer having a (meth)acryloyloxy group to all the constituent units constituting the resin is 70 mol % or more, preferably 90 mol % or more, and more preferably 100 mol %. In the present specification, “(meth)acrylic” means both “acrylic” and “methacrylic”.

“(Meth)acrylate” means both “acrylate” and “methacrylate”.

“(Meth)acryloyloxy” means both “acryloyloxy” and “methacryloyloxy”.

Examples of the constituent unit (B3-1) derived from an acid dissociable (meth)acrylic acid alicyclic ester contained in the acrylic resin (B3) include a constituent unit represented by the following formula (b3-1).

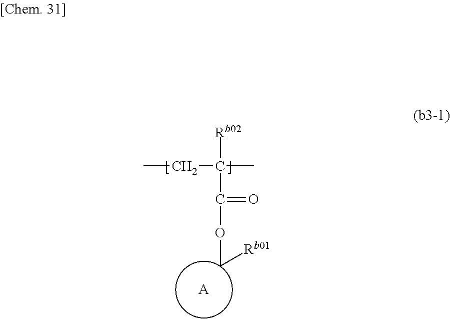

(In the formula (b3-1), ring A is a saturated aliphatic hydrocarbon ring, R^{b01} is an alkyl group having 1 to 12 carbon atoms or an arylalkyl group having 7 to 15 carbon atoms, and R^{b02} is a hydrogen atom or a methyl group.)

In the formula (b3-1), ring A is a saturated aliphatic hydrocarbon ring. The saturated aliphatic hydrocarbon ring is preferably a saturated aliphatic hydrocarbon ring having 5 or more and 20 or less carbon atoms. The saturated aliphatic hydrocarbon ring may be monocycloalkanes or polycycloalkanes, such as bicycloalkanes, tricycloalkanes, and tetracycloalkanes. Specific examples of the saturated aliphatic hydrocarbon ring include monocycloalkanes such as cyclopentane, cyclohexane, cycloheptane and cyclooctane, and polycycloalkanes such as adamantane, norbornane, isobornane, tricyclodecane and tetracyclodecane.

In the formula (b3-1), R^{b01} represents an alkyl group having 1 to 12 carbon atoms or an arylalkyl group having 7 to 15 carbon atoms. Examples of the alkyl group having 1 or more and 12 or less carbon atoms for R^{b01} include a methyl group, an ethyl group, a n-propyl group, an isopropyl group, a n-butyl group, an isobutyl group, a sec-butyl group, a tert-butyl group, a n-pentyl group, an isopentyl group, a tert-pentyl group, a n-hexyl group, a n-heptyl group, a n-octyl group, a 2-ethyl-n-hexyl group, a n-nonyl group, and a n-decyl group.

Specific examples of the constituent unit represented by the formula (b3-1) include the following constituent units.

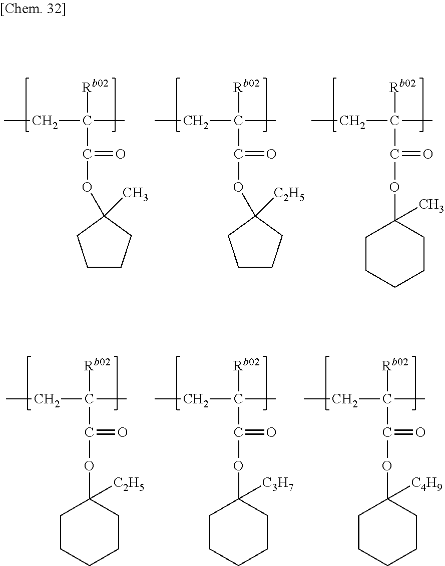

(R^{b02} in the formula is the same as R^{b02} in the formula (b3-1).)

An amount of the constituent unit (B3-1) derived from an acid dissociable (meth)acrylic acid alicyclic ester in the acrylic resin (B3) is not particularly limited, but a ratio of a mass of the constituent unit (B3-1) derived from the acid dissociable (meth)acrylic acid alicyclic ester to the mass of the acrylic resin (B3) is preferably 15% by mass or more and 80% by mass or less, and more preferably 25% by mass or more and 70% by mass or less. With respect to an amount of the constituent unit represented by the formula (b3-1) in the acrylic resin (B3), a ratio of a mass of the constituent unit represented by the formula (b3-1) to the mass of the acrylic resin (B3) is preferably 15% by mass or more and 80% by mass or less, and more preferably 25% by mass or more and 70% by mass or less.

The acrylic resin (B3) may include, for example, a constituent unit (b-3) derived from an acrylate ester including an —SO₂-containing cyclic group or a lactone-containing cyclic group. Note that the constituent unit (b-3) does not correspond to the constituent unit (B3-1) derived from the acid dissociable (meth)acrylic acid alicyclic ester.

### (—SO₂— Containing Cyclic Group)

Here, the “—SO₂— containing cyclic group” refers to a cyclic group which contains a ring including —SO₂— in its ring skeleton, and is specifically a cyclic group in which a sulfur atom(s) in —SO₂— forms part of the ring skeleton in the cyclic group. When the ring including —SO₂— in its ring skeleton is counted as the first ring, and only this ring is provided, the “—SO₂— containing cyclic group” is referred to as a monocyclic group whereas when another ring structure is further provided, it is referred to as a polycyclic group regardless of its structure. The —SO₂— containing cyclic group may be either monocyclic or polycyclic.

In particular, the —SO₂— containing cyclic group is preferably a cyclic group that includes —O—SO₂— in its ring skeleton, that is, a cyclic group that contains a sultone ring in which —O—S— in —O—SO₂— forms part of the ring skeleton.

The number of carbon atoms of the —SO₂— containing cyclic group is preferably 3 or more and 30 or less, is more preferably 4 or more and 20 or less, is further preferably 4 or more and 15 or less and is particularly preferably 4 or more and 12 or less. It is assumed that the number of carbon atoms described above is the number of carbon atoms which form the ring skeleton and does not include the number of carbon atoms in a substituent.

The —SO₂— containing cyclic group may be either a —SO₂— containing aliphatic cyclic group or a —SO₂— containing aromatic cyclic group. The —SO₂— containing cyclic group is preferably a —SO₂— containing aliphatic cyclic group.

Examples of the —SO₂— containing aliphatic cyclic group include a group that is obtained by removing at least one hydrogen atom from an aliphatic hydrocarbon ring in which part of carbon atoms forming its ring skeleton is substituted with —SO₂— or —O—SO₂—. More specifically, examples thereof include a group that is obtained by removing at least one hydrogen atom from an aliphatic hydrocarbon ring in which —CH₂— forming its ring skeleton is substituted with —SO₂—, a group that is obtained by removing at least one hydrogen atom from an aliphatic hydrocarbon ring in which —CH₂—CH₂— forming its ring is substituted with —O—SO₂— and the like.

The number of carbon atoms of the aliphatic hydrocarbon ring is preferably 3 or more and 20 or less and is more preferably 3 or more and 12 or less. The aliphatic hydrocarbon ring may be either polycyclic or monocyclic. As the monocyclic aliphatic hydrocarbon group, a group is preferable that is obtained by removing two hydrogen atoms from a monocycloalkane in which the number of carbon atoms is 3 or more and 6 or less. Examples of the monocycloalkane can include cyclopentane, cyclohexane and the like. As the polycyclic aliphatic hydrocarbon ring, a group is preferable that is obtained by removing two hydrogen atoms from a polycycloalkane in which the number of carbon atoms is 7 or more and 12 or less, and specific examples of the polycycloalkane include adamantane, norbornane, isobornane, tricyclodecane, tetracyclododecane and the like.

The —SO₂— containing cyclic group may include a substituent. Examples of the substituent include an alkyl group, an alkoxy group, a halogen atom, a halogenated alkyl group, a hydroxyl group, an oxygen atom (═O), —COOR″, —OC(═O)R″, a hydroxyalkyl group, a cyano group and the like.

As the alkyl group serving as the substituent, an alkyl group is preferable in which the number of carbon atoms is 1 or more and 6 or less. The alkyl group described above is preferably linear or branched. Specific examples thereof include a methyl group, an ethyl group, an n-propyl group, an isopropyl group, an n-butyl group, an isobutyl group, a tert-butyl group, an n-pentyl group, an isopentyl group, a neopentyl group, an n-hexyl group and the like. Among them, a methyl group and an ethyl group are preferable, and a methyl group is particularly preferable.

As the alkoxy group serving as the substituent described above, an alkoxy group is preferable in which the number of carbon atoms is 1 or more and 6 or less. The alkoxy group described above is preferably linear or branched. Specific examples thereof include a group in which the alkyl group serving as the substituent described above is bonded to an oxygen atom (—O—).

Examples of the halogen atom serving as the substituent described above include a fluorine atom, a chlorine atom, a bromine atom, an iodine atom and the like, and a fluorine atom is preferable.

Examples of the halogenated alkyl group serving as the substituent include a group in which part or all of hydrogen atoms in the alkyl group described above are substituted with the halogen atom described above.

Examples of the halogenated alkyl group serving as the substituent described above include a group in which part or all of hydrogen atoms in the alkyl group serving as the substituent described above are substituted with the halogen atom described above. As the halogenated alkyl group described above, a fluorinated alkyl group is preferable, and a perfluoroalkyl group is particularly preferable.

R″ in each of —COOR″ and —OC(═O)R″ described above is a hydrogen atom or a linear, branched or cyclic alkyl group in which the number of carbon atoms is 1 or more and 15 or less.

When R″ is a linear or branched alkyl group, the number of carbon atoms in the chained alkyl group is preferably 1 or more and 10 or less, is more preferably 1 or more and 5 or less and is particularly preferably 1 or 2.

When R″ is a cyclic alkyl group, the number of carbon atoms in the cyclic alkyl group is preferably 3 or more and 15 or less, is more preferably 4 or more and 12 or less and is particularly preferably 5 or more and 10 or less. Specific examples thereof can include a group that is obtained by removing one or more hydrogen atoms from a monocycloalkane which may or may not be substituted with a fluorine atom or a fluorinated alkyl group or a polycycloalkane such as bicycloalkane, tricycloalkane or tetracycloalkane and the like. More specific examples thereof include a group that is obtained by removing one or more hydrogen atoms from a monocycloalkane such as cyclopentane or cyclohexane or a polycycloalkane such as adamantane, norbornane, isobornane, tricyclodecane or tetracyclododecane.

As the hydroxyalkyl group serving as the substituent described above, a hydroxyalkyl group is preferable in which the number of carbon atoms is 1 or more and 6 or less. Specific examples thereof include a group in which at least one of hydrogen atoms in the alkyl group serving as the substituent described above is substituted with a hydroxyl group.

More specific examples of the —SO₂— containing cyclic group include groups represented by formulae (3-1) to (3-4) below.

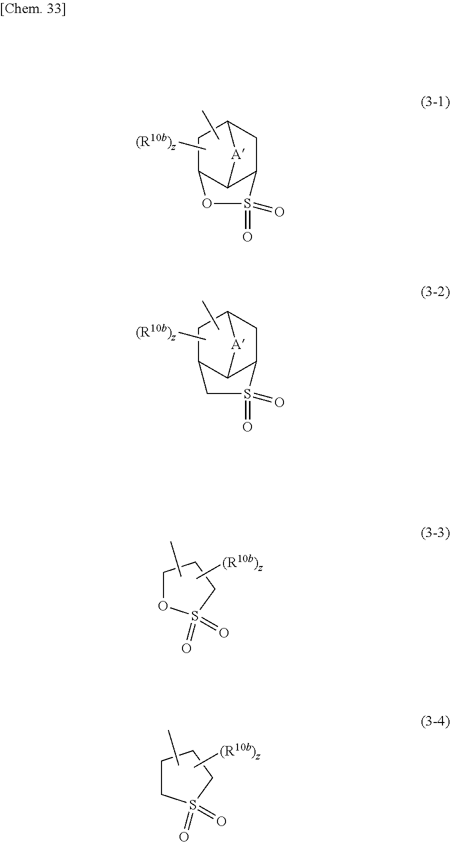

(where A′ represents an alkylene group which may include an oxygen atom or a sulfur atom and in which the number of carbon atoms is 1 or more and 5 or less, an oxygen atom or a sulfur atom, z represents an integer of 0 or more and 2 or less, R^{10b} represents an alkyl group, an alkoxy group, a halogenated alkyl group, a hydroxyl group, —COOR″, —OC(═O)R″, a hydroxyalkyl group or a cyano group and R″ represents a hydrogen atom or an alkyl group.)

In the above formulae (3-1) to (3-4), A′ represents an alkylene group which may include an oxygen atom (—O—) or a sulfur atom (—S—) and in which the number of carbon atoms is 1 or more and 5 or less, an oxygen atom or a sulfur atom. As the alkylene group in A′ in which the number of carbon atoms is 1 or more and 5 or less, a linear or branched alkylene group is preferable, and examples thereof include a methylene group, an ethylene group, an n-propylene group, an isopropylene group and the like.

When the alkylene group described above includes an oxygen atom or a sulfur atom, specific examples thereof include a group in which —O— or —S— is interposed in the terminal of the alkylene group described above or between carbon atoms, and examples thereof include —O—CH₂—, —CH₂—O—CH₂—, —S—CH₂—, —CH₂—S—CH₂— and the like. As A′, an alkylene group in which the number of carbon atoms is 1 or more and 5 or less or —O— is preferable, an alkylene group in which the number of carbon atoms is 1 or more and 5 or less is more preferable and a methylene group is most preferable.

Z may be either of 0, 1 and 2, and 0 is most preferable. When z is 2, a plurality of Riots may be the same as or different from each other.

As the alkyl group, the alkoxy group, the halogenated alkyl group, —COOR″, —OC(═O)R″ and the hydroxyalkyl group in R^{10b}, the same ones as the alkyl group, the alkoxy group, the halogenated alkyl group, —COOR″, —OC(═O)R″ and the hydroxyalkyl group mentioned as the substituents that may be included in the —SO₂— containing cyclic group are respectively mentioned.

Specific cyclic groups represented by formulae (3-1) to (3-4) described above will be illustrated below.

“Ac” in the formulae represents an acetyl group.

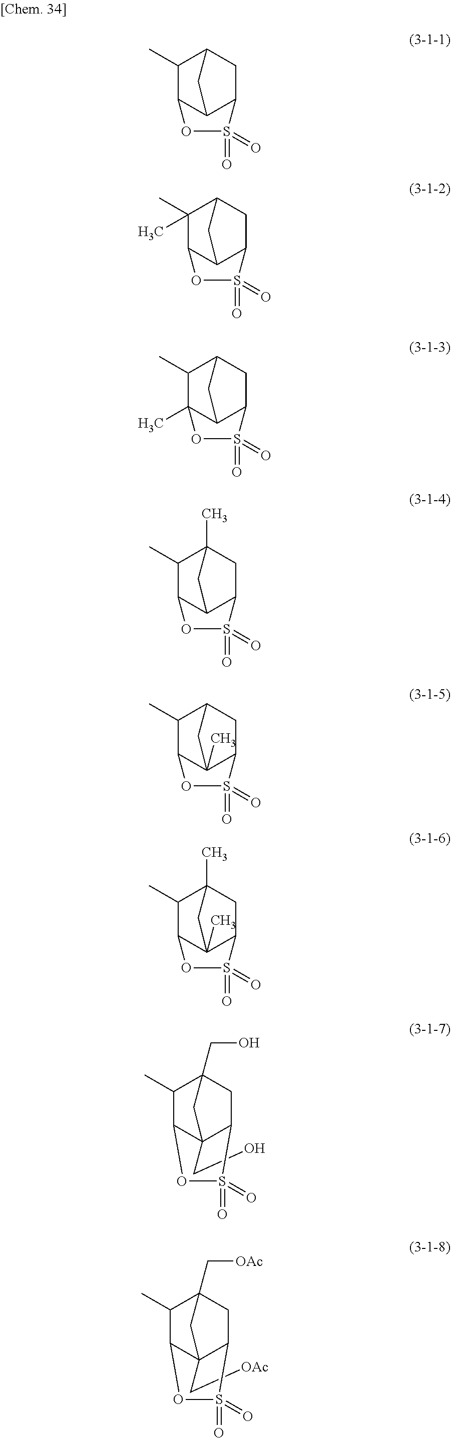

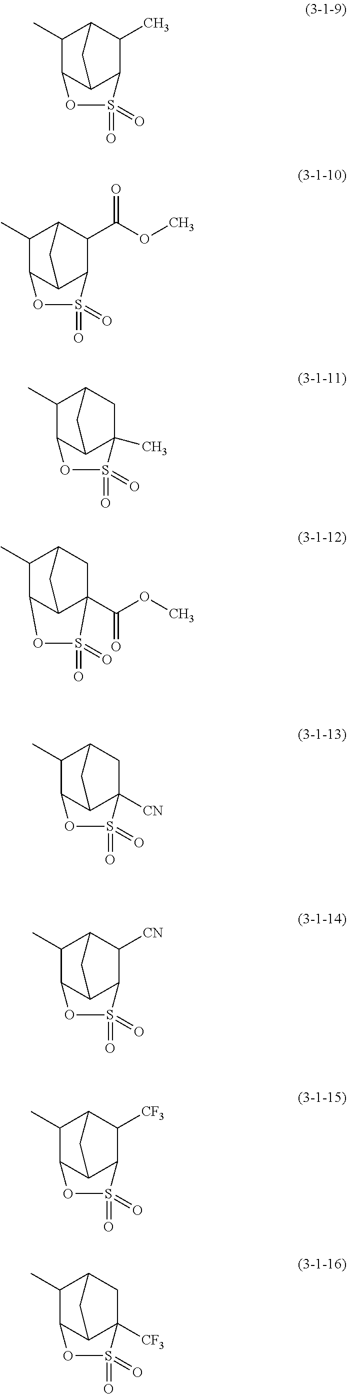

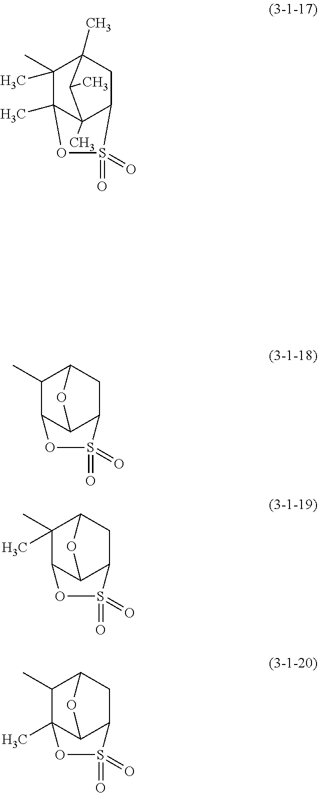

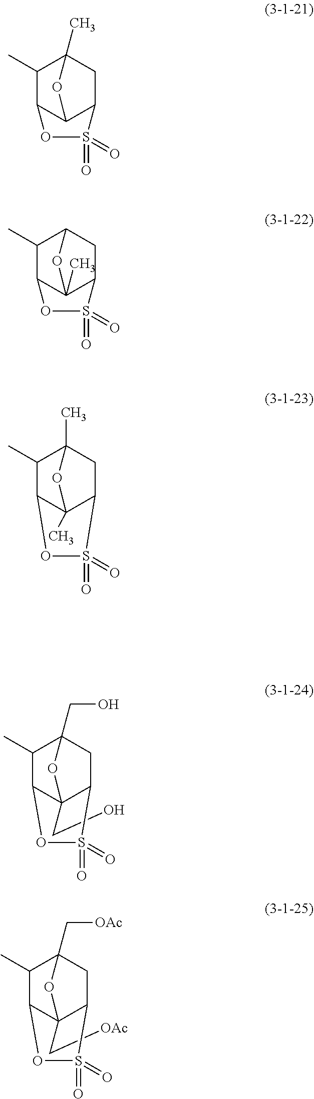 [SMILES: CC1C2OS(=O)(=O)C3CC1(C)OC23 ; CC1C2CC3C(C)(O2)C1OS3(=O)=O ; CC1C2OS(=O)(=O)C3CC1(C)OC23C ; CC1C2OS(=O)(=O)C3CC1(CO)OC23CO ; CC(=O)OCC12CC3C(COC(C)=O)(O1)C(OS3(=O)=O)C2C]

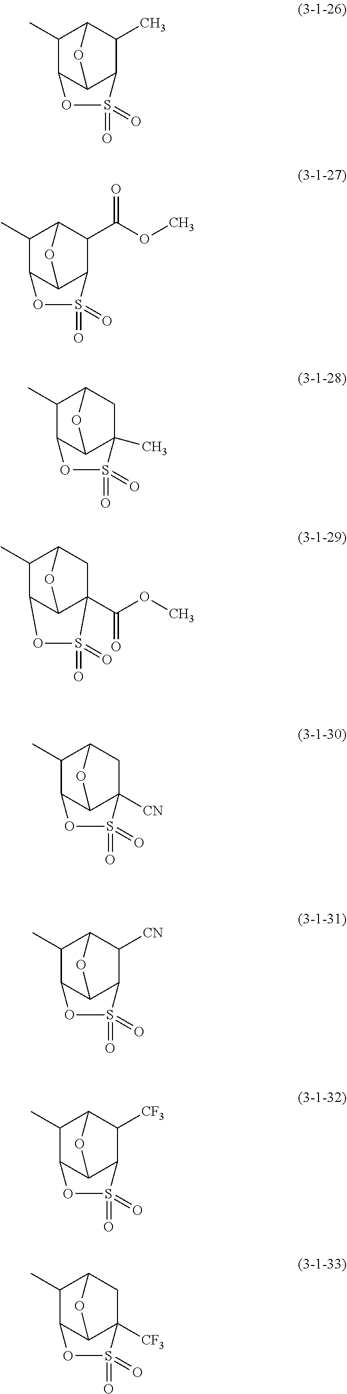

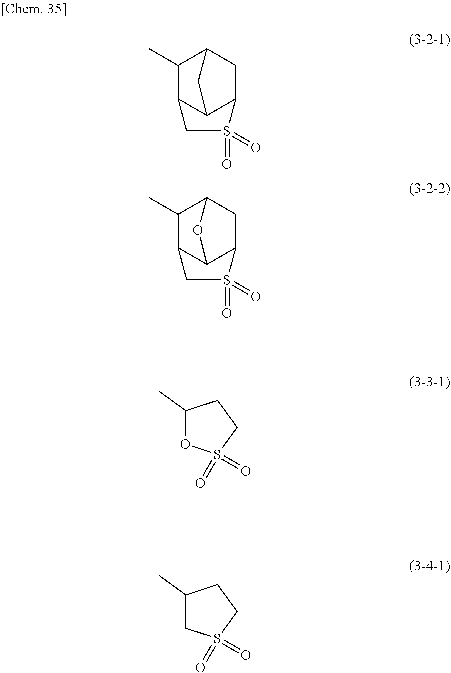

Among the —SO₂— containing cyclic groups described above, the group represented by formula (3-1) described above is preferable, at least one type selected from the group consisting of the groups represented by chemical formulae (3-1-1), (3-1-18), (3-3-1) and (3-4-1) described above is more preferable and the group represented by chemical formula (3-1-1) described above is most preferable.

### (Lactone-Containing Cyclic Group)

The “lactone-containing cyclic group” refers to a cyclic group which contains a ring (lactone) including —O—C(═O)— in its ring skeleton. When the lactone ring is counted as the first ring, and only this ring is provided, the lactone-containing cyclic group is referred to as a monocyclic group whereas when another ring structure is further provided, it is referred to as a polycyclic group regardless of its structure. The lactone-containing cyclic group may be either monocyclic or polycyclic.

The lactone cyclic group in the structural unit (b-3) is not particularly limited, and an arbitrary lactone cyclic group can be used. Specific examples of the lactone-containing monocyclic group include groups which are obtained by removing one hydrogen atom from 4 to 6 membered ring lactones, for example, a group which is obtained by removing one hydrogen atom from β-propionolactone, a group which is obtained by removing one hydrogen atom from γ-butyrolactone and a group which is obtained by removing one hydrogen atom from δ-valero lactone. Specific examples of the lactone-containing polycyclic group include groups which are obtained by removing one hydrogen atom from bicycloalkane, tricycloalkane and tetracycloalkane including lactone rings.

Although in the structural unit (b-3), the structure of the other parts is not particularly limited as long as the —SO₂— containing cyclic group or the lactone-containing cyclic group is included, at least one type of structural unit is preferable that is selected from the group consisting of a structural unit (b-3-S) which is derived from an acrylic ester where a hydrogen atom bonded to the α-position carbon atom may be substituted with a substituent and which includes the —SO₂— containing cyclic group and a structural unit (b-3-L) which is derived from an acrylic ester where a hydrogen atom bonded to the a-position carbon atom may be substituted with a substituent and which includes the lactone-containing cyclic group.

[Structural Unit (b-3-S)]

More specific examples of the structural unit (b-3-s) include a structural unit represented by formula (b-S1) below.

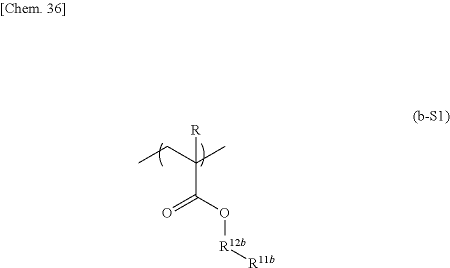

(where R represents a hydrogen atom, an alkyl group in which the number of carbon atoms is 1 or more and 5 or less or a halogenated alkyl group in which the number of carbon atoms is 1 or more and 5 or less, R^{11b} represents a —SO₂— containing cyclic group and R^{12b} represents a single bond or a divalent linking group.)

In formula (b-S1), R is the same as described above. R^{11b} is the same as the —SO₂— containing cyclic group described above. R^{12b} may be either a single bond or a divalent linking group. R^{12b} is preferably a divalent linking group such that the effects of the present invention are excellent.

Although the divalent linking group in R^{12b} is not particularly limited, preferred examples thereof include a divalent hydrocarbon group which may include a substituent, a divalent linking group which includes a hetero atom and the like.

Divalent Hydrocarbon Group which May Include a Substituent

The hydrocarbon group serving as the divalent linking group may be either an aliphatic hydrocarbon group or an aromatic hydrocarbon group. The aliphatic hydrocarbon group means a hydrocarbon group which does not have aromaticity. The aliphatic hydrocarbon group may be either saturated or unsaturated. In general, a saturated hydrocarbon group is preferable. More specific examples of the aliphatic hydrocarbon group include linear and branched aliphatic hydrocarbon groups, an aliphatic hydrocarbon group which includes a ring in its structure and the like.

The number of carbon atoms of the linear or branched aliphatic hydrocarbon group is preferably 1 or more and 10 or less, is more preferably 1 or more and 8 or less and is further preferably 1 or more and 5 or less.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like.

As the branched aliphatic hydrocarbon group, a branched alkylene group is preferable. Specific examples thereof include alkyl alkylene groups such as: alkyl methylene groups such as —CH(CH₃)—, —CH(CH₂CH₃)—, —C(CH³)²—, —C(CH³)(CH₂CH³)—, —C(CH₃)(CH₂CH₂CH₃)— and —C(CH₂CH₃)₂—; alkyl ethylene groups such as —CH(CH₃)CH₂, —CH(CH₃)CH(CH₃)—, —C(CH₃)₂CH₂—, —CH(CH₂CH 3)CH₂— and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂— and the like. As the alkyl group in the alkyl alkylene group, a linear alkyl group is preferable in which the number of carbon atoms is 1 or more and 5 or less.

The linear or branched aliphatic hydrocarbon group described above may include or may not include a substituent (group or atom other than a hydrogen atom) which substitutes a hydrogen atom. Examples of the substituent include a fluorine atom, a fluorinated alkyl group which is substituted with a fluorine atom and in which the number of carbon atoms is 1 or more and 5 or less, an oxo group (═O) and the like.

Examples of the aliphatic hydrocarbon group which includes a ring in its structure described above include: a cyclic aliphatic hydrocarbon group which may include a substituent that includes a hetero atom in a ring structure (group obtained by removing two hydrogen atoms from an aliphatic hydrocarbon ring); a group in which the cyclic aliphatic hydrocarbon group is bonded to the terminal of a linear or branched aliphatic hydrocarbon group; a group in which the cyclic aliphatic hydrocarbon group is interposed partway in a linear or branched aliphatic hydrocarbon group; and the like. Examples of the linear or branched aliphatic hydrocarbon group described above include the same ones as described above.

The number of carbon atoms of the cyclic aliphatic hydrocarbon group is preferably 3 or more and 20 or less and is more preferably 3 or more and 12 or less.

The cyclic aliphatic hydrocarbon group may be either polycyclic or monocyclic. As the monocyclic aliphatic hydrocarbon group, a group is preferable which is obtained by removing two hydrogen atoms from a monocycloalkane. The number of carbon atoms of the monocycloalkane is preferably 3 or more and 6 or less. Specific examples thereof include cyclopentane, cyclohexane and the like. As the polycyclic aliphatic hydrocarbon group, a group is preferable which is obtained by removing two hydrogen atoms from a polycycloalkane. The number of carbon atoms of the polycycloalkane is 7 or more and 12 or less. Specific examples thereof include adamantane, norbornane, isobornane, tricyclodecane, tetracyclododecane and the like.

The cyclic aliphatic hydrocarbon group may include or may not include a substituent (group or atom other than a hydrogen atom) which substitutes a hydrogen atom. Examples of the substituent include an alkyl group, an alkoxy group, a halogen atom, a halogenated alkyl group, a hydroxyl group, an oxo group (═O) and the like.

As the alkyl group serving as the substituent, an alkyl group is preferable in which the number of carbon atoms is 1 or more and 5 or less, and a methyl group, an ethyl group, a propyl group, an n-butyl group, an isobutyl group and a tert-butyl group are more preferable.

As the alkoxy group serving as the substituent described above, an alkoxy group is preferable in which the number of carbon atoms is 1 or more and 5 or less, a methoxy group, an ethoxy group, an n-propoxy group, an iso-propoxy group, an n-butoxy group and a tert-butoxy group are more preferable and a methoxy group and an ethoxy group are particularly preferable.

Examples of the halogen atom serving as the substituent described above include a fluorine atom, a chlorine atom, a bromine atom, an iodine atom and the like, and a fluorine atom is preferable.

Examples of the halogenated alkyl group serving as the substituent described above include a group in which part or all of hydrogen atoms in the alkyl group described above are substituted with the halogen atom described above.

In the cyclic aliphatic hydrocarbon group, part of carbon atoms forming its ring structure may be substituted with —O— or —S—. As the substituent which includes the hetero atom described above, —O—, —C(═O)—O—, —S—, —S(O═)₂— or —S(O═)₂—O— are preferable.

The aromatic hydrocarbon group serving as the divalent hydrocarbon group is a divalent hydrocarbon group which includes at least one aromatic ring, and may include a substituent. The aromatic ring is not particularly limited as long as it is a cyclic conjugated system which includes (4n+2) n electrons, and the aromatic ring may be either monocyclic or polycyclic. The number of carbon atoms of the aromatic ring is preferably 5 or more and 30 or less, is more preferably 5 or more and 20 or less, is further preferably 6 or more and 15 or less and is particularly preferably 6 or more and 12 or less. However, the number of carbon atoms thereof does not include the number of carbon atoms of the substituent.

Specific examples of the aromatic ring include: aromatic hydrocarbon rings such as benzene, naphthalene, anthracene and phenanthrene; an aromatic heterocycle in which part of hydrogen atoms forming the aromatic hydrocarbon ring is substituted with a hetero atom; and the like. Examples of the hetero atom in the aromatic heterocycle include an oxygen atom, a sulfur atom, a nitrogen atom and the like. Specific examples of the aromatic heterocycle include a pyridine ring, a thiophene ring and the like.

Specific examples of the aromatic hydrocarbon group serving as the divalent hydrocarbon group include: a group which is obtained by removing two hydrogen atoms from the aromatic hydrocarbon ring or the aromatic heterocycle described above (arylene group or heteroarylene group); a group which is obtained by removing two hydrogen atoms from an aromatic compound (for example, biphenyl or fluorene) including two or more aromatic rings; a group in which one of hydrogen atoms in the group that is obtained by removing one hydrogen atom from the aromatic hydrocarbon ring or the aromatic heterocycle described above (aryl group or heteroaryl group) is substituted with an alkylene group (for example, a group which is obtained by further removing one hydrogen atom from an aryl group in an arylalkyl group such as a benzyl group, a phenethyl group, 1-naphthylmethyl group, 2-naphthylmethyl group, 1-naphthylethyl group or 2-naphthylethyl group); and the like.

The number of carbon atoms of the alkylene group bonded to the aryl group or heteroaryl group described above is preferably 1 or more and 4 or less, is more preferably 1 or more and 2 or less and is particularly preferably 1.

In the aromatic hydrocarbon group described above, the hydrogen atom included in the aromatic hydrocarbon group described above may be substituted with a substituent. For example, the hydrogen atom bonded to the aromatic ring in the aromatic hydrocarbon group described above may be substituted with a substituent. Examples of the substituent described above include an alkyl group, an alkoxy group, a halogen atom, a halogenated alkyl group, a hydroxyl group, an oxo group (═O) and the like.

As the alkyl group serving as the substituent described above, an alkyl group is preferable in which the number of carbon atoms is 1 or more and 5 or less, and a methyl group, an ethyl group, an n-propyl group, an n-butyl group and a tert-butyl group are more preferable.

As the alkoxy group serving as the substituent described above, an alkoxy group is preferable in which the number of carbon atoms is 1 or more and 5 or less, a methoxy group, an ethoxy group, an n-propoxy group, an iso-propoxy group, an n-butoxy group and a tert-butoxy group are preferable and a methoxy group and an ethoxy group are more preferable.

Examples of the halogen atom serving as the substituent described above include a fluorine atom, a chlorine atom, a bromine atom, an iodine atom and the like, and a fluorine atom is preferable.

Examples of the halogenated alkyl group serving as the substituent described above include a group in which part or all of hydrogen atoms in the alkyl group described above are substituted with the halogen atom described above.

Divalent Linking Group Including Hetero Atom

The hetero atom in the divalent linking group including the hetero atom is an atom other than a carbon atom and a hydrogen atom, and examples thereof include an oxygen atom, a nitrogen atom, a sulfur atom, a halogen atom and the like.

Specific examples of the divalent linking group including the hetero atom include: non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)— and ═N—; combinations of at least one type of these non-hydrocarbon based linking groups and the divalent hydrocarbon group; and the like. Examples of the divalent hydrocarbon group described above include the same as the divalent hydrocarbon group which may include the substituent described above, and a linear or branched aliphatic hydrocarbon group is preferable.

Among those described above, —NH— in —C(═O)—NH—, and Hs in —NH— or —NH—C(═NH)— may be individually substituted with a substituent such as an alkyl group or an acyl group. The number of carbon atoms of the substituent described above is preferably 1 or more and 10 or less, is more preferably 1 or more and 8 or less and is particularly preferably 1 or more and 5 or less.

As the divalent linking group in Rib, a linear or branched alkylene group, a cyclic aliphatic hydrocarbon group or a divalent linking group including a hetero atom is particularly preferable.

When the divalent linking group in R^{12b} is a linear or branched alkylene group, the number of carbon atoms of the alkylene group is preferably 1 or more and 10 or less, is more preferably 1 or more and 6 or less, is particularly preferably 1 or more and 4 or less and is most preferably 1 or more and 3 or less. Specific examples thereof include the same ones as the linear alkylene group and the branched alkylene group mentioned as the linear or branched aliphatic hydrocarbon group in the description of the “divalent hydrocarbon group which may include a substituent” serving as the divalent linking group described above.

When the divalent linking group in R^{12b} is a cyclic aliphatic hydrocarbon group, examples of the cyclic aliphatic hydrocarbon group include the same as the cyclic aliphatic hydrocarbon group mentioned as the “aliphatic hydrocarbon group which includes a ring in its structure” in the description of the “divalent hydrocarbon group which may include a substituent” serving as the divalent linking group described above.

As the cyclic aliphatic hydrocarbon group described above, a group which is obtained by removing two or more hydrogen atoms from cyclopentane, cyclohexane, norbornane, isobornane, adamantane, tricyclodecane or tetracyclododecane is particularly preferable.

When the divalent linking group in R^{12b} is a divalent linking group including a hetero atom, examples of the preferable linking group described above include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, groups which are represented by general formulae of —Y¹—O—Y²—, —[Y¹—C(═O)—O]_{m′}—Y²— and —Y¹—O—C(═O)—Y²— [where Y¹ and Y² each represent a divalent hydrocarbon group which may independently include a substituent, O represents an oxygen atom and m′ represents an integer of 0 or more and 3 or less] and the like.

When the divalent linking group in R^{12b} is —NH—, a hydrogen atom in —NH— may be substituted with a substituent such as an alkyl group or an acyl group. The number of carbon atoms of the substituent (such as an alkyl group or an acyl group) is preferably 1 or more and 10 or less, is more preferably 1 or more and 8 or less and is particularly preferably 1 or more and 5 or less.

In the formulae of —Y¹—O—Y²—, —[Y¹—C(═O)—O]_{m′}—Y²— and —Y¹—O—C(═O)—Y²—, Y¹ and Y² each represent a divalent hydrocarbon group which may independently include a substituent. Examples of the divalent hydrocarbon group described above include the same as the “divalent hydrocarbon group which may include a substituent” mentioned in the description of the divalent linking group described above.

As Y¹, a linear aliphatic hydrocarbon group is preferable, a linear alkylene group is more preferable, a linear alkylene group in which the number of carbon atoms is 1 or more and 5 or less is more preferable and a methylene group and an ethylene group are particularly preferable.

As Y², a linear or branched aliphatic hydrocarbon group is preferable, and a methylene group, an ethylene group and an alkyl methylene group are more preferable. As the alkyl group in the alkyl methylene group, a linear alkyl group in which the number of carbon atoms is 1 or more and 5 or less is preferable, a linear alkyl group in which the number of carbon atoms is 1 or more and 3 or less is more preferable and a methyl group is particularly preferable.

In the group represented by the formula of —[Y¹—C(═O)—O]_{m′}—Y²—, m′ is an integer of 0 or more and 3 or less, is preferably an integer of 0 or more and 2 or less, is more preferably 0 or 1 and is particularly preferably 1. In other words, as the group represented by the formula of —[Y¹—C(═O)—O]_{m′}—Y²—, a group represented by the formula of —Y¹—C(═O)—O—Y²— is particularly preferable. Among them, a group represented by the formula of —(CH₂)_{a′}—C(═O)—O—(CH₂)_{b′}— is preferable. In the formula described above, a′ is an integer of 1 or more and 10 or less, is preferably an integer of 1 or more and 8 or less, is more preferably an integer of 1 or more and 5 or less, is further preferably 1 or 2 and is most preferably 1. b′ is an integer of 1 or more and 10 or less, is preferably an integer of 1 or more and 8 or less, is more preferably an integer of 1 or more and 5 or less, is further preferably 1 or 2 and is most preferably 1.

With respect to the divalent linking group in R^{12b}, as the divalent linking group including the hetero atom, organic groups formed by combinations of at least one type of non-hydrocarbon group and a divalent hydrocarbon group are preferable. Among them, a linear group which includes an oxygen atom as a hetero atom, for example, a group which includes an ether bond or an ester bond is preferable, a group represented by the formula of —Y¹—O—Y²—, —[Y¹—C(═O)—O]_{m′}—Y²— or —Y¹—O—C(═O)—Y²— is more preferable and a group represented by the formula of —[Y¹—C(═O)—O]_{m′}—Y²— or —Y¹—O—C(═O)—Y²— is particularly preferable.

As the divalent linking group in Rib, an alkylene group or a divalent linking group including an ester bond (—C(C═O)—O—) is preferable.

As the alkylene group described above, a linear or branched alkylene group is preferable. Preferred examples of the linear aliphatic hydrocarbon group described above include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like. Preferred examples of the branched alkylene group described above include alkyl alkylene groups such as: alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkyl ethylene groups such as —CH(CH₃)CH₂, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH (CH₃)CH₂—; and alkyl tetramethylene groups such as —CH(CH₃)CH₂CH₂CH₂— and —CH₂CH(CH₃)CH₂CH₂— and the like.

As the divalent linking group including the ester bond, a group represented by the formula of —R^{13b}—C(═O)—O—[where —R^{13b} represents a divalent linking group] is particularly preferable. In other words, the structural unit (b-3-S) is preferably a structural unit which is represented by formula (b-S1-1) below.

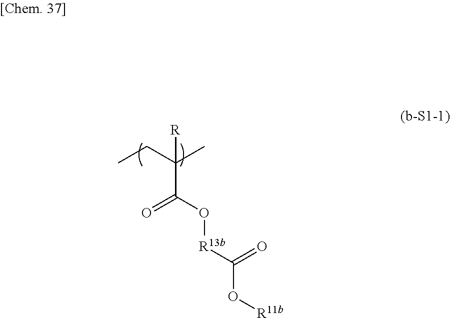

(where R and R^{11b} each are the same as described above, and R^{13b} represents a divalent linking group.)

R^{13b} is not particularly limited, and examples thereof include the same as the divalent linking group in R^{12b} described above. As the divalent linking group in R^{13b}, a linear or branched alkylene group, an aliphatic hydrocarbon group including a ring in its structure or a divalent linking group including a hetero atom is preferable, and a linear or branched alkylene group or a divalent linking group including an oxygen atom as a hetero atom is preferable.

As the linear alkylene group, a methylene group or an ethylene group is preferable, and a methylene group is particularly preferable. As the branched alkylene group, an alkyl methylene group or an alkyl ethylene group is preferable, and —CH(CH₃)—, —CH(CH₃)₂— or C(CH₃)₂—CH₂— is particularly preferable.

As the divalent linking group including an oxygen atom, a divalent linking group including an ether bond or an ester bond is preferable, and —Y¹—O—Y²—, —[Y¹—C(═O)—O]_{m′}—Y²— or —Y¹—O—C(═O)—Y²— described above is more preferable. Y¹ and Y² each represent a divalent hydrocarbon group which may independently include a substituent, and m′ represents an integer of 0 or more and 3 or less. Among them, —Y¹—O—C(═O)—Y²— is preferable, and a group represented by —(CH₂)_{c}—O—C(═O)—(CH₂)_{d}— is particularly preferable.

c represents an integer of 1 or more and 5 or less, and preferably represents 1 or 2.

d represents an integer of 1 or more and 5 or less, and preferably represents 1 or 2.

As the structural unit (b-3-S), a structural unit represented by formula (b-S1-11) or (b-S1-12) below is particularly preferable, and a structural unit represented by formula (b-S1-12) is more preferable.

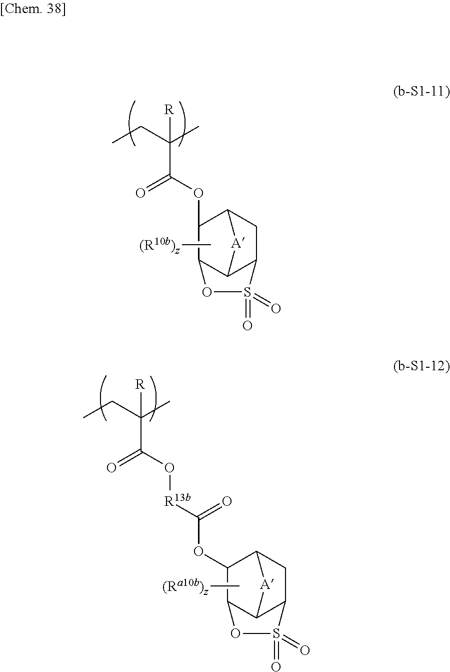

(where R, A′, R^{10b}, z and R^{13b} each represent the same ones as described above.)

In formula (b-S1-11), A′ is preferably a methylene group, an oxygen atom (—O—) or a sulfur atom (—S—).

As R^{13b}, a linear or branched alkylene group or a divalent linking group including an oxygen atom is preferable. As the linear or branched alkylene group and the divalent linking group including an oxygen atom in R^{13b}, the same ones as the linear or branched alkylene group and the divalent linking group including an oxygen atom described above are respectively mentioned.

As the structural unit represented by formula (b-S1-12), a structural unit represented by formula (b-S1-12a) or (b-S1-12b) below is particularly preferable.

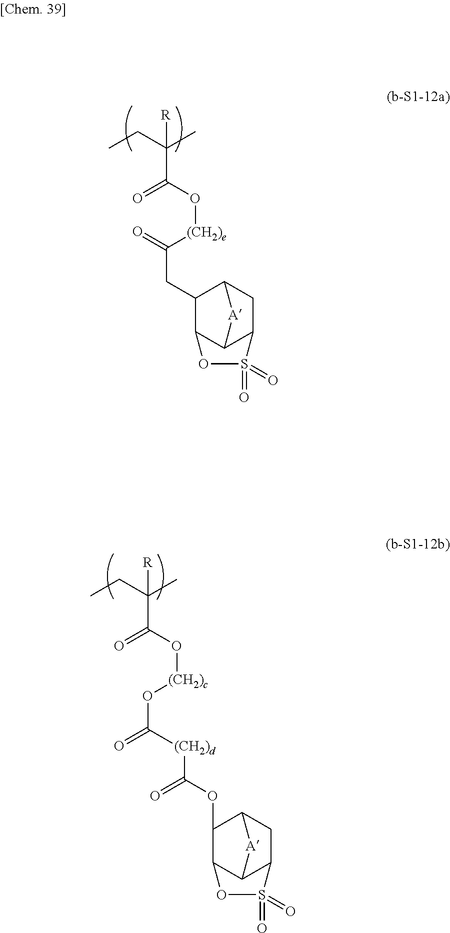

(where R and A′ each represent the same ones as described above, and c to e each independently represent an integer of 1 or more and 3 or less.)
[Structural Unit (b-3-L)]

Examples of the structural unit (b-3-L) include a structural unit in which R^{11b} in formula (b-S1) described above is substituted with a lactone-containing cyclic group, and specific examples thereof include structural units represented by formulae (b-L1) to (b-L5) below.

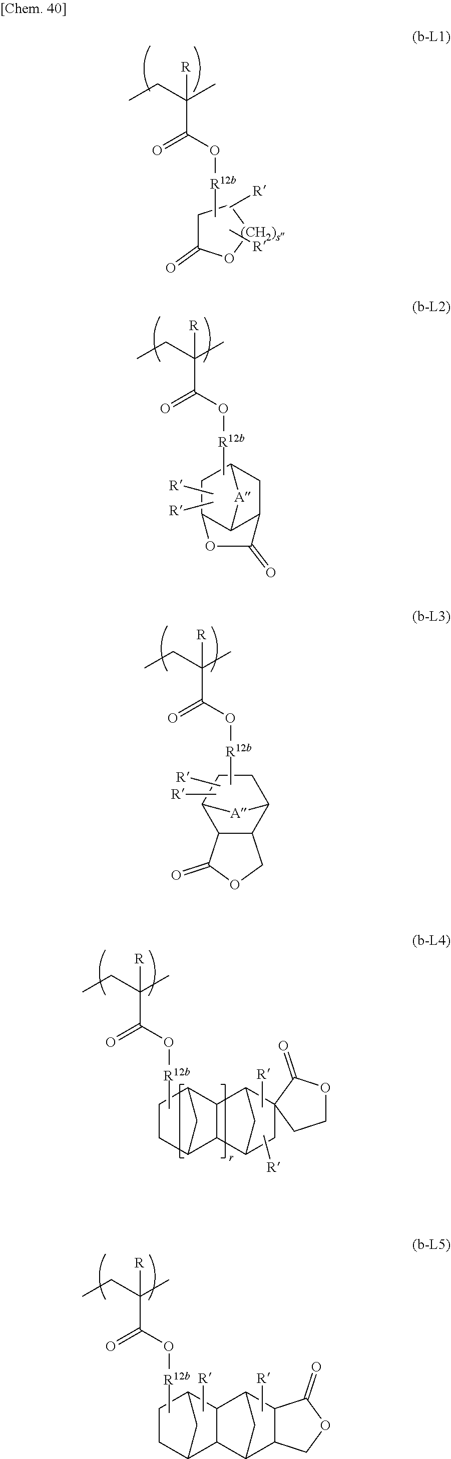

(where R represents a hydrogen atom, an alkyl group in which the number of carbon atoms is 1 or more and 5 or less or a halogenated alkyl group in which the number of carbon atoms is 1 or more and 5 or less; R's each independently represent a hydrogen atom, an alkyl group, an alkoxy group, a halogenated alkyl group, a hydroxyl group, —COOR″, —OC(═O)R″, a hydroxyalkyl group or a cyano group, and R″ represents a hydrogen atom or an alkyl group; R^{12b} represents a single bond or a divalent linking group and s″ represents an integer of 0 or more and 2 or less; A″ represents an alkylene group which may include an oxygen atom or a sulfur atom and in which the number of carbon atoms is 1 or more and 5 or less, an oxygen atom or a sulfur atom; and r represents 0 or 1.)

R in formulae (b-L1) to (b-L5) is the same as described above. As the alkyl group, the alkoxy group, the halogenated alkyl group, —COOR″, —OC(═O)R″ and the hydroxyalkyl group in R′, the same ones as the alkyl group, the alkoxy group, the halogenated alkyl group, —COOR″, —OC(═O)R″ and the hydroxyalkyl group mentioned as the substituents that may be included in the —SO₂— containing cyclic group are respectively mentioned.

With consideration given to ease of availability in industry, R′ is preferably a hydrogen atom. The alkyl group in R″ may be linear, branched or cyclic. When R″ is a linear or branched alkyl group, the number of carbon atoms is preferably 1 or more and 10 or less, and is further preferably 1 or more and 5 or less. When R″ is a cyclic alkyl group, the number of carbon atoms is preferably 3 or more and 15 or less, is further preferably 4 or more and 12 or less and is most preferably 5 or more and 10 or less. Specific examples thereof can include a group that is obtained by removing one or more hydrogen atoms from a monocycloalkane which may or may not be substituted with a fluorine atom or a fluorinated alkyl group or a polycycloalkane such as bicycloalkane, tricycloalkane or tetracycloalkane and the like. Specific examples thereof include a group that is obtained by removing one or more hydrogen atoms from a monocycloalkane such as cyclopentane or cyclohexane or a polycycloalkane such as adamantane, norbornane, isobornane, tricyclodecane or tetracyclododecane and the like. Examples of A″ include the same as A′ in formula (3-1) described above. A″ is preferably an alkylene group in which the number of carbon atoms is 1 or more and 5 or less, an oxygen atom (—O—) or a sulfur atom (—S—), and is more preferably an alkylene group in which the number of carbon atoms is 1 or more and 5 or less or —O—. As the alkylene group in which the number of carbon atoms is 1 or more and 5 or less, a methylene group or a dimethylmethylene group is more preferable, and a methylene group is most preferable.

R^{12b} is the same as R^{12b} in formula (b-S1) described above. In formula (b-L1), s″ is preferably 1 or 2. Specific examples of the structural units represented in formulae (b-L1) to (b-L3) described above will be described below. In each of the formulae below, Ra represents a hydrogen atom, a methyl group or a trifluoromethyl group.

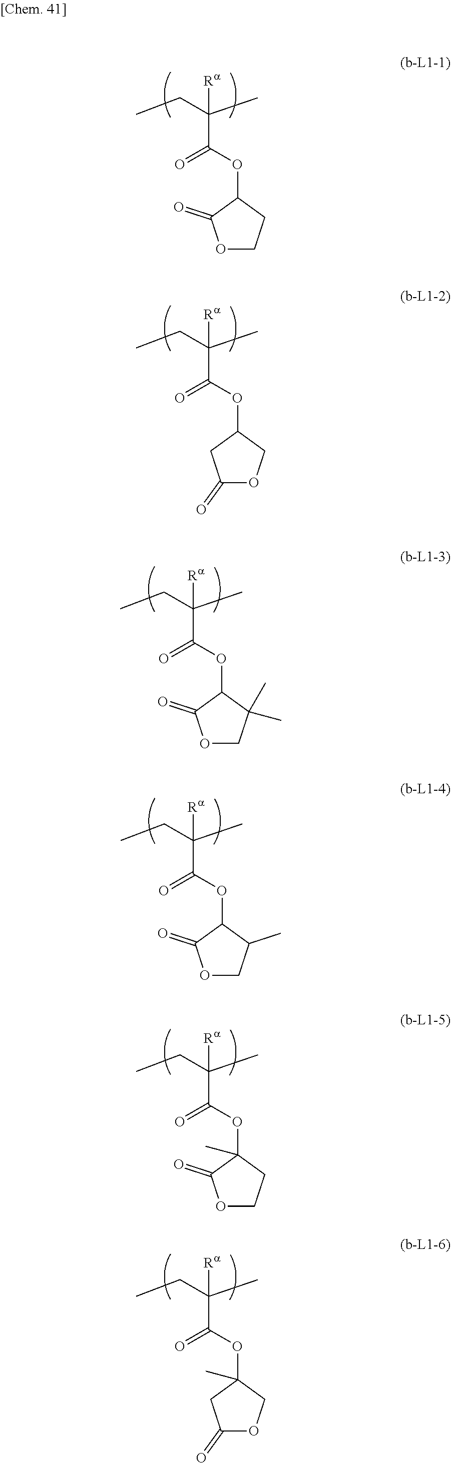

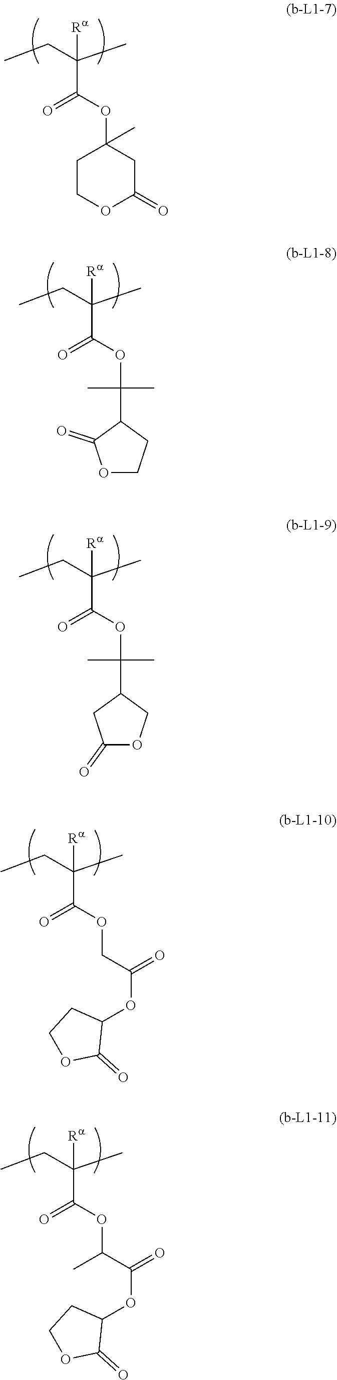

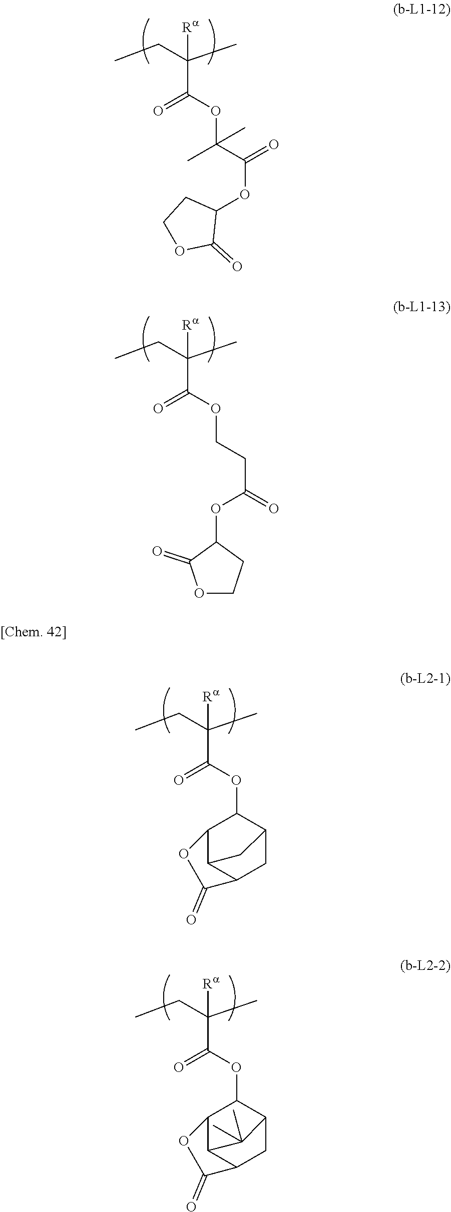

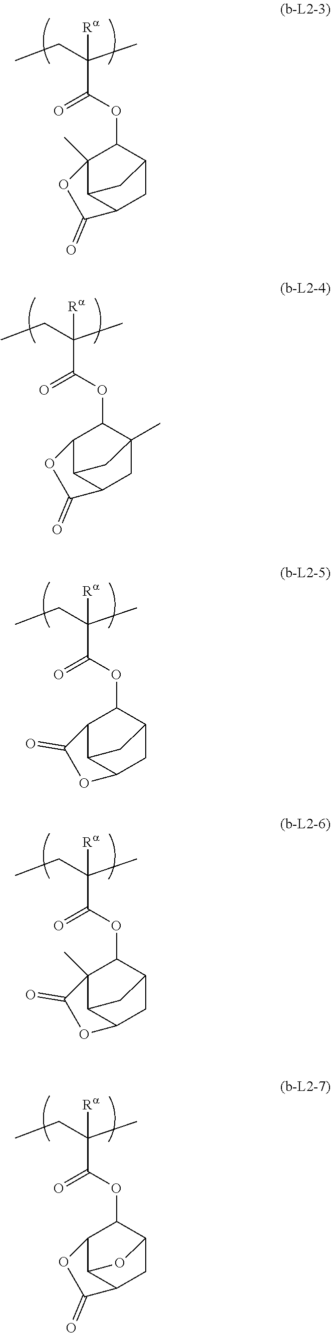

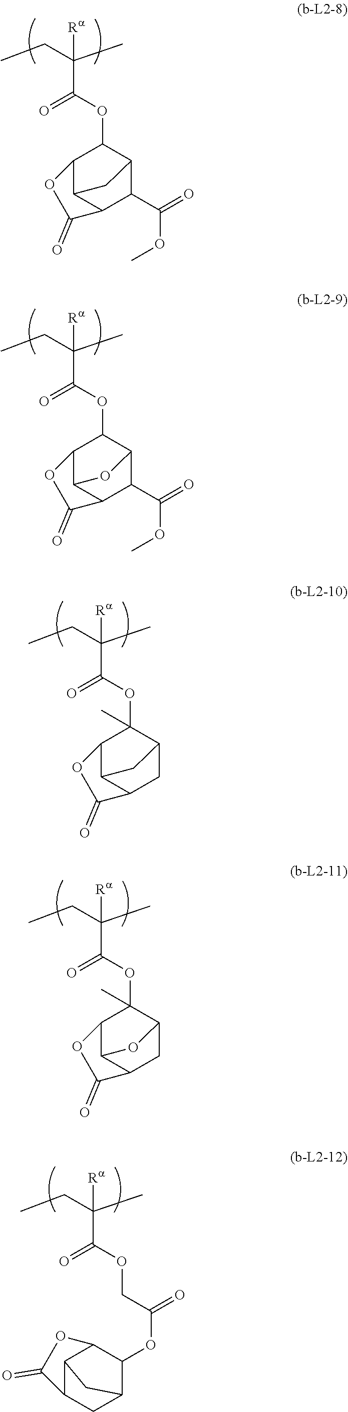

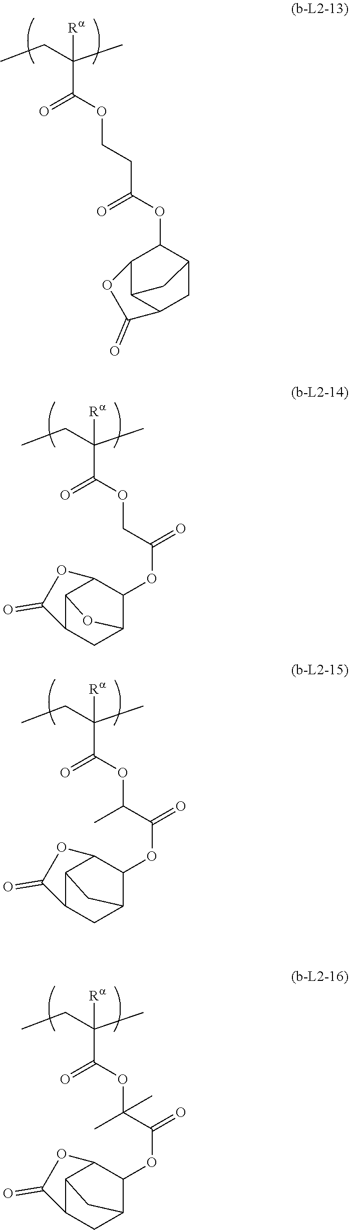

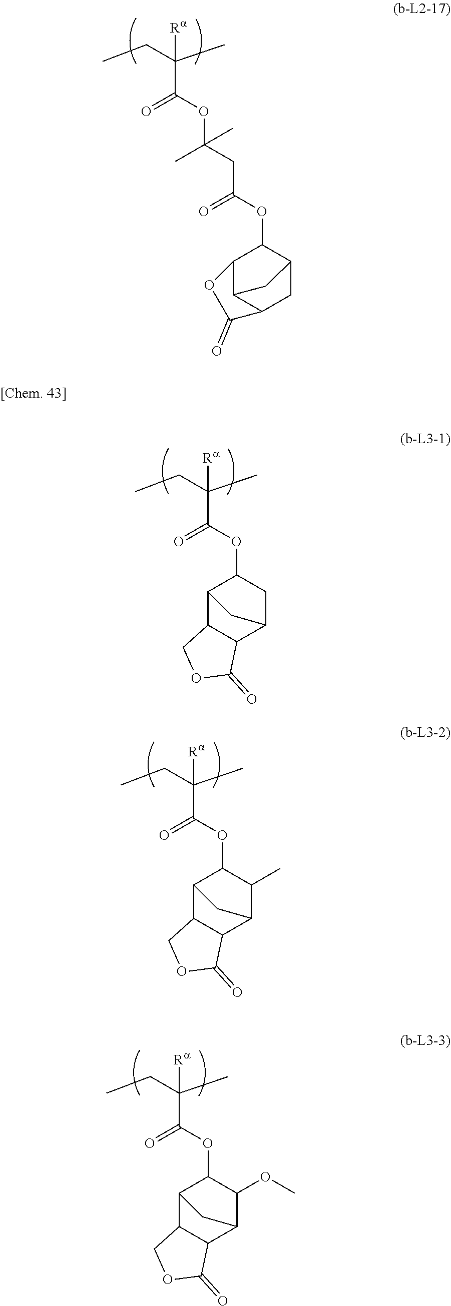

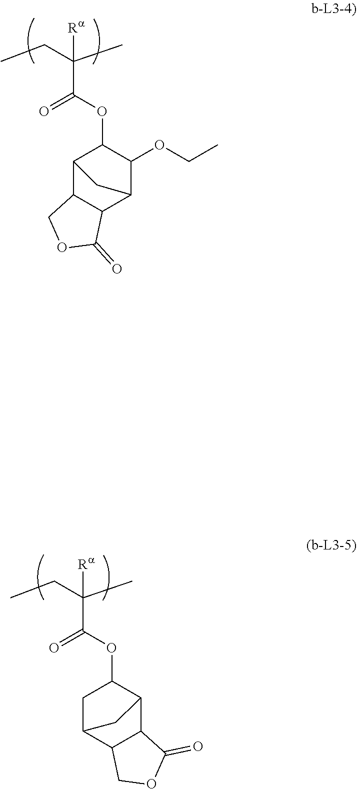

As the structural unit (b-3-5), at least one type selected from the group consisting of the structural units represented by formulae (b-L1) to (b-15) described above is preferable, at least one type selected from the group consisting of the structural units represented by formulae (b-L1) to (b-L3) described above is more preferable and at least one type selected from the group consisting of the structural units represented by formula (b-L1) or (b-L3) described above is particularly preferable. Among them, at least one type selected from the group consisting of the structural units represented by formulae (b-L1-1), (b-L1-2), (b-L2-1), (b-L2-7), (b-L2-12), (b-L2-14), (b-L3-1) and (b-L3-5) is preferable.

As the structural unit (b-3-L), structural units represented by formulae (b-L6) and (b-L7) below are also preferable.

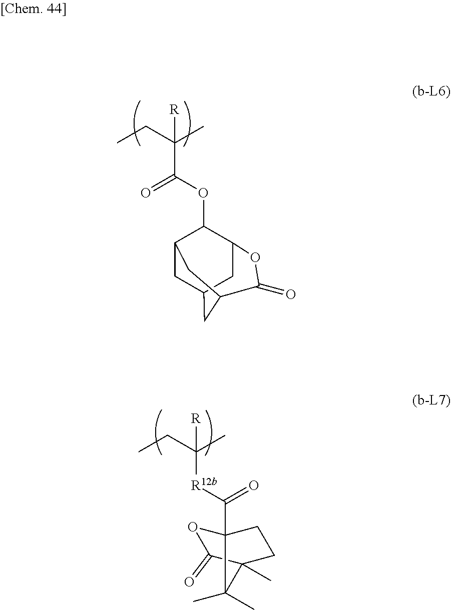

In formulae (b-L6) and (b-L7), R and R^{12b} represent the same ones as described above.

In addition, the acrylic resin (B3) may include a constituent unit represented by the following formulae (b5) to (b7) having an acid dissociable group as a constituent unit that increases alkali solubility of the acrylic resin (B3) under action of an acid. However, from the viewpoint of further suppressing footing of the resist pattern, it is preferable that the constituent unit represented by formula (b5) is not included.

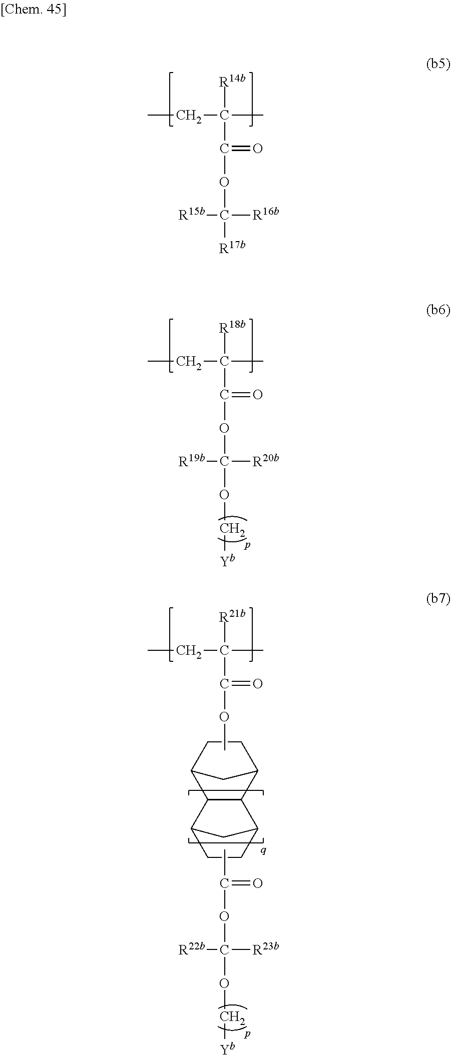

R^{14b} and R^{18b} to R^{23b} in the above formulae (b5) to (b7) each are independently a hydrogen atom, a linear or branched alkyl group having 1 or more and 6 or less carbon atoms, a fluorine atom or a linear or branched fluorinated alkyl group having 1 or more and 6 or less carbon atoms, R^{15b} to R^{17b} each are independently a linear or branched alkyl group having 1 or more and 6 or less carbon atoms, a linear or branched fluorinated alkyl group having 1 or more and 6 or less carbon atoms or an aliphatic cyclic group having 5 or more and 20 or less carbon atoms, Y^{b} represents an aliphatic cyclic group or an alkyl group which may include a substituent, p represents an integer of 0 or more and 4 or less and q represents 0 or 1.

Examples of the linear or branched alkyl group include a methyl group, ethyl group, propyl group, isopropyl group, n-butyl group, isobutyl group, tert-butyl group, pentyl group, isopentyl group, neopentyl group, and the like. The fluorinated alkyl group refers to the abovementioned alkyl groups of which the hydrogen atoms are partially or entirely substituted with fluorine atoms. Specific examples of the aliphatic cyclic group include a group in which one or more hydrogen atoms are removed from monocycloalkanes and polycycloalkanes such as bicycloalkanes, tricycloalkanes, and tetracycloalkanes. Specific examples thereof include a group in which one hydrogen atom is removed from monocycloalkanes such as cyclopentane, cyclohexane, cycloheptane, and cyclooctane, and polycycloalkanes such as adamantane, norbornane, isobornane, tricyclodecane, and tetracyclododecane. In particular, cyclohexane and adamantane from which one hydrogen atom is removed (optionally further having a substituent) are preferable.

A linear or branched alkyl group having 2 or more and 4 or less carbon atoms is preferable as R^{15b}, R^{16b}, and R^{17b} in view of high contrast, satisfactory resolution, satisfactory focal depth-width and the like. As R^{19b}, R^{20b}, R^{22b} and R^{23b}, a hydrogen atom or a methyl group is preferable.

Furthermore, in a case where an aliphatic cyclic group formed with R^{16b} and R^{17b} has a substituent on the ring skeleton thereof, examples of the substituent described above include a polar group such as a hydroxyl group, a carboxyl group, a cyano group and an oxygen atom (═O), and a linear or branched alkyl group having 1 or more and 4 or less carbon atoms. As the polar group, an oxygen atom (═O) is particularly preferable.

Y^{b} described above is an alicyclic group or an alkyl group; and examples thereof are monocycloalkanes and polycycloalkanes such as bicycloalkanes, tricycloalkanes, and tetracycloalkanes from which at least one hydrogen atom is removed. Specific examples thereof are monocycloalkanes such as cyclopentane, cyclohexane, cycloheptane, and cyclooctane, and polycycloalkanes such as adamantane, norbornane, isobornane, tricyclodecane, and tetracyclododecane, from which at least one hydrogen atom is removed. Particularly preferable is adamantane from which at least one hydrogen atom is removed (that may further include a substituent).

In addition, when the alicyclic group of Y^{b} described above has a substituent on the ring skeleton, the substituent described above is exemplified by polar groups such as a hydroxide group, a carboxyl group, a cyano group, and an oxygen atom (═O) and linear or branched lower alkyl groups having 1 or more and 4 or less carbon atoms. The polar group is preferably an oxygen atom (═O) in particular.

Furthermore, when Y^{b} is an alkyl group, it is preferably a linear or branched alkyl group having 1 or more and 20 or less carbon atoms, and more preferably 6 or more and 15 or less carbon atoms. Preferably, the alkyl group is an alkoxyalkyl group in particular, and examples of the alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferable specific examples of the structural unit represented by the above formula (b5) are those represented by the following formulae (b5-1) to (b5-5).

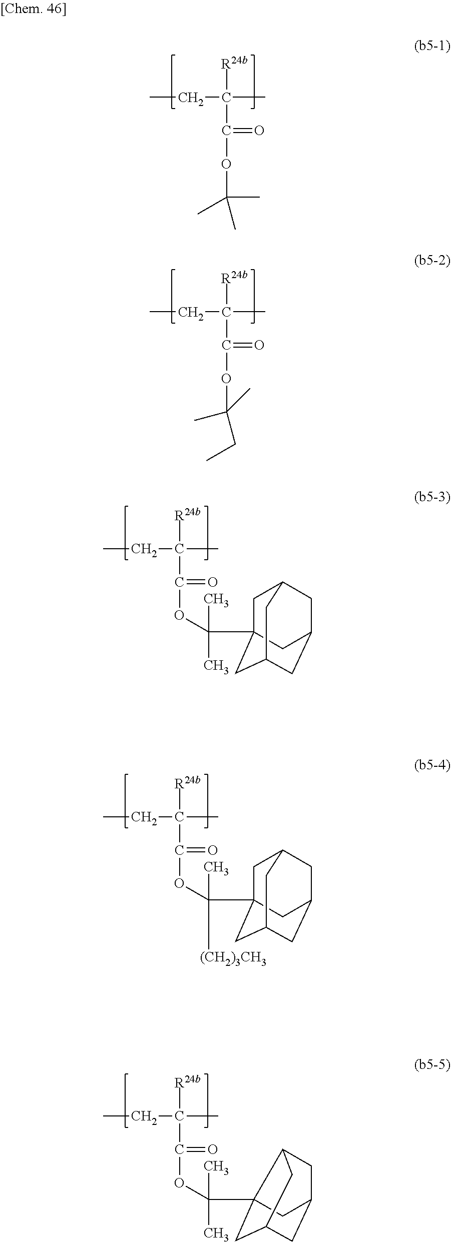

In the above formulae (b5-1) to (b5-5), R^{24b} represents a hydrogen atom or a methyl group.

Preferable specific examples of the structural unit represented by the above formula (b6) include those represented by the following formulae (b6-1) to (b6-26).

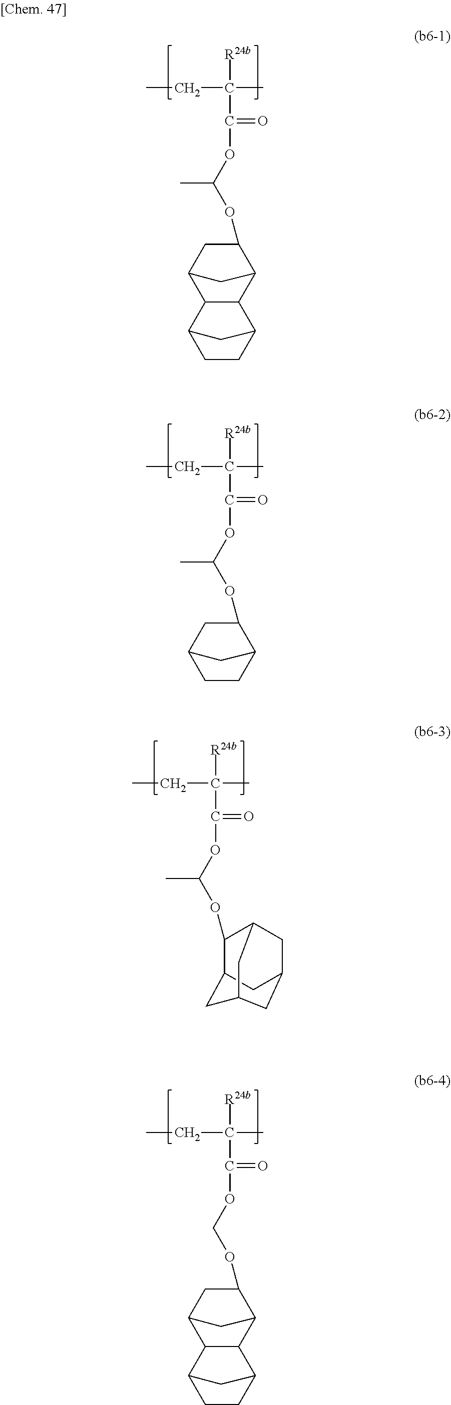

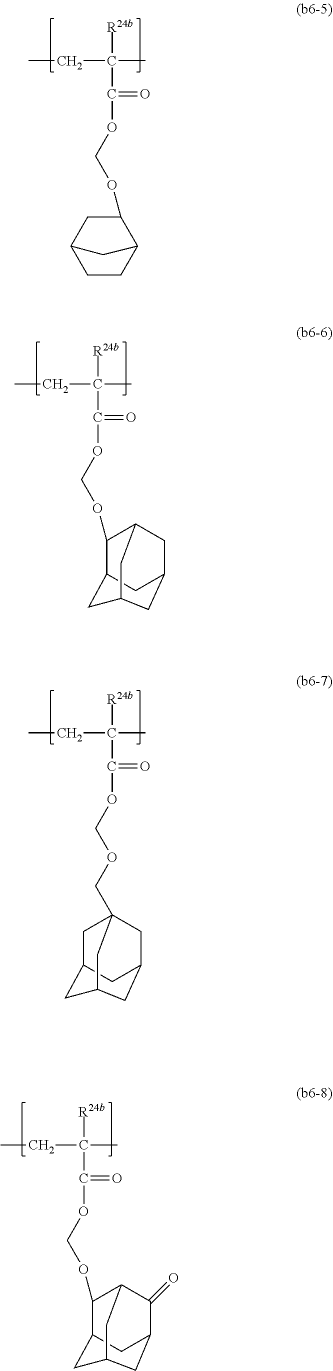

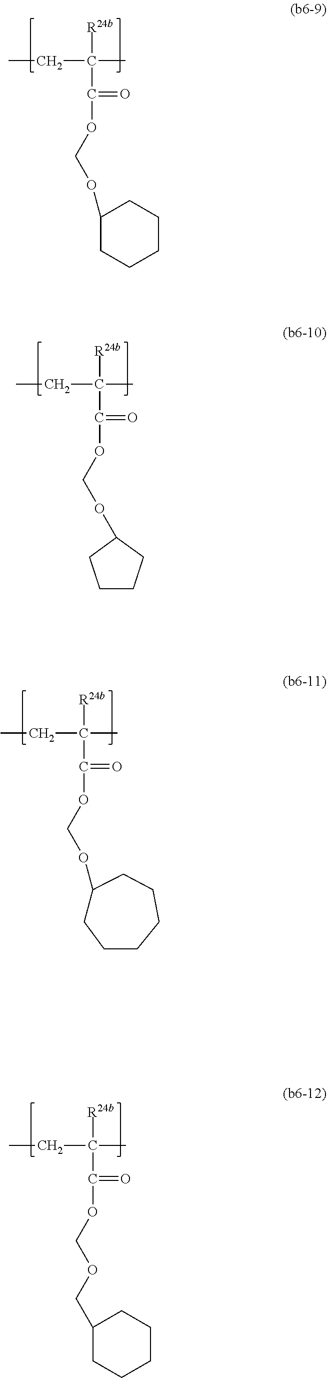

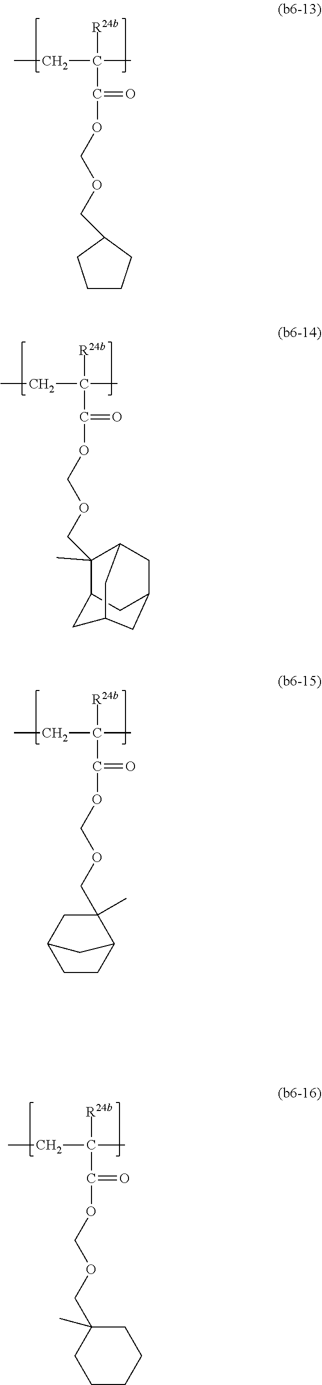

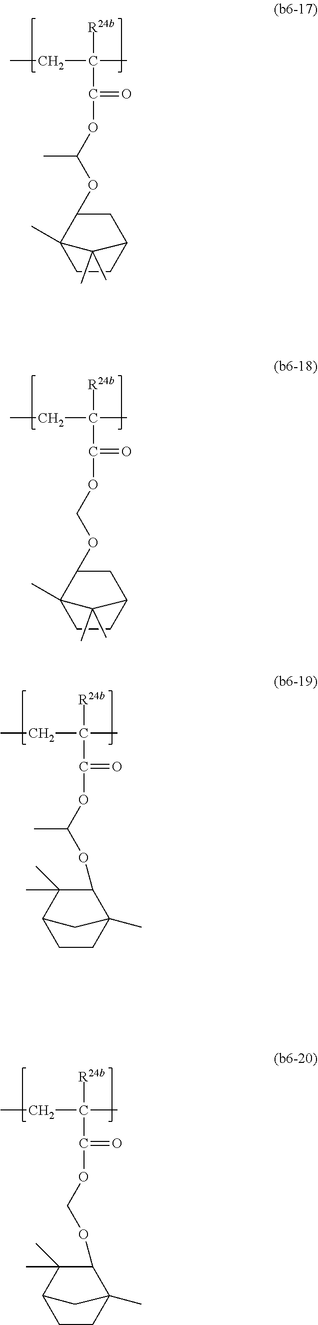

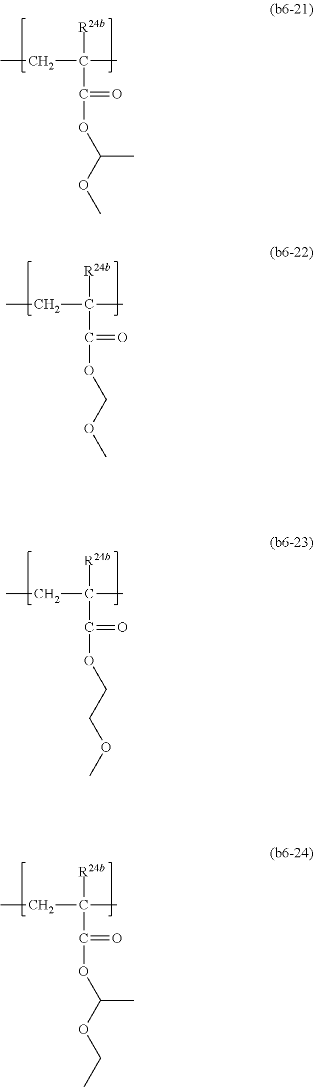

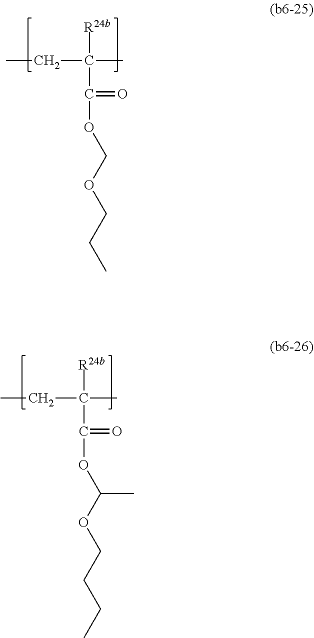

In the above formulae (b6-1) to (b6-06), R^{24b} presents a hydrogen atom or a methyl group.

Preferable specific examples of the structural unit represented by the above formula (b7) include those represented by the following formulae (b7-1) to (b7-15).

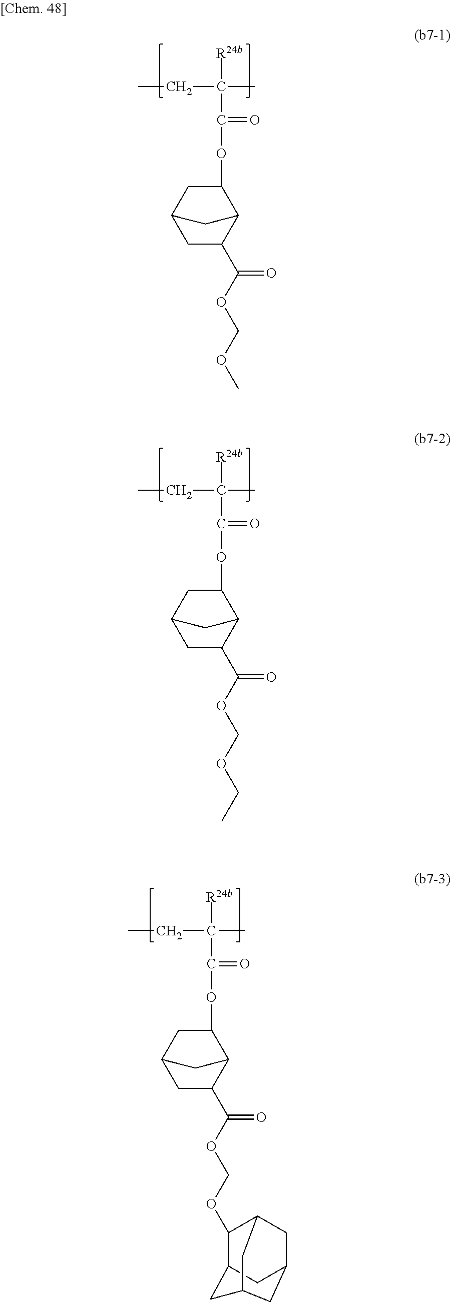

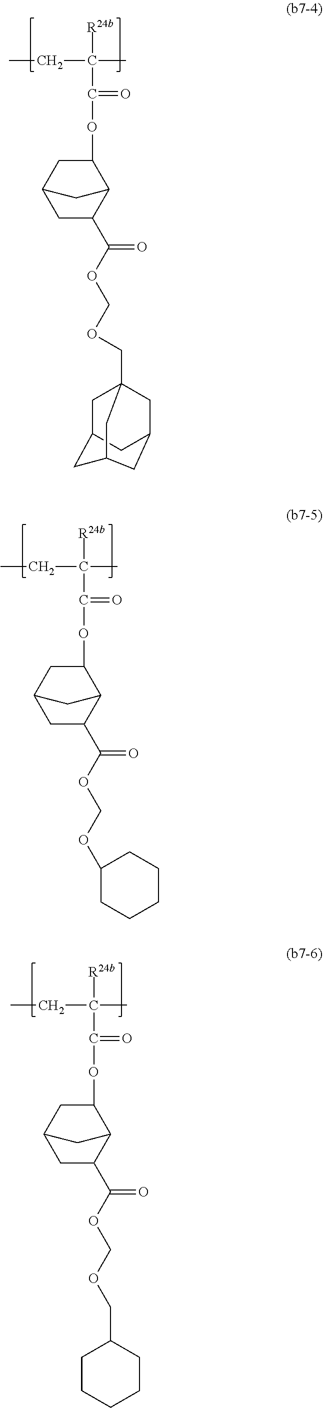

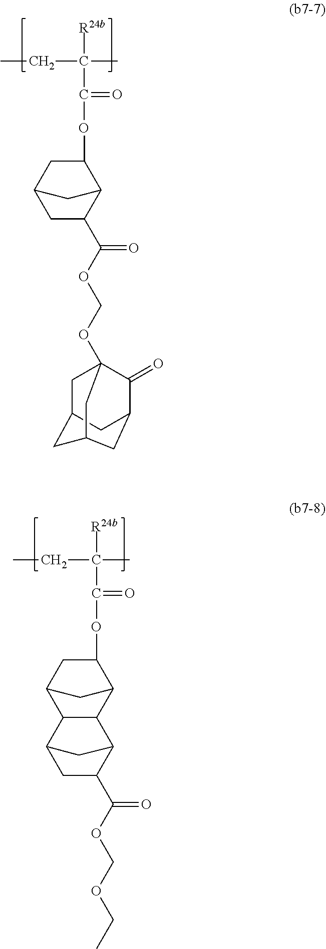

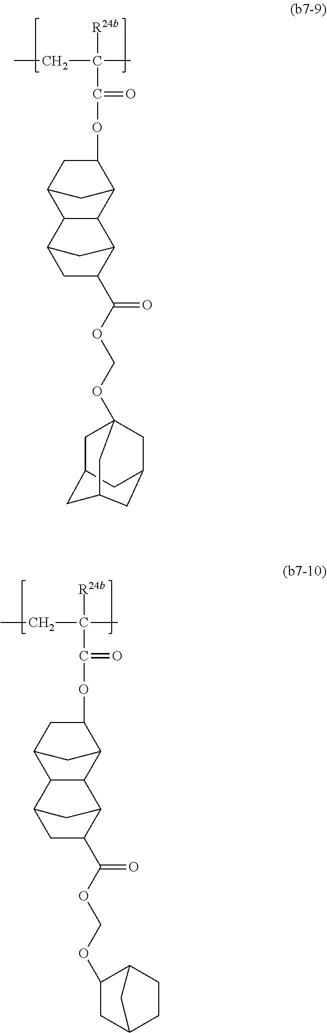

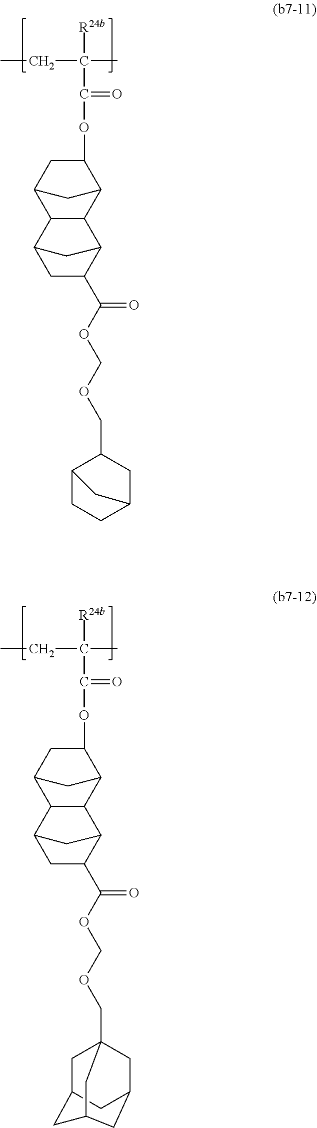

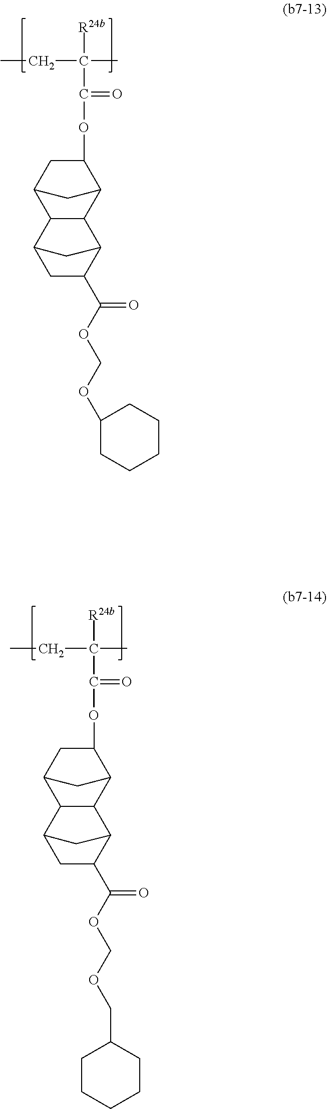

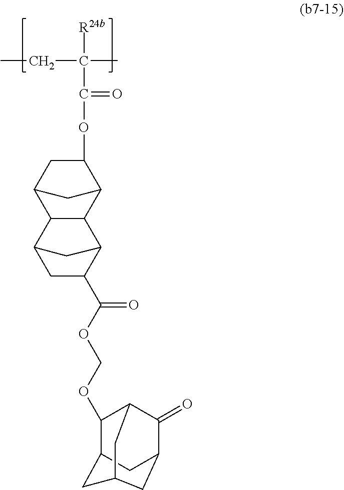

In the above formula (b7-1) to (b7-15), R^{24b} resents a hydrogen atom or a methyl group.

Since synthesis is easily performed and high sensitivity is relatively easily achieved, among the structural units represented by formulae (b5) to (b7) described above, the structural unit represented by formula (b6) is preferable. In the structural unit represented by formula (b6), Y^{b} is preferably an alkyl group, and one or both of R^{19b} and R^{20b} are preferably an alkyl group. The content ratio (the total content ratio when a plurality of types are contained) of the above structural units represented by formulae (b5) to (b7) having the acid dissociation group in the acrylic resin (B3) is preferably 08 by mass or more and 40% by mass or less and is more preferably 0% by mass or more and 30% by mass or less.

It is preferable that the acrylic resin (B3) is formed of a copolymer including a structural unit derived from a polymerizable compound having an ether bond.

Illustrative examples of the polymerizable compound having an ether bond include radical polymerizable compounds such as (meth)acrylic acid derivatives having an ether bond and an ester bond. Specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolyethylene glycol (meth)acrylate, methoxypolypropylene glycol (meth)acrylate, tetrahydrofurfuryl (meth)acrylate, and the like. Also, the polymerizable compound having an ether bond is preferably 2-methoxyethyl (meth)acrylate, 2-ethoxyethyl (meth)acrylate, or methoxytriethylene glycol (meth)acrylate. These polymerizable compounds may be used alone or in combinations of two or more thereof.

Furthermore, the acrylic resin (B3) may include another polymerizable compound as a structural unit in order to moderately control physical and chemical properties. The polymerizable compound is exemplified by conventional radical polymerizable compounds and anion polymerizable compounds.

Examples of the polymerizable compound include monocarboxylic acids such as acrylic acid, methacrylic acid, and crotonic acid; dicarboxylic acids such as maleic acid, fumaric acid, and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl (meth)acrylate, butyl(meth)acrylate, and cyclohexyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

As described above, the acrylic resin (B3) may include a constituent unit derived from a polymerizable compound having a carboxy group such as the monocarboxylic acids or the dicarboxylic acids described above, and particularly preferably includes a constituent unit derived from (meth)acrylic acid. A proportion of the constituent unit derived from (meth)acrylic acid in the acrylic resin (B3) is preferably 5 mass % or more and 20 mass % or less. When the proportion is 58 by mass or more, an undercut shape is easily formed, and when the proportion is 20% by mass or less, a resist pattern having a favorable rectangular shape as the cross-sectional shape tends to be easily formed.

Examples of the polymerizable compound include (meth)acrylic acid esters having an acid non-dissociable aliphatic polycyclic group, and vinyl group-containing aromatic compounds. As the acid non-dissociable aliphatic polycyclic group, in particular, a tricyclodecanyl group, an adamantyl group, a tetracyclododecanyl group, an isobornyl group, a norbornyl group and the like are preferable from the viewpoint of industrial availability and the like. These aliphatic polycyclic groups may have a linear or branched alkyl group having 1 to 5 carbon atoms as a substituent.

Specific examples of the (meth)acrylic acid esters having an acid non-dissociable aliphatic polycyclic group include compounds having structures represented by the following formulae (b8-1) to (b8-5).

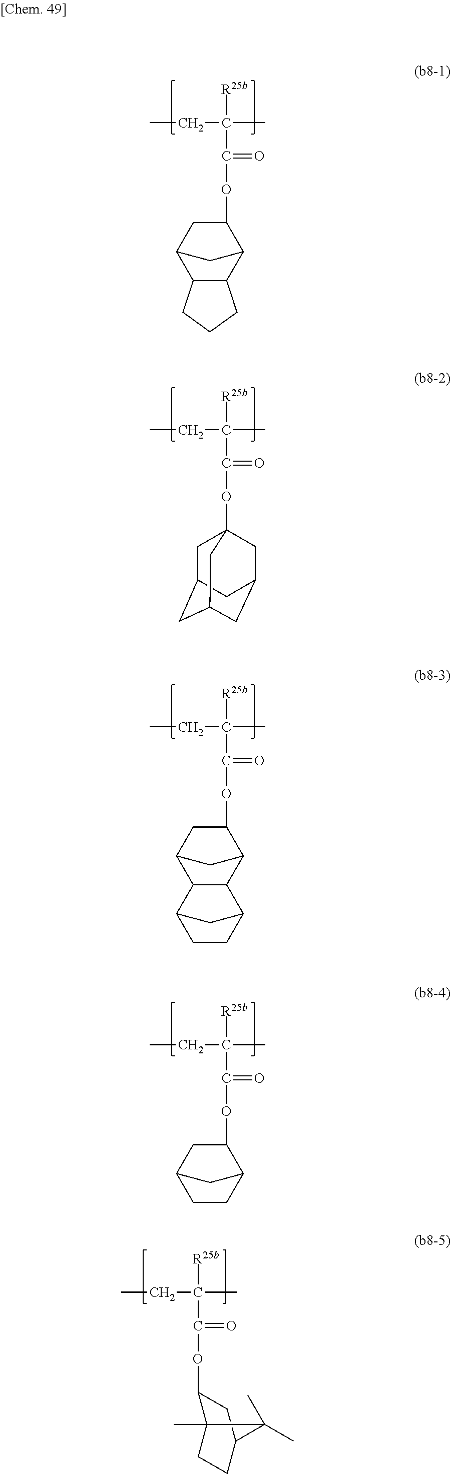

In formulae (b8-1) to (b8-5), R^{25b} represents a hydrogen atom or a methyl group.

The acrylic resin (B3) preferably includes the structural unit derived from the polymerizable compound having an ether bond described above. The content of the structural unit derived from the polymerizable compound having an ether bond in the acrylic resin (B3) is preferably 0% by mass or more and 50% by mass or less, and is more preferably 5% by mass or more and 35% by mass or less.

The acrylic resin (B3) preferably includes the structural unit derived from the (meth)acrylic acid esters having an acid non-dissociable aliphatic polycyclic group described above. The content of the structural unit derived from the (meth)acrylic acid esters having an acid non-dissociable aliphatic polycyclic group in the acrylic resin (B3) is preferably 0% by mass or more and 50% by mass or less, and is more preferably 5% by mass or more and 30% by mass or less.

As long as the photosensitive composition contains the acrylic resin (B3), the acrylic resins other than the acrylic resin (B3) described above can also be used as the resin (B). The acrylic resins other than the acrylic resin (B3) as described above are not particularly limited as long as they include the structural units represented by formulae (b5) to (b7) described above. In the specification of the present application, a resin including the constituent units represented by the formulae (b5) to (b7) and not including the constituent unit (B3-1) derived from an acid dissociable (meth)acrylic acid alicyclic ester corresponds to an acrylic resin other than the acrylic resin (B3) as the resin (B).

The polystyrene equivalent mass average molecular weight of the resin (B) described above is preferably 10,000 or more and 600,000 or less, is more preferably 20,000 or more and 400,000 or less and is further preferably 30,000 or more and 300,000 or less. By the setting of the mass average molecular weight described above, it is possible to hold sufficient strength of the photosensitive layer without lowering separation from a substrate and to further prevent the swelling of a profile at the time of plating and the occurrence of a crack.

The dispersivity of the resin (B) is preferably 1.05 or more. Here, the dispersivity refers to a value which is obtained by dividing a mass average molecular weight by a number average molecular weight. The dispersivity in the range described above is set, and thus it is possible to achieve desired stress resistance on plating and to avoid a problem in which a metal layer resulting from plating processing easily swells.

The content of the resin (B) with respect to the total solid content of the photosensitive composition is preferably 5% by mass or more and 98% by mass or less, is more preferably 10% by mass or more and 97% by mass or less, is more preferably 20% by mass or more and 96% by mass or less and is particularly preferably 25% by mass or more and 60% by mass or less.

### <Lewis Acid Compound (C)>

The photosensitive composition may or may not include a Lewis acid compound (C). The photosensitive composition preferably includes a Lewis acid compound (C). When the photosensitive composition includes a Lewis acid compound (C), a photosensitive composition having high sensitivity can be easily obtained. Furthermore, when a pattern is formed using the photosensitive composition, when time required for each process at the time of pattern formation or time required between the processes is long, a pattern having a desired shape and dimension may not be easily formed, or developing property may be deteriorated. However, when a Lewis acid compound (C) is blended into the photosensitive composition, such adverse effects on the pattern shape or the developing property can be mitigated or a process margin can be widened.

Here, the Lewis acid compound (C) means a “compound which has an empty orbit capable of receiving at least one electron pair and which achieves the action of an electron pair receptor”. The Lewis acid compound (C) is not particularly limited as long as the compound applies to the definition described above and is recognized as a Lewis acid compound by a person skilled in the art. As the Lewis acid compound (C), a compound which does not apply to a Bronsted acid (protonic acid) is preferably used. Specific examples of the Lewis acid compound (C) include boron fluoride, ether complexes of the boron fluorides (for example, BF₃·Et₂O, BF₃·Me₂O and BF₃·THF where Et represents an ethyl group, Me represents a methyl group and THF represents tetrahydrofuran), organic boron compounds (for example, tri n-octyl borate, tri n-butyl borate, triphenyl borate and triphenyl boron), titanium chloride, aluminum chloride, aluminum bromide, gallium chloride, gallium bromide, indium chloride, thallium trifluoroacetate, tin chloride, zinc chloride, zinc bromide, zinc iodide, zinc trifluoromethane sulfonate, zinc acetate, zinc nitrate, zinc tetrafluoroborate, manganese chloride, manganese bromide, nickel chloride, nickel bromide, nickel cyanide, nickel acetylacetonate, cadmium chloride, cadmium bromide, stannous chloride, stannous bromide, stannous sulfate, stannous tartrate and the like. Other specific examples of the Lewis acid compound (C) include chlorides, bromides, sulfates, nitrates, carboxylates and trifluoromethanesulfonates of rare earth metal elements, cobalt chloride, ferrous chloride, yttrium chloride and the like. Here, examples of the rare earth metal element include lanthanum, cerium, praseodymium, neodymium, samarium, europium, gadolinium, terbium, dysprosium, holmium, erbium, thulium, ytterbium, lutetium and the like.

The Lewis acid compound (C) preferably includes a Lewis acid compound which includes a group 13 element in the periodic table because it is easily available and an effect caused by the addition thereof is satisfactory. Here, examples of the group 13 element in the periodic table include boron, aluminum, gallium, indium and thallium. Among the group 13 elements in the periodic table described above, boron is preferable because the Lewis acid compound (C) is easily available and an effect caused by the addition thereof is particularly excellent. In other words, the Lewis acid compound (C) preferably includes a Lewis acid compound which includes boron.

Examples of the Lewis acid compound including boron include: boron halides such as boron fluoride, ether complex of boron fluoride, boron chloride and boron bromide; and various organic boron compounds. As the Lewis acid compound including boron, the organic boron compound is preferable because the content ratio of halogen atoms in the Lewis acid compound is low and the photosensitive composition is also easily applied to applications in which a low halogen content is required.

Preferred examples of the organic boron compound include a boron compound represented by formula (c1) below:

B(R^{C1})ₙ₁(OR^{C2})₍₃₋ₙ₁₎ (c1)

(in formula (c1), R^{C1} and R^{C2} each independently represent a hydrocarbon group having 1 or more and 20 or less carbon atoms, the hydrocarbon group may include 1 or more substituents, n1 represents an integer of 0 or more and 3 or less, when a plurality of R^{C1}s are present, two of the R^{C1}s may be bonded to each other to form a ring and when a plurality of OR^{C2}s are present, two of the OR^{C2}s may be bonded to each other to form a ring.) The photosensitive composition preferably includes, as the Lewis acid compound (C), one or more types of boron compound represented by formula (c1) described above.

When in formula (c1), R^{C1} and R^{C2} are hydrocarbon groups, the number of carbon atoms in each of the hydrocarbon groups is 1 or more and 20 or less. The hydrocarbon group in which the number of carbon atoms is 1 or more and 20 or less may be an aliphatic hydrocarbon group, an aromatic hydrocarbon group or a hydrocarbon group formed by combination of an aliphatic group and an aromatic group. As the hydrocarbon group in which the number of carbon atoms is 1 or more and 20 or less, a saturated aliphatic hydrocarbon group or an aromatic hydrocarbon group is preferable. The number of carbon atoms in each of the hydrocarbon groups serving as R^{C1} and R^{C2} is preferably 1 or more and 10 or less. When the hydrocarbon group is an aliphatic hydrocarbon group, the number of carbon atoms therein is preferably 1 or more and 6 or less and is particularly preferably 1 or more and 4 or less. The hydrocarbon groups serving as R^{C1} and R^{C2} may be saturated hydrocarbon groups or unsaturated hydrocarbon groups, and are preferably saturated hydrocarbon groups. When the hydrocarbon groups serving as R^{C1} and R^{C2} are aliphatic hydrocarbon groups, the aliphatic hydrocarbon groups may be linear, branched, cyclic or a combination of structures thereof.

Preferred examples of the aromatic hydrocarbon group include a phenyl group, a naphthalene-1-yl group, a naphthalene-2-yl group, a 4-phenylphenyl group, a 3-phenylphenyl group and a 2-phenylphenyl group. Among them, a phenyl group is preferable.

As the saturated aliphatic hydrocarbon group, an alkyl group is preferable. Preferred specific examples of the alkyl group include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethylhexyl group, an n-nonyl group and an n-decyl group.

The hydrocarbon groups serving as R^{C1} and R^{C2} each may include one or more substituent. Examples of the substituent include a halogen atom, a hydroxyl group, an alkyl group, an aralkyl group, an alkoxy group, a cycloalkyloxy group, an aryloxy group, an aralkyloxy group, an alkylthio group, a cycloalkylthio group, an arylthio group, an aralkylthio group, an acyl group, an acyloxy group, an acylthio group, an alkoxycarbonyl group, a cycloalkyloxycarbonyl group, an aryloxycarbonyl group, an amino group, an N-monosubstituted amino group, an N,N-disubstituted amino group, a carbamoyl group (—CO—NH₂), an N-monosubstituted carbamoyl group, an N,N-disubstituted carbamoyl group, a nitro group, a cyano group and the like. Although the number of carbon atoms in the substituent is not particularly limited as long as the object of the present invention is not disturbed, the number of carbon atoms is preferably 1 or more and 10 or less and is more preferably 1 or more and 6 or less.

Preferred specific examples of the organic boron compound represented by formula (c1) described above include compounds below. In the following formulae, Pen represents a pentyl group, Hex represents a hexyl group, Hep represents a heptyl group, Oct represents an octyl group, Non represents a nonyl group and Dec represents a decyl group.

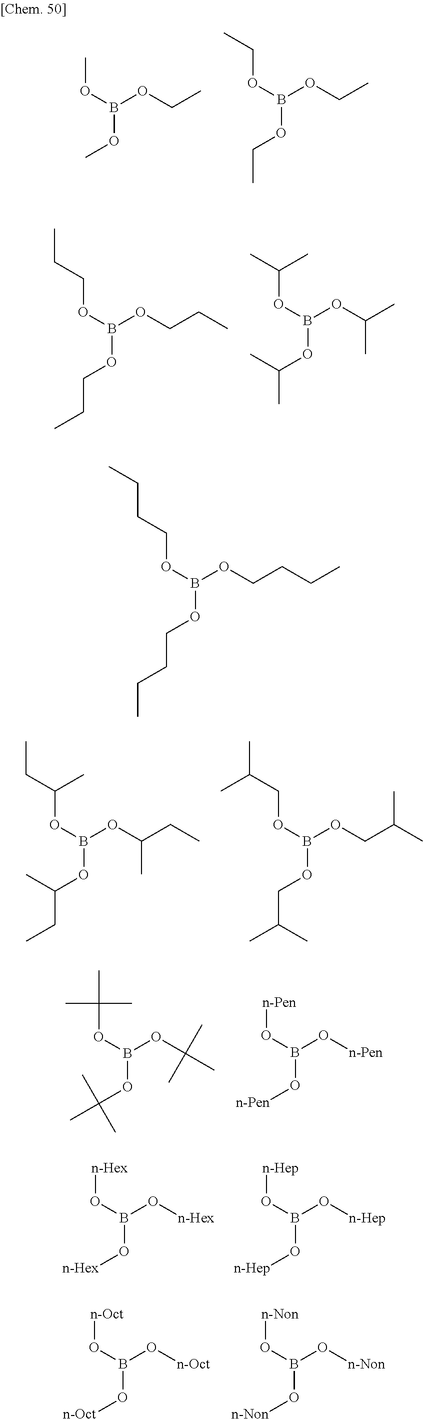

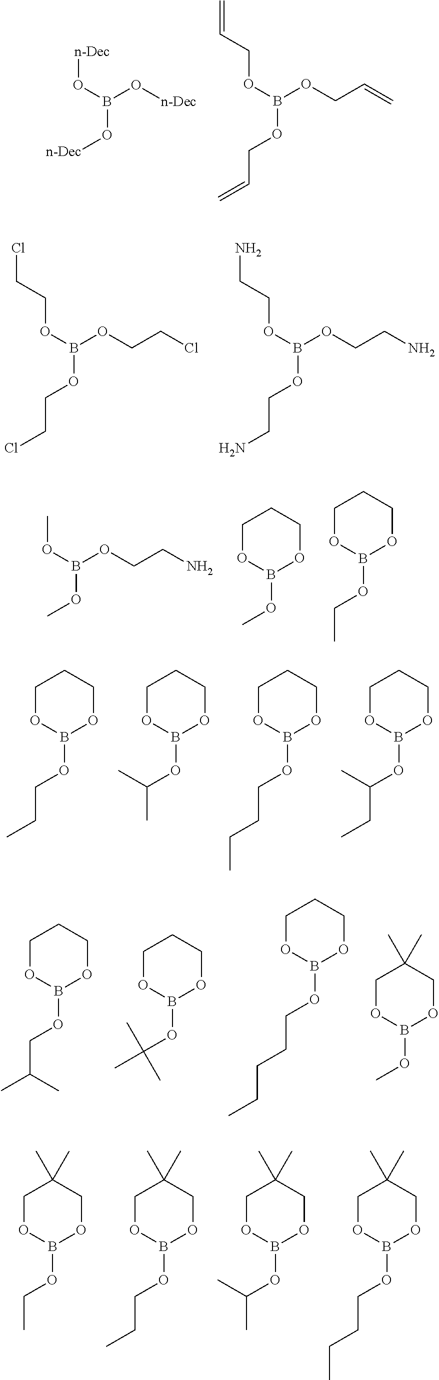

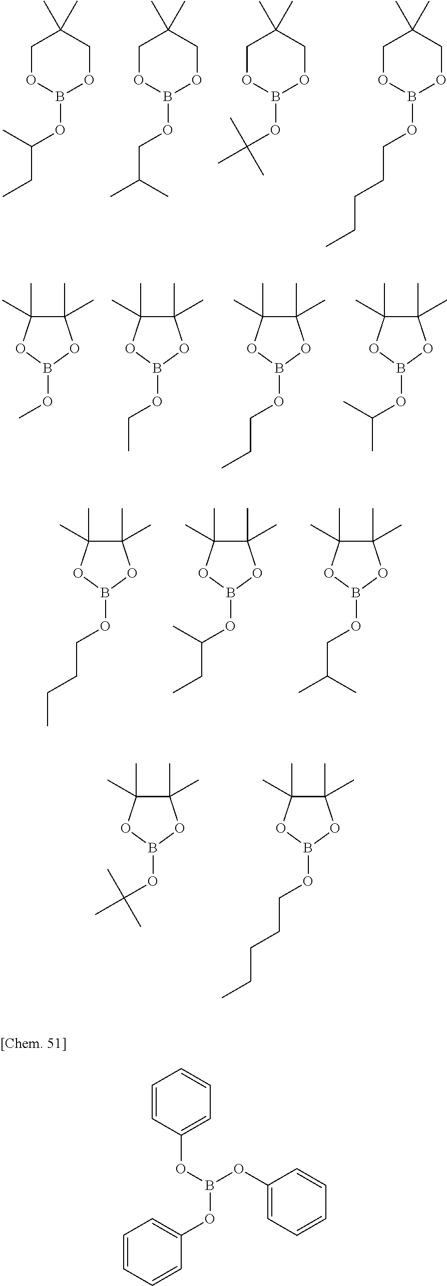

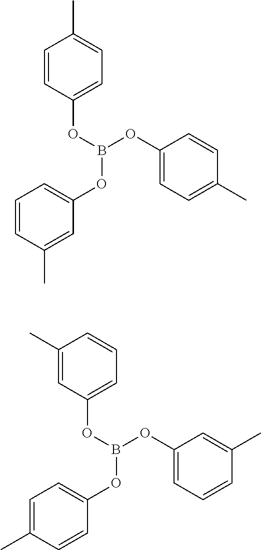

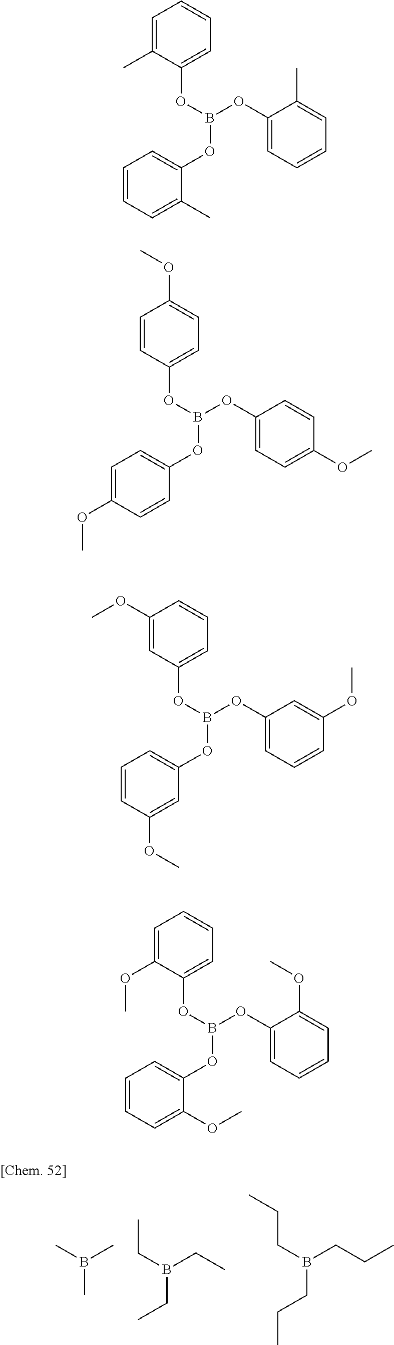

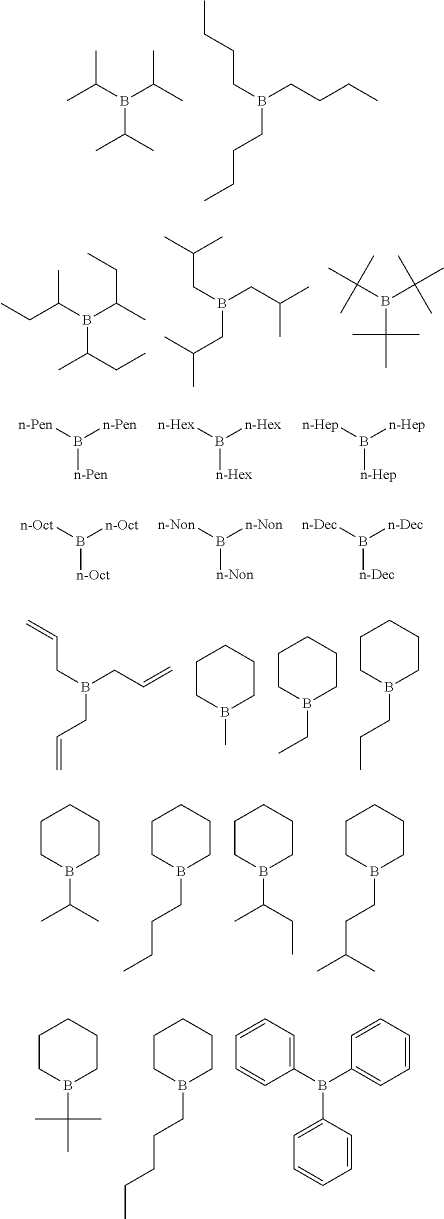

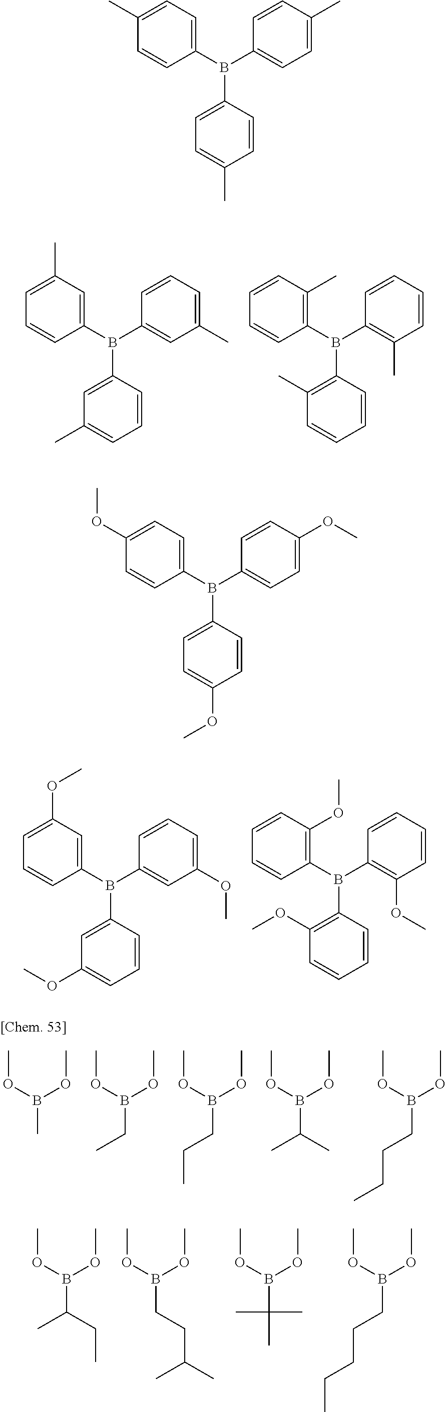

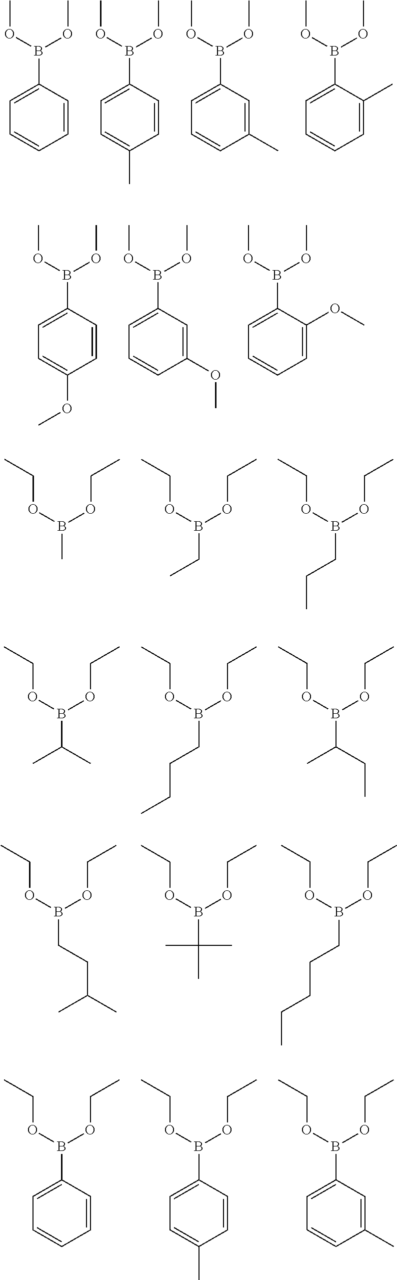

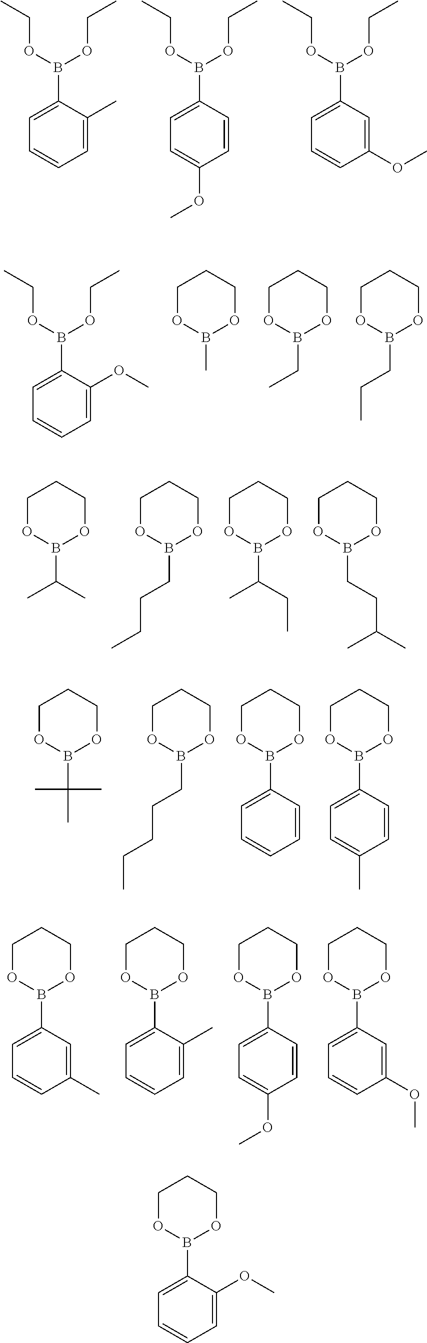

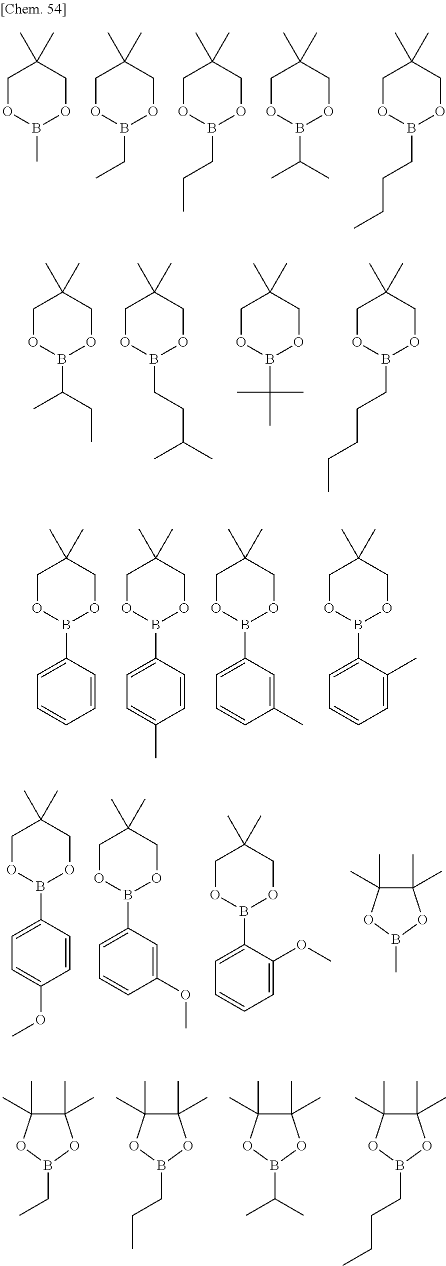

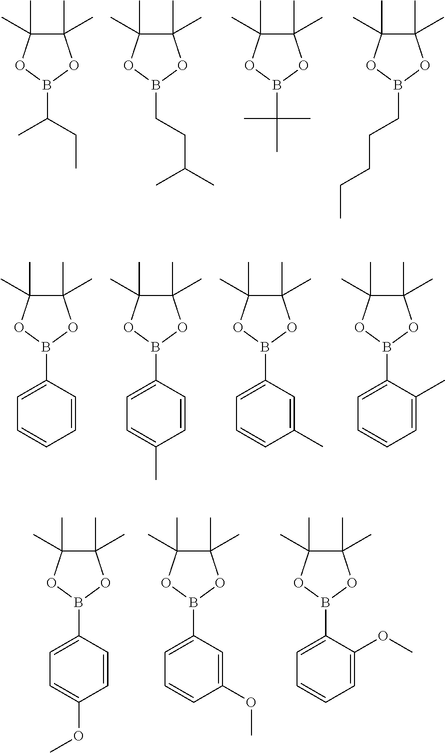

The Lewis acid compound (C) used with respect to the total 100 parts by mass of the resin (B) described above and the alkali soluble resin (D) to be described later is preferably 0.01 parts by mass or more and 5 parts by mass or less, is more preferably 0.01 parts by mass or more and 3 parts by mass or less and is further preferably 0.05 parts by mass or more and 2 parts by mass or less.

### <Alkali Soluble Resin (D)>

It is preferable that the photosensitive composition further contains an alkali-soluble resin (D) in order to improve crack resistance. The alkali-soluble resin as referred to herein may be determined as follows. A solution of the resin to give a resin concentration of 20% by mass (solvent: propylene glycol monomethyl ether acetate) is used to form a resin film having a film thickness of 1 μm on a substrate, and immersed in a 2.38% by mass aqueous TMAH solution for 1 min. If the resin was dissolved in an amount of no less than 0.01 μm, the resin is defined to be alkali soluble. The alkali-soluble resin (D) is preferably at least one selected from the group consisting of novolak resin (D1), polyhydroxystyrene resin (D2) and acrylic resin (D3).

### [Novolak Resin (D1)]

The novolak resin may be prepared by addition condensation between, for example, aromatic compounds having a phenolic hydroxyl group (hereinafter, merely referred to as “phenols”) and aldehydes in the presence of an acid catalyst.

Examples of the phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenylphenol, resorcinol, hydroquinone, hydroquinone monomethyl ether, pyrogallol, phloroglycinol, hydroxydiphenyl, bisphenol A, gallic acid, gallic acid ester, α-naphthol, β-naphthol, and the like. Examples of the aldehydes include formaldehyde, furfural, benzaldehyde, nitrobenzaldehyde, acetaldehyde, and the like. Although the catalyst used in the addition condensation reaction is not particularly limited, for example, for an acid catalyst, hydrochloric acid, nitric acid, sulfuric acid, formic acid, oxalic acid, acetic acid and the like are used.

The flexibility of the novolak resins can be enhanced still more when o-cresol is used, a hydrogen atom of a hydroxide group in the resins is substituted with other substituents, or bulky aldehydes are used.

Although the mass average molecular weight of the novolak resin (D1) is not particularly limited as long as the object of the present invention is not disturbed, the mass average molecular weight is preferably 1,000 or more and 50,000 or less.

### [Polyhydroxystyrene Resin (D2)]

Examples of a hydroxystyrene-based compound constituting the polyhydroxystyrene resin (D2) include p-hydroxystyrene, α-methylhydroxystyrene, and α-ethylhydroxystyrene. The polyhydroxystyrene resin (D2) may be a homopolymer of a hydroxystyrene-based compound or a copolymer of two or more hydroxystyrene-based compounds. Furthermore, the polyhydroxystyrene resin (D2) may be a copolymer of a hydroxystyrene-based compound and a styrene-based compound. Examples of the styrene-based compound include styrene, chlorostyrene, chloromethylstyrene, vinyltoluene, and α-methylstyrene.

Although the mass average molecular weight of the polyhydroxystyrene resin (D2) is not particularly limited as long as the object of the present invention is not disturbed, the mass average molecular weight is preferably 1,000 or more and 50,000 or less.

### [Acrylic Resin (D3)]

It is preferable that the acrylic resin (D3) includes a structural unit derived from a polymerizable compound having an ether bond, and a structural unit derived from a polymerizable compound having a carboxy group.

Examples of the polymerizable compound having an ether bond can include (meth)acrylic acid derivatives having an ether bond and an ester bond such as 2-methoxyethyl (meth)acrylate, methoxytriethylene glycol (meth)acrylate, 3-methoxybutyl(meth)acrylate, ethylcarbitol (meth)acrylate, phenoxypolyethylene glycol (meth)acrylate, methoxypolypropylene glycol (meth)acrylate, tetrahydrofurfuryl (meth)acrylate, and the like. The polymerizable compound having an ether bond is preferably, 2-methoxyethyl acrylate, or methoxytriethylene glycol acrylate. These polymerizable compounds may be used alone, or in combinations of two or more.

Examples of the polymerizable compound having a carboxyl group can include monocarboxylic acids such as acrylic acid, methacrylic acid and crotonic acid; dicarboxylic acids such as maleic acid, fumaric acid and itaconic acid; compounds having a carboxyl group and an ester linkage such as 2-methacryloyloxyethyl succinic acid, 2-methacryloyloxyethyl maleic acid, 2-methacryloyloxyethyl phthalic acid and 2-methacryloyloxyethyl hexahydrophthalic acid. The polymerizable compound having a carboxyl group is preferably, acrylic acid and methacrylic acid. These polymerizable compounds may be used alone, or in combinations of two or more thereof.

Although the mass average molecular weight of the acrylic resin (D3) is not particularly limited as long as the object of the present invention is not disturbed, the mass average molecular weight is preferably 50,000 or more and 800,000 or less.

When the total of the resin (B) described above and the alkali soluble resin (D) is 100 parts by mass, the content of the alkali-soluble resin (D) is preferably 0 parts by mass or more and 80 parts by mass or less, and is more preferably 0 parts by mass or more and 60 parts by mass or less. The content of the alkali soluble resin (D) is set within the range described above, and thus there is a tendency to enhance crack resistance and to prevent a reduction in a film at the time of development.

### <Sulfur-Containing Compound (E)>

The photosensitive composition includes the sulfur-containing compound (E). The sulfur-containing compound (E) is a compound which includes a sulfur atom capable of coordinating metal. With respect to a compound which can generate two or more tautomers, when at least one tautomer includes a sulfur atom which coordinates a metal forming a metal layer, this compound applies to the sulfur-containing compound. When on a surface made of a metal such as Cu, a resist pattern which is used as a template for plating is formed, a failure such as fitting in a cross-sectional shape easily occurs. However, in a case where the photosensitive composition includes the sulfur-containing compound (E), even when a resist pattern is formed on a surface made of a metal in a substrate, the occurrence of a failure such as fitting in a cross-sectional shape is easily reduced.

A sulfur atom capable of coordinating metal is included in the sulfur-containing compound as, for example, a mercapto group (—SH), a thiocarboxy group (—CO—SH), a dithiocarboxy group (—CS—SH) or a thiocarbonyl group (—CS—). The sulfur-containing compound preferably includes a mercapto group because it easily coordinates metal and is excellent in the effect of reducing fitting of a resist pattern.

Preferred examples of the sulfur-containing compound including a mercapto group include a compound represented by formula (e1) below.

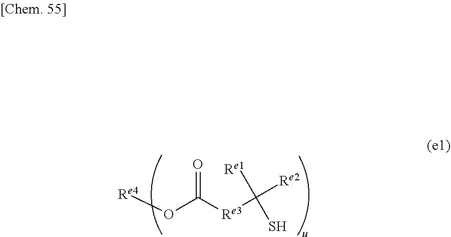

(where R^{e1} and R^{e2} each independently represent a hydrogen atom or an alkyl group, R^{e3} represents a single bond or an alkylene group, R^{e4} represents a u-valent aliphatic group which may include an atom other than carbon and u represents an integer of 2 or more and 4 or less.)

When R^{e1} and R^{e2} are an alkyl group, the allyl group may be linear or branched and is preferably linear. When R^{e1} and R^{e2} are an alkyl group, the number of carbon atoms in the allyl group is not particularly limited as long as the object of the present invention is not disturbed. The number of carbon atoms in the allyl group is preferably 1 or more and 4 or less, is particularly preferably 1 or 2 and is most preferably 1. As the combination of R^{e1} and R^{e2}, it is preferable that one be a hydrogen atom and that the other be an alkyl group, and it is particularly preferable that one be a hydrogen atom and that the other be a methyl group.

When R^{e3} is an alkylene group, the alkylene group may be linear or branched and is preferably linear. When R^{e3} is an alkylene group, the number of carbon atoms in the allylene group is not particularly limited as long as the object of the present invention is not disturbed. The number of carbon atoms in the allylene group is preferably 1 or more and 10 or less, is more preferably 1 or more and 5 or less, is particularly preferably 1 or 2 and is most preferably 1.

R^{e4} is a bivalent to tetravalent aliphatic group which may include an atom other than carbon. Examples of the atom other than carbon which may be included in R^{e4} include a nitrogen atom, an oxygen atom, a sulfur atom, a fluorine atom, a chlorine atom, a bromine atom, an iodine atom and the like. The structure of the aliphatic group of R^{e4} may be linear, branched, cyclic or a combination of structures thereof.

Among compounds represented by formula (e1), a compound represented by formula (e2) below is more preferable.

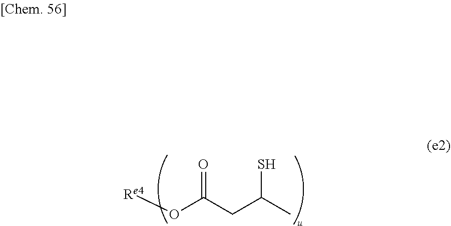

(in formula (e1), R^{e4} and u have the same meanings as in formula (e1).)

Among compounds represented by formula (e2) described above, compounds below are preferable.

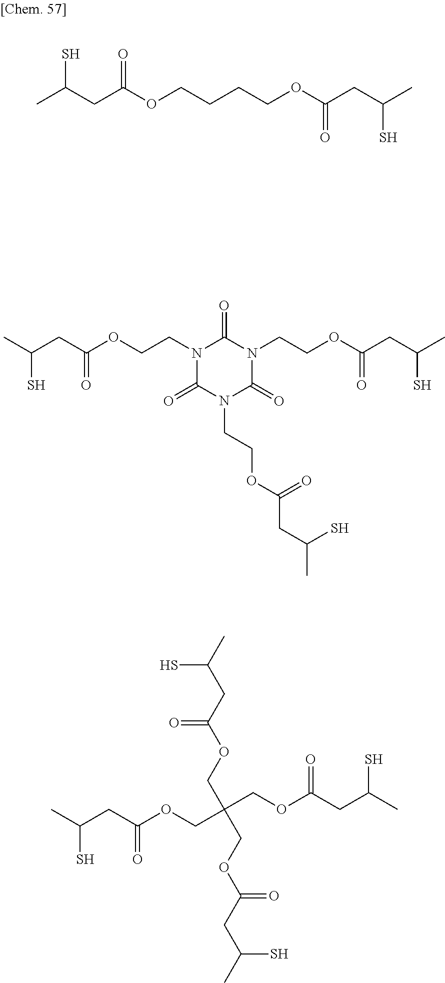

Preferred examples of the sulfur-containing compound including a mercapto group include compounds represented by formulae (e3-11) to (e3-17) below.

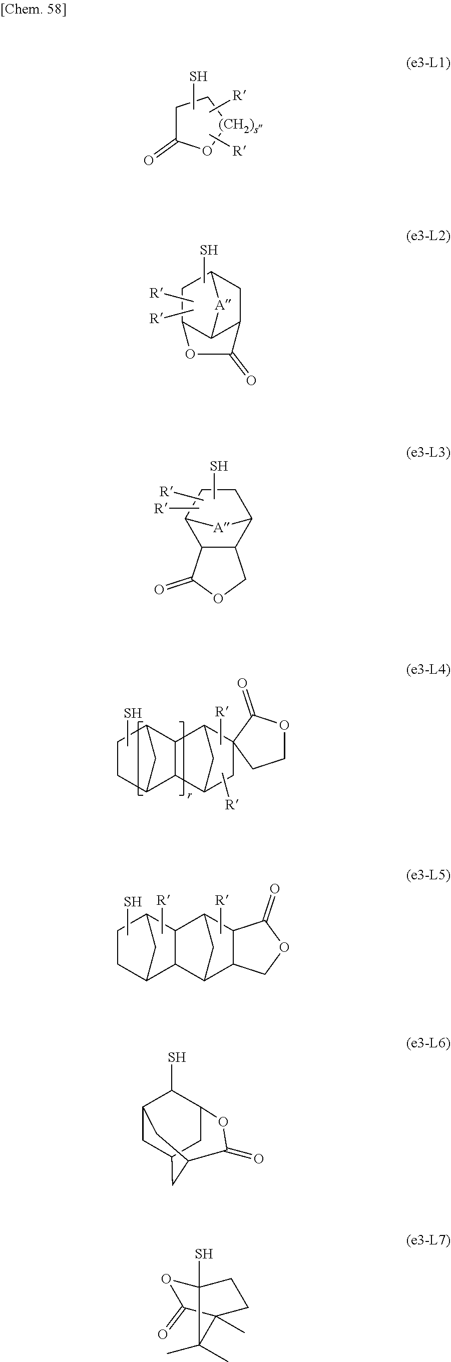

(in formulae (e3-11) to (e3-17), R′, s″, A″ and r represent the same ones in formulae (b-L1) to (b-17) which previously describes the acrylic resto (B3).)

Preferred specific examples of mercapto compounds represented by formulae (e3-L1) to (e3-L7) described above include compounds below.

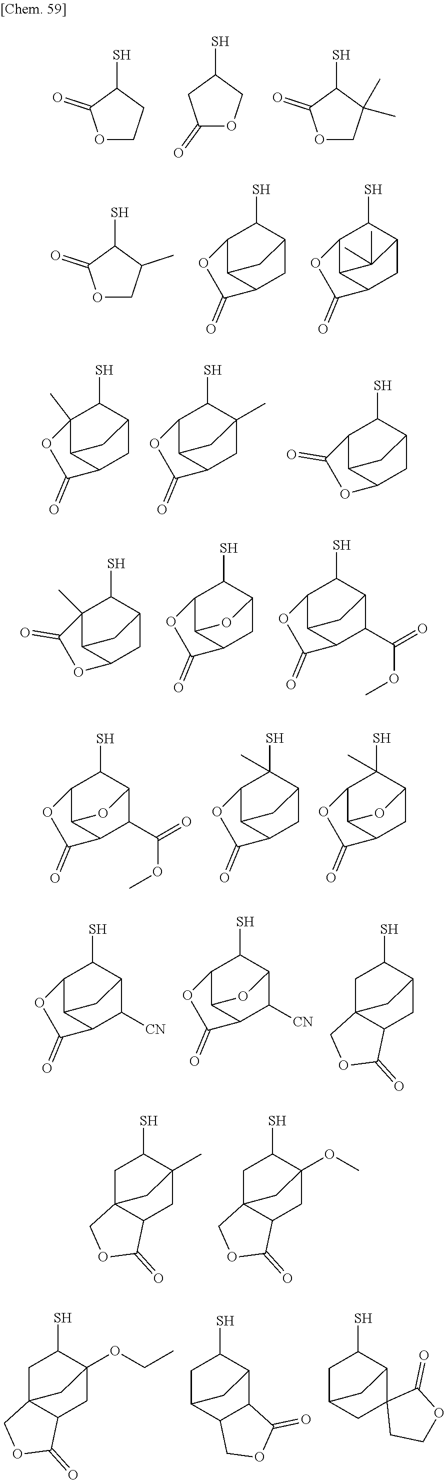

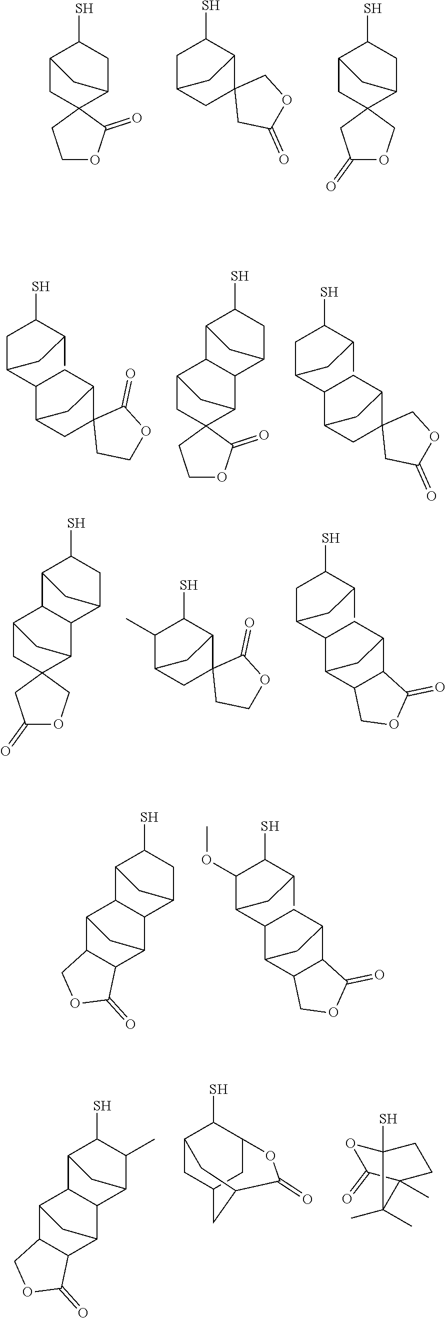

Preferred examples of the sulfur-containing compound including a mercapto group include compounds represented by formulae (e3-1) to (e3-4) below.

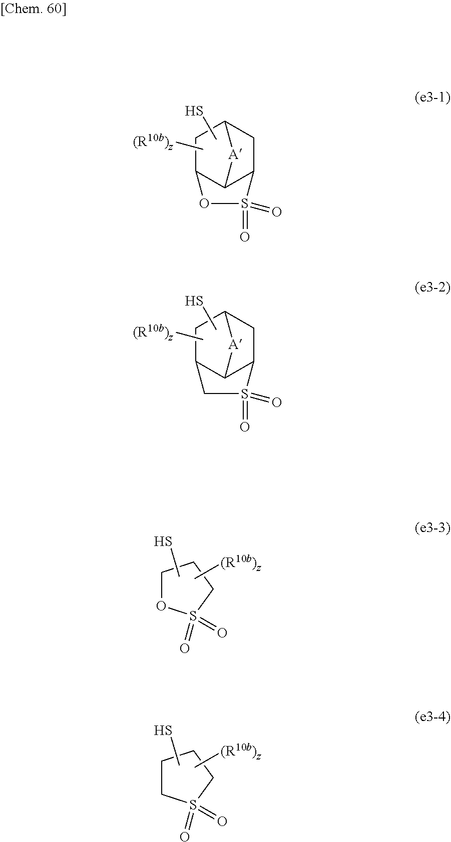

(where the definitions of symbols in formulae (e3-1) to (e3-4) are the same as described in formulae (3-1) to (3-4) which previously describes the acrylic resin (B3).)

Preferred specific examples of mercapto compounds represented by formulae (e3-1) to (e3-4) described above include compounds below.

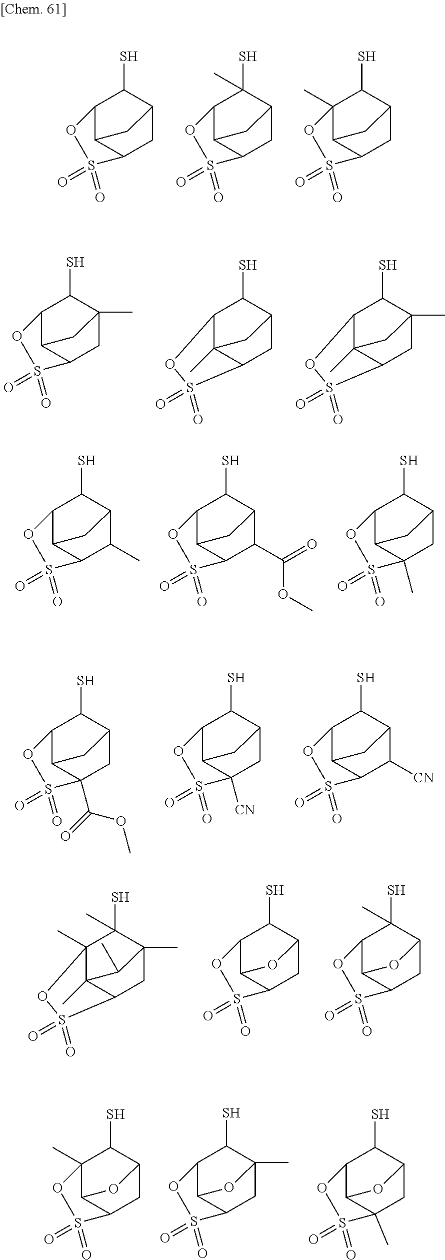

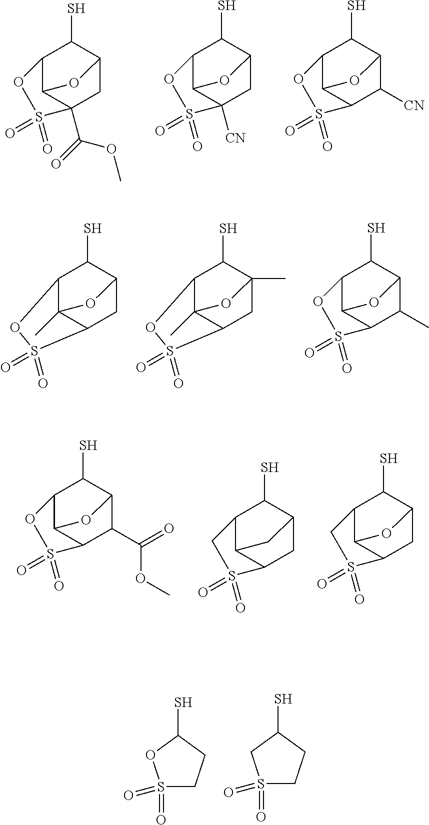

Preferred examples of the compound including a mercapto group include a compound represented by formula (e4) below.

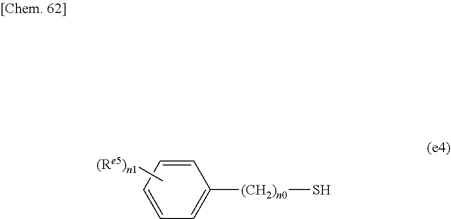

(in formula (e4), R^{e5} represents a hydroxyl group, an alkyl group having 1 or more and 4 or less carbon atoms, an alkoxy group having 1 or more and 4 or less carbon atoms, an alkylthio group having 1 or more and 4 or less carbon atoms, a hydroxyalkyl group having 1 or more and 4 or less carbon atoms, a mercaptoalkyl group having 1 or more and 4 or less carbon atoms, a halogenated alkyl group having 1 or more and 4 or less carbon atoms and a group selected from the group consisting of halogen atoms, and when n1 is an integer of 0 or more and 3 or less, no is an integer of 0 or more and 3 or less and n1 is 2 or 3, R^{e5}s may be identical to or different from each other.)

Specific examples when R^{e5} is an alkyl group which may include a hydroxyl group having 1 or more and 4 or less carbon atoms include a methyl group, an ethyl group, an n-propyl group, an isopropyl group, an n-butyl group, an isobutyl group, a sec-butyl group and a tert-butyl group. Among these alkyl groups, a methyl group, a hydroxymethyl group and an ethyl group are preferable.

Specific examples when R^{e5} is an alkoxy group having 1 or more and 4 or less carbon atoms include a methoxy group, an ethoxy group, an n-propyloxy group, an isopropyloxy group, an n-butyloxy group, an isobutyloxy group, a sec-butyloxy group and a tert-butyloxy group. Among these alkoxy groups, a methoxy group and an ethoxy group are preferable, and a methoxy group is more preferable.

Specific examples when Res is an alkylthio group having 1 or more and 4 or less carbon atoms include a methylthio group, an ethylthio group, an n-propylthio group, an isopropylthio group, an n-butylthio group, an isobutylthio group, a sec-butylthio group and a tert-butylthio group. Among these alkylthio groups, a methylthio group and an ethylthio group are preferable, and a methylthio group is more preferable.

Specific examples when R^{e5} is a hydroxyalkyl group having 1 or more and 4 or less carbon atoms include a hydroxymethyl group, a 2-hydroxyethyl group, a 1-hydroxyethyl group, a 3-hydroxy-n-propyl group, a 4-hydroxy-n-butyl group and the like. Among these hydroxyalkyl groups, a hydroxymethyl group, a 2-hydroxyethyl group and a 1-hydroxyethyl group are preferable, and a hydroxymethyl group is more preferable.

Specific examples when Res is a mercaptoalkyl group having 1 or more and 4 or less carbon atoms include a mercaptomethyl group, a 2-mercaptoethyl group, a 1-mercaptoethyl group, a 3-mercapto-n-propyl group, a 4-mercapto-n-butyl group and the like. Among these mercaptoalkyl groups, a mercaptomethyl group, a 2-mercaptoethyl group and a 1-mercaptoethyl group are preferable, and a mercaptomethyl group is more preferable.

When R^{e5} is a halogenated alkyl group having 1 or more and 4 or less carbon atoms, examples of the halogen atom included in the halogenated alkyl group include fluorine, chlorine, bromine, iodine and the like. Specific examples when Res is a halogenated alkyl group having 1 or more and 4 or less carbon atoms include a chloromethyl group, a bromomethyl group, an iodomethyl group, a fluoromethyl group, a dichloromethyl group, a dibromomethyl group, a difluoromethyl group, a trichloromethyl group, a tribromomethyl group, a trifluoromethyl group, a 2-chloroethyl group, a 2-bromoethyl group, a 2-fluoroethyl group, a 1,2-dichloroethyl group, a 2,2-difluoroethyl group, a 1-chloro-2-fluoroethyl group, a 3-chloro-n-propyl group, a 3-bromo-n-propyl group, a 3-fluoro-n-propyl group, a 4-chloro-n-butyl group and the like. Among these halogenated alkyl groups, a chloromethyl group, a bromomethyl group, an iodomethyl group, a fluoromethyl group, a dichloromethyl group, a dibromomethyl group, a difluoromethyl group, a trichloromethyl group, a tribromomethyl group and a trifluoromethyl group are preferable, and a chloromethyl group, a dichloromethyl group, a trichloromethyl group and a trifluoromethyl group are more preferable.

Specific examples when R^{e5} is a halogen atom include fluorine, chlorine, bromine and iodine.

In formula (e4), n1 is an integer of 0 or more and 3 or less, and is more preferably 1. When n1 is 2 or 3, a plurality of R^{e5}s may be identical to or different from each other.

In the compound represented by formula (e4), the substitution position of R^{e5} on a benzene ring is not particularly limited. The substitution position of Res on the benzene ring is preferably a meta position or a para position with respect to the bonding position of —(CH₂) no-SH.

As the compound represented by formula (e4), a compound is preferable which includes, as Res, at least one group selected from the group consisting of an alkyl group, a hydroxyalkyl group and a mercaptoalkyl group, and a compound is more preferable which includes, as R^{e5}, one group selected from the group consisting of an alkyl group, a hydroxyalkyl group and a mercaptoalkyl group. When the compound represented by formula (e4) includes, as R^{e5}, one group selected from the group consisting of an alkyl group, a hydroxyalkyl group and a mercaptoalkyl group, the substitution position of an alkyl group, a hydroxyalkyl group and a mercaptoalkyl group on the benzene ring is preferably a meta position or a para position with respect to the bonding position of —(CH₂)ₙ₀—SH and is more preferably a para position.

In formula (e4), no represents an integer of 0 or more and 3 or less. Since the compound is easily prepared and acquired, n is preferably 0 or 1 and is more preferably 0.

Specific examples of the compound represented by formula (e4) include p-mercaptophenol, p-thiocresol, m-thiocresol, 4-(methylthio)benzenethiol, 4-methoxybenzenethiol, 3-methoxybenzenethiol, 4-ethoxybenzenethiol, 4-isopropyloxybenzenethiol, 4-tert-butoxybenzenethiol, 3,4-dimethoxybenzenethiol, 3,4,5-trimethoxybenzenethiol, 4-ethylbenzenethiol, 4-isopropylbenzenethiol, 4-n-butylbenzenethiol, 4-tert-butylbenzenethiol, 3-ethylbenzenethiol, 3-isopropylbenzenethiol, 3-n-butylbenzenethiol, 3-tert-butylbenzenethiol, 3,5-dimethylbenzenethiol, 3,4-dimethylbenzenethiol, 3-tert-butyl-4-methylbenzenethiol, 3-tert-4-methylbenzenethiol, 3-tert-butyl-5-methylbenzenethiol, 4-tert-butyl-3-methylbenzenethiol, 4-mercaptobenzyl alcohol, 3-mercaptobenzyl alcohol, 4-(mercaptomethyl) phenol, 3-(mercaptomethyl) phenol, 1,4-di(mercaptomethyl)phenol 1,3-di(mercaptomethyl) phenol, 4-fluorobenzenethiol, 3-fluorobenzenethiol, 4-chlorobenzenethiol, 3-chlorobenzenethiol, 4-bromobenzenethiol, 4-iodobenzenethiol, 3-bromobenzenethiol, 3,4-dichlorobenzenethiol, 3,5-dichlorobenzenethiol, 3,4-difluorobenzenethiol, 3,5-difluorobenzenethiol, 4-mercaptocatechol, 2,6-di-tert-butyl-4-mercaptophenol, 3,5-di-tert-butyl-4-methoxybenzenethiol, 4-bromo-3-methylbenzenethiol, 4-(trifluoromethyl)benzenethiol, 3-(trifluoromethyl)benzenethiol, 3,5-bis(trifluoromethyl)benzenethiol, 4-methylthiobenzenethiol, 4-ethylthiobenzenethiol, 4-n-butylthiobenzenethiol, 4-tert-butylthiobenzenethiol and the like.

Examples of the sulfur-containing compound including a mercapto group include a compound which includes a nitrogen-containing aromatic heterocycle that is substituted with a mercapto group and a tautomer of a compound which includes a nitrogen-containing aromatic heterocycle that is substituted with a mercapto group. Preferred specific examples of the nitrogen-containing aromatic heterocycle include imidazole, pyrazole, 1,2,3-triazole, 1,2,4-triazole, oxazole, thiazole, pyridine, pyrimidine, pyridazine, pyrazine, 1,2,3-triazine, 1,2,4-triazine, 1,3,5-triazine, indole, indazole, benzoimidazole, benzoxazole, benzothiazole, 1H-benzotriazole, quinoline, isoquinoline, cinnoline, phthalazine, quinazoline, quinoxaline, and 1,8-naphthyridine.

Preferred specific examples of a nitrogen-containing heterocyclic compound which is suitable as the sulfur-containing compound and a tautomer of a nitrogen-containing heterocyclic compound include the following compounds.

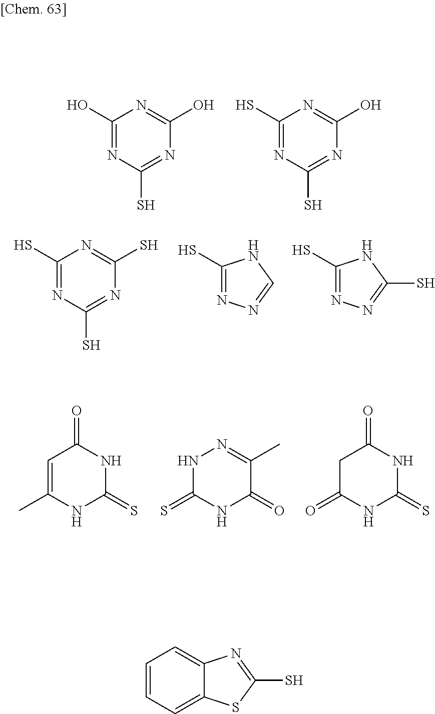

The use amount of the sulfur-containing compound (E) with respect to the total 100 parts by mass of the resin (B) described above and the alkali soluble resin (D) is preferably 0.01 parts by mass or more and 5 parts by mass or less, is more preferably 0.02 parts by mass or more and 3 parts by mass or less and is particularly preferably 0.05 parts by mass or more and 2 parts by mass or less.

### <Acid Diffusion Suppressing Agent (F)>

The photosensitive composition includes an acid diffusion suppressing agent (F). The acid diffusion suppressing agent (F) is not particularly limited as long as the photosensitive composition satisfies the above-described requirement 1. The acid diffusion suppressing agent (F) can improve, for example, the shape of a resist pattern to be used as a template, and the post-exposure stability of a photosensitive composition film. The acid diffusion suppressing (F) is preferably a nitrogen-containing compound (F1), and an organic carboxylic acid or an oxo acid of phosphorus or a derivative thereof (F2) may be contained, if necessary.

### [Nitrogen-Containing Compound (F1)]

Examples of the nitrogen-containing compound (F1) can include trimethylamine, diethylamine, triethylamine, di-n-propylamine, tri-n-propylamine, tri-n-pentylamine (triamylamine), tribenzylamine, diethanolamine, triethanolamine, n-hexylamine, n-heptylamine, n-octylamine, n-nonylamine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3,-tetramethylurea, 1,3-diphenylurea, imidazole, benzimidazole, 4-methylimidazole, 8-oxyquinoline, acridine, purine, pyrrolidine, piperidine, 4-hydroxy-pentamethylpiperidine, 2,4,6-tri (2-pyridyl)-S-triazine, morpholine, 4-methylmorpholine, piperazine, 1,4-dimethylpiperazine, 1,4-diazabicyclo[2.2.2] octane, pyridine, and the like. These may be used alone, or in combinations of two or more thereof.

Commercially available hindered amine compounds such as ADK STAB LA-52, ADK STAB LA-57, ADK STAB LA-63P, ADK STAB LA-68, ADK STAB LA-72, ADK STAB LA-77Y, ADK STAB LA-77G, ADK STAB LA-81, ADK STAB LA-82, and ADK STAB LA-87 (all of which are made by ADEKA Corporation) and the like can be used as the nitrogen-containing compound (F1).

From the viewpoint of easily obtaining a photosensitive composition satisfying the requirement 1, the photosensitive composition preferably includes a basic compound containing a tertiary amine skeleton as the nitrogen-containing compound (F1), and preferably includes an aliphatic tertiary amine such as trialkylamine. From the viewpoint of easily obtaining the photosensitive composition satisfying the requirement 1, the photosensitive composition preferably does not include, as the nitrogen-containing compound (F1), pyridine in which 2 and 6 positions are substituted with a substituent, e.g., a hydrocarbon group, such as 2,6-diphenylpyridine.

The nitrogen-containing compound (F1) is preferably used in a range of 0.01 parts by mass or more and 3 parts by mass or less, and particularly preferably in a range of 0.05 parts by mass or more and 1 part by mass or less, with respect to 100 parts by mass of a total mass of the resin (B) and the alkali-soluble resin (D).

### [Organic Carboxylic Acid or Oxo Acid of Phosphorus or Derivative Thereof (F2)]

Among the organic carboxylic acid, or the oxo acid of phosphorus and the derivative thereof (F2), preferred examples of the organic carboxylic acid include malonic acid, citric acid, malic acid, succinic acid, benzoic acid, salicylic acid and the like, and salicylic acid is particularly preferable.

Examples of the oxo acid of phosphorus or derivatives thereof include phosphoric acid and derivatives such as esters thereof such as, e.g., phosphoric acid, phosphoric acid di-n-butyl ester, and phosphoric acid diphenyl ester; phosphonic acid and derivatives such as esters thereof such as, e.g., phosphonic acid, phosphonic acid dimethyl ester, phosphonic acid di-n-butyl ester, phenylphosphonic acid, phosphonic acid diphenyl ester, and phosphonic acid dibenzyl ester; and phosphinic acid and derivatives such as esters thereof such as, e.g., phosphinic acid and phenylphosphinic acid; and the like. Among these, phosphonic acid is particularly preferred. These may be used alone, or in combinations of two or more thereof.

The organic carboxylic acid, or the oxo acid of phosphorus or the derivative thereof (F2) is used with respect to the total 100 parts by mass of the resin (B) described above and the alkali soluble resin (D) described above normally within a range of 0 parts by mass or more and 5 parts by mass or less and particularly preferably within a range of 0 parts by mass or more and 3 parts by mass or less.

Moreover, in order to form a salt to allow for stabilization, the organic carboxylic acid, or the oxo acid of phosphorous or the derivative thereof (F2) is preferably used in an amount equivalent to that of the nitrogen-containing compound (F1).

### <Organic Solvent(S)>

The photosensitive composition contains an organic solvent(S). The type of organic solvent(S) is not particularly limited as long as the object of the present invention is not disturbed, and the organic solvent can be appropriately selected for use from the organic solvents that have been conventionally used in positive-type photosensitive compositions.

Specific examples of the organic solvent(S) can include ketones such as acetone, methyl ethyl ketone, cyclohexanone, methyl isoamyl ketone, and 2-heptanone; polyhydric alcohols and derivatives thereof, like monomethyl ethers, monoethyl ethers, monopropyl ethers, monobutyl ethers and monophenyl ethers, such as ethylene glycol, ethylene glycol monoacetate, diethylene glycol, diethylene glycol monoacetate, propylene glycol, propylene glycol monoacetate, dipropylene glycol and dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, methyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate, and 3-methyl-3-methoxybutyl acetate; aromatic hydrocarbons such as toluene and xylene; and the like. These may be used alone, or as a mixture of two or more thereof.

The content of the organic solvent(S) is not particularly limited as long as the object of the present invention is not disturbed. When the photosensitive composition is used such that the film thickness of a photosensitive layer obtained such as by a spin coat method is 5 μm or more, the organic solvent(S) is preferably used such that the solid content concentration of the photosensitive composition falls within a range of 30% by mass or more and 55% by mass or less.

### <Other Components>

The photosensitive composition may further contain a polyvinyl resin for improving plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and copolymers thereof, and the like. The polyvinyl resin is preferably polyvinyl methyl ether in view of lower glass transition temperatures.

Further, the photosensitive composition may also contain an adhesive auxiliary agent in order to improve the adhesiveness between a template formed with the photosensitive composition and a metal substrate.

The photosensitive composition may further contain a surfactant for improving coating, defoaming, leveling and the like. As the surfactant, for example, a fluorinated surfactant and a silicone surfactant are preferably used. Specific examples of the fluorinated surfactant include commercially available fluorochemical surfactants such as BM-1000 and BM-1100 (both made by B.M-Chemie Co., Ltd.), Megafac F142D, Megafac F172, Megafac F173 and Megafac F183 (all manufactured by Dainippon Ink And Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.) but there is no limitation to those. As the silicone surfactant, a non-modified silicone surfactant, a polyether modified silicone surfactant, a polyester modified silicone surfactant, an alkyl modified silicone surfactant, an aralkyl modified silicone surfactant, a reactive silicone surfactant and the like can be preferably used. As the silicone surfactant, a commercially available silicone surfactant can be used. Specific examples of the commercially available silicone surfactant include Paintad M (made by Dow Corning Toray Co., Ltd.), TOPICA K1000, TOPICA K2000 and TOPICA K5000 (all of which are made by Takachiho Sangyo Co., Ltd.), XL-121 (polyether modified silicone surfactant, made by Clariant), BYK-310 (polyester modified silicone surfactant, made by BYK-Chemie GmbH) and the like.

Additionally, in order to finely adjust the solubility in a developing solution, the photosensitive composition may further contain an acid, an acid anhydride, or a solvent having a high boiling point.

Specific examples of the acid and acid anhydride can include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic acid, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Furthermore, specific examples of the solvent having a high boiling point can include N-methylformamide, N,N-dimethylformamide, N-methylformanilide, N-methylacetamide, N,N-dimethlyacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like.

Moreover, the photosensitive composition may further contain a sensitizer for improving the sensitivity.

### <Method of Preparing Chemically Amplified Positive-Type Photosensitive Composition>

The chemically amplified positive-type photosensitive composition is prepared by mixing and stirring the above components with a common method. Machines which can be used for mixing and stirring the above components include dissolvers, homogenizers, 3-roll mills and the like. The resulting mixture obtained after uniformly mixing the above components may further be filtered with a mesh, a membrane filter or the like.

### <<Photosensitive Dry Film>>

A photosensitive dry film includes a base material film and a photosensitive layer which is formed on the surface of the base material film, and the photosensitive layer is formed of the photosensitive composition described above.

As the base material film, a base material film which has optical transparency is preferable. Specific examples include a polyethylene terephthalate (PET) film, a polypropylene (PP) film, a polyethylene (PE) film and the like, and a polyethylene terephthalate (PET) film is preferable because it is excellent in the balance of optical transparency and rupture strength.

The photosensitive composition described above is applied on the base material film so as to form the photosensitive layer, and thus the photosensitive dry film is manufactured. When the photosensitive layer is formed on the base material film, an applicator, a bar coater, a wire bar coater, a roll coater, a curtain flow coater or the like is used, and thus the photosensitive composition is applied and dried such that the thickness of the film after being dried on the base material film is preferably 0.5 μm or more and 300 μm or less, is more preferably 1 μm or more and 300 μm or less and is particularly preferably 3 μm or more and 100 μm or less.

The photosensitive dry film may further include a protective film on the photosensitive layer. Examples of the protective film include a polyethylene terephthalate (PET) film, a polypropylene (PP) film, polyethylene (PE) film and the like.

<<Method of Manufacturing Substrate with Template>>

A method of forming a patterned resist film on a substrate with the photosensitive composition described above is not particularly limited. Such a patterned resist film described above is suitably used as an insulating film, an etching mask, and a template for forming a plated article. As a preferable method of manufacturing such a substrate with a template, the following method is mentioned:
the method including:
laminating a photosensitive layer comprising the above-described photosensitive composition on a substrate having a metal layer on a surface thereof,
heating the photosensitive layer,
irradiating the heated photosensitive layer with an active ray or radiation position-selectively, and
developing the irradiated photosensitive layer to form a template having a pattern shape for forming a plated article. Each step is described below. Laminating a photosensitive layer including the above-described photosensitive composition on a substrate having a metal layer on a surface thereof is also referred to as a “laminating step”. Heating the photosensitive layer is also referred to as a “heating step”. Position selectively irradiating the heated photosensitive layer with an active ray or radiation is also referred to as an “exposure step”. Developing the irradiated photosensitive layer to form a template having a pattern shape for forming a plated article is also referred to as a “developing step”.

### <Laminating Step>

In the laminating step, a photosensitive layer including a photosensitive layer composed of the above-described photosensitive composition is laminated on a substrate having a metal layer on a surface thereof. When a substrate provided with a template for forming a plating article is produced, a substrate having a metal layer on a surface thereof (a substrate having a metal surface) is used as the substrate. As metal species constituting the metal layer, copper, gold, and aluminum are preferable, and copper is more preferable.

The photosensitive layer is laminated on a substrate having a metal layer on a surface thereof, for example, by applying a liquid photosensitive composition onto the metal layer on the surface of the substrate. In addition, the photosensitive layer may be laminated on the substrate using the above-described photosensitive dry film. A thickness of the photosensitive layer is not particularly limited as long as a resist pattern to serve as a template can be formed with a desired film thickness, but is preferably 0.5 μm or more, more preferably 0.5 μm or more and 300 μm or less, particularly preferably 1 μm or more and 150 μm or less, and most preferably 3 μm or more and 100 μm or less.

As a method of applying the photosensitive composition onto a substrate, a spin coating method, a slit coating method, a roll coating method, a screen printing method, an applicator method, or the like can be employed.

### <Heating Step (Pre-Baking)>

In the heating step, the photosensitive layer is heated. The solvent (organic solvent(S)) is removed by heating. A heating temperature is preferably 110° C. or higher and 150° C. or lower, and more preferably 130° C. or higher and 145° C. or lower. A heating time is preferably 100 seconds or more and 550 seconds or less, and more preferably 150 seconds or more and 450 seconds or less.

In the heating step, the solvent is removed, and the acid generating agent (A) reacts with the metal layer on the substrate surface to partially decompose and generate an acid. This reaction is promoted by the acid diffusion suppressing agent (F). As a result, the acrylic resin (B3) having the constituent unit (B3-1) derived from a specific acid-dissociable (meth)acrylic acid alicyclic ester has increased solubility in alkali, in a region near the substrate surface.

### <Exposure Step>

In the exposure step, the heated photosensitive layer is position-selectively irradiated with an active ray or radiation. The position-selective exposure is performed in such a manner that a portion where the plating article is to be formed is removed by development. Specifically, the heated photosensitive layer is selectively irradiated (exposed) with an active ray or radiation, for example, ultraviolet rays or visible light having a wavelength of 300 nm or more and 500 nm or less through a mask having a predetermined pattern. By selectively radiating (exposure) an active ray or radiation, the acid generating agent (A) decomposes to generate an acid in the exposed portion, and alkali solubility of the acrylic resin (B3) having the constituent unit (B3-1) derived from a specific acid-dissociable (meth)acrylic acid alicyclic ester increases.

As a radiation source of the radiation, low pressure mercury lamps, high pressure mercury lamps, super high pressure mercury lamps, metal halide lamps, argon gas lasers, or the like can be used. The radiation may include microwaves, infrared rays, visible lights, ultraviolet rays, X-rays, Y-rays, electron beams, proton beams, neutron beams, ion beams, etc. An irradiation dose of the radiation may vary depending on the component ratio of the photosensitive composition and/or the film thickness of the photosensitive layer, and the like. For example, in the case of an ultra high-pressure mercury lamp, the dose may be 100 mJ/cm² or more and 10,000 mJ/cm² or less. Furthermore, the radiation includes a light ray to activate the acid generating agent (A) in order to generate an acid.

After the exposure, diffusion of acid is promoted by heating (PEB) the photosensitive layer using a known method to change the alkali solubility of the photosensitive layer at an exposed portion of the photosensitive layer.

### <Development Step>

In the development step, the irradiated photosensitive layer is developed to form a template having a pattern shape for forming a plated article. By dissolving and removing unnecessary portions by development, a resist pattern having a pattern shape and serving as a template for forming a plated article is formed. At this time, an alkaline aqueous solution is used as a developing solution.

As the developing solution, an aqueous solution of alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene or 1,5-diazabicyclo[4,3,0]-5-nonane can be used. Also, an aqueous solution prepared by adding an adequate amount of a water-soluble organic solvent such as methanol or ethanol, or a surfactant to the aqueous solution of alkali can be used as the developing solution.

The developing time may vary depending on the component ratio of the photosensitive composition, the film thickness of the photosensitive layer, and the like, and is typically 1 minute or more and 30 minutes or less. A method of development may be any of a liquid-filling method, a dipping method, a paddle method, a spray developing method, or the like.

After the development, the photosensitive layer is washed with running water for 30 seconds or more and 90 seconds or less, and is then dried with an air gun, an oven or the like.

The resist pattern thus formed has a cross-sectional shape in which a large undercut is formed and footing is suppressed because the photosensitive composition described above is used.

### <<Method of Manufacturing Plated Article>>

A method of manufacturing a plated article includes plating a substrate with a template formed by the above-described method to form the plated article in the template. Specifically, a conductor such as metal is embedded by plating into a nonresist portion (portion removed with the developing solution) in the template of the substrate with a template formed by the method described above, and thus it is possible to form a plated article like a connection terminal such as a bump or a metal post or Cu rewiring. A plating processing method is not particularly limited, and various types of conventionally known methods can be adopted. As a plating liquid, in particular, a solder plating liquid, a copper plating liquid, a gold plating liquid and a nickel plating liquid are suitably used. Finally, the remaining template is removed with a detaching liquid or the like according to a conventional method.

It is likely that, when the plated article is manufactured, ashing processing is preferably performed on a metal surface exposed in a non-pattern part of the resist pattern serving as the template for the formation of the plated article. Specifically, for example, there is a case where the pattern which is formed of the photosensitive composition including the sulfur-containing compound (E) is used as the template so as to form the plated article. In this case, it is likely that the adherence to the metal surface of the plated article is easily degraded. This failure is remarkable when the sulfur-containing compound (E) represented by formula (e1) described previously or the sulfur-containing compound (E) represented by formula (e4) described previously is used. However, when the ashing processing described above is performed, even if the pattern formed of the photosensitive composition including the sulfur-containing compound (E) is used as the template, the plated article which is satisfactorily adhered to the metal surface is easily formed. When a compound which includes a nitrogen-containing aromatic heterocycle that is substituted with a mercapto group is used as the sulfur-containing compound (E), the problem on the adherence of the plated article described above hardly occurs or the degree thereof is low. Hence, when a compound which includes a nitrogen-containing aromatic heterocycle that is substituted with a mercapto group is used as the sulfur-containing compound (E), the plated article having satisfactory adherence to the metal surface is easily formed without the ashing processing being performed.

The ashing processing is not particularly limited as long as a method is adopted which does not cause such a damage that the plated article having a desired shape cannot be formed on the resist pattern serving as the template for the formation of the plated article. Examples of the preferable ashing processing method include a method using oxygen plasma. In order to perform ashing on the metal surface on the substrate with oxygen plasma, it is preferable to use a known oxygen plasma generation device to generate oxygen plasma and to then apply the oxygen plasma to the metal surface on the substrate.

As a gas used for the generation of the oxygen plasma, as long as the object of the present invention is not disturbed, oxygen and various gasses used for plasma processing can be conventionally mixed together. Examples of the gas described above include a nitrogen gas, a hydrogen gas, a CF₄ gas and the like. Although conditions for the ashing using the oxygen plasma are not particularly limited as long as the object of the present invention is not disturbed, the processing time falls within, for example, a range of 10 seconds or more and 20 minutes or less, preferably falls within a range of 20 seconds or more and 18 minutes or less and more preferably falls within a range of 30 seconds or more and 15 minutes or less. The processing time with the oxygen plasma is set within the range described above, and thus the effect of enhancing the adherence of the plated article is easily achieved without any change in the shape of the resist pattern.

According to the above method, a resist pattern having a cross-sectional shape in which a large undercut is formed and footing is suppressed can be used as a template for forming a plated article, and thus a plated article having a footing shape and a large footing can be formed. Therefore, the plated article does not easily collapse, and a plated article having an excellent collapse margin can be formed. Therefore, after forming a plated article such as a bump, a metal post, or a wiring, even if the surface of the substrate is rinsed with a rinse solution, a gas is blown to the surface of the substrate for the purpose of drying or the like, a chemical treatment such as etching is performed, or a material for forming another member is applied to the substrate or the substrate is filled with a material for forming another member in order to provide the another member on the substrate, the plated article does not easily collapse.

### EXAMPLES

Although the present invention will be described in more detail below with reference to Examples, the present invention is not limited to these Examples.

### Examples 1 to 34 and Comparative Examples 1 to 16

In Examples 1 to 34 and Comparative Examples 1 to 16, compounds A1 to A11 represented by the following formulae were used as the acid generating agent (A).

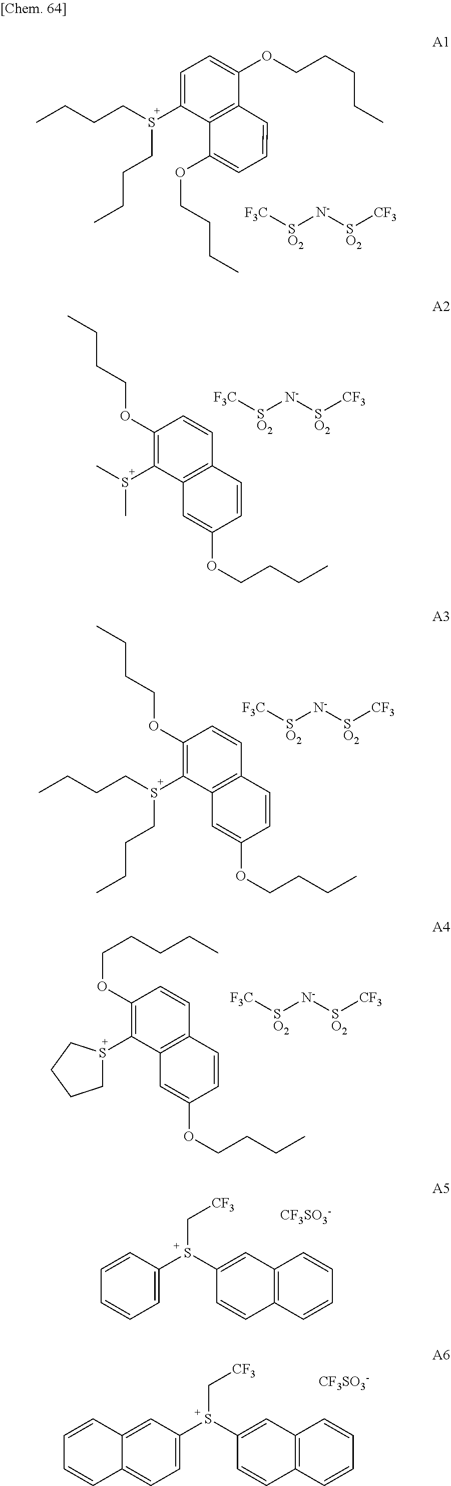

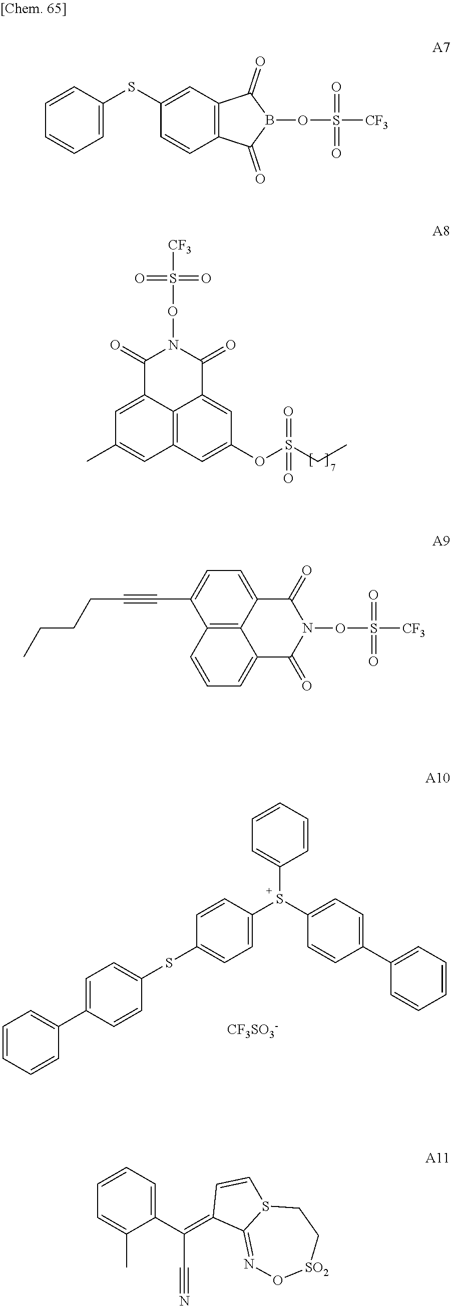

In Examples 1 to 34 and Comparative Examples 1 to 16, the following resins B1 to B13 were used as the resin (resin (B)) having alkali solubility that increases under action of an acid. In the following structural formulae, the number at the lower right of parentheses in each constituent unit represents a content (mass %) of the constituent unit in each resin. A weight average molecular weight Mw of each of the resins B1 to B11 was 40,000. The dispersity (Mw/Mn) of each of the resins B1 to B11 was 4.0. The resins B12 and B13 had a mass average molecular weight Mw of 10,000.

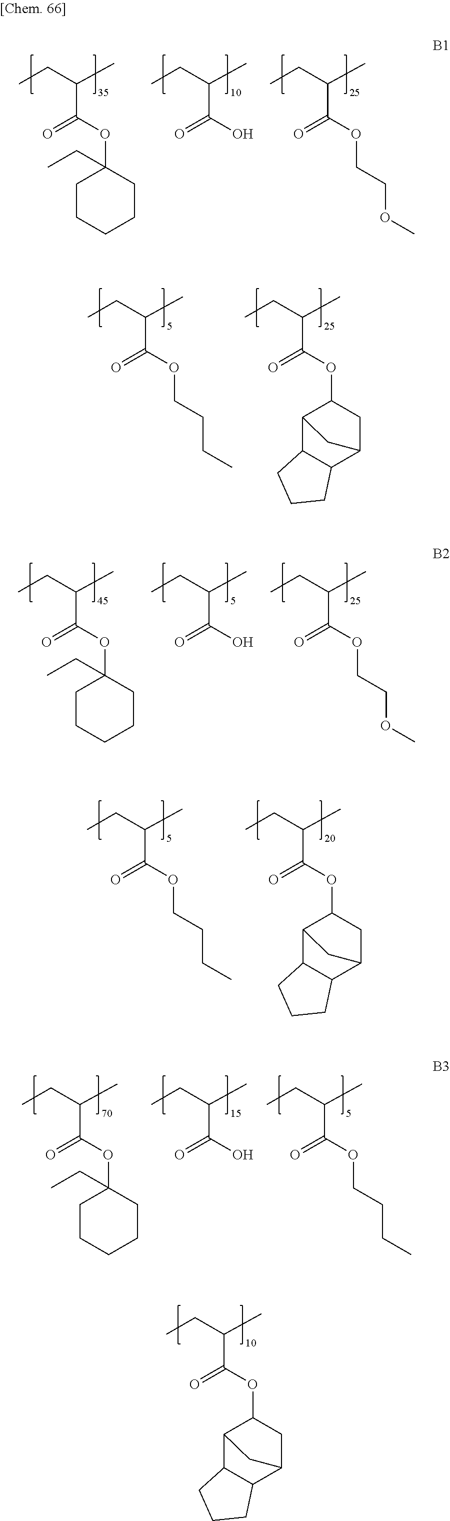

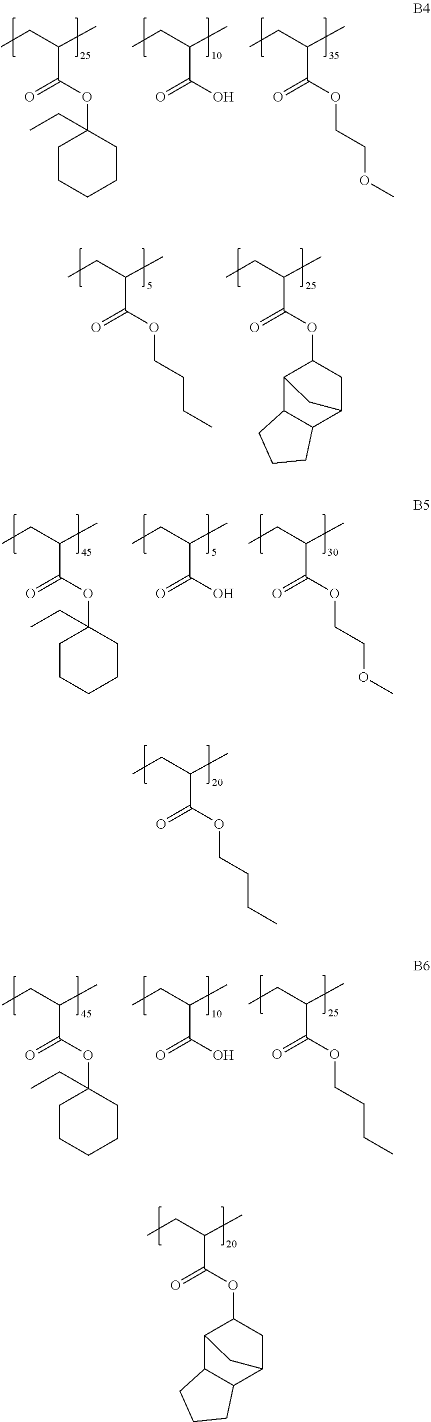

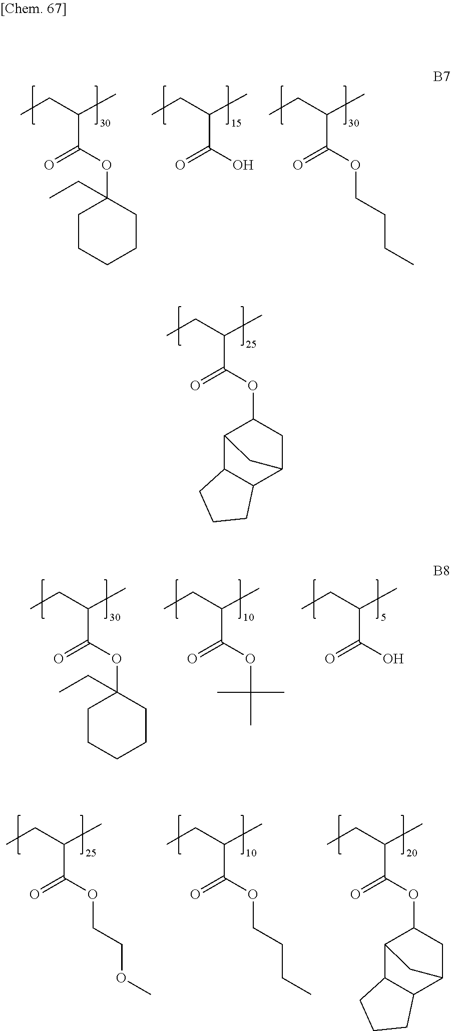

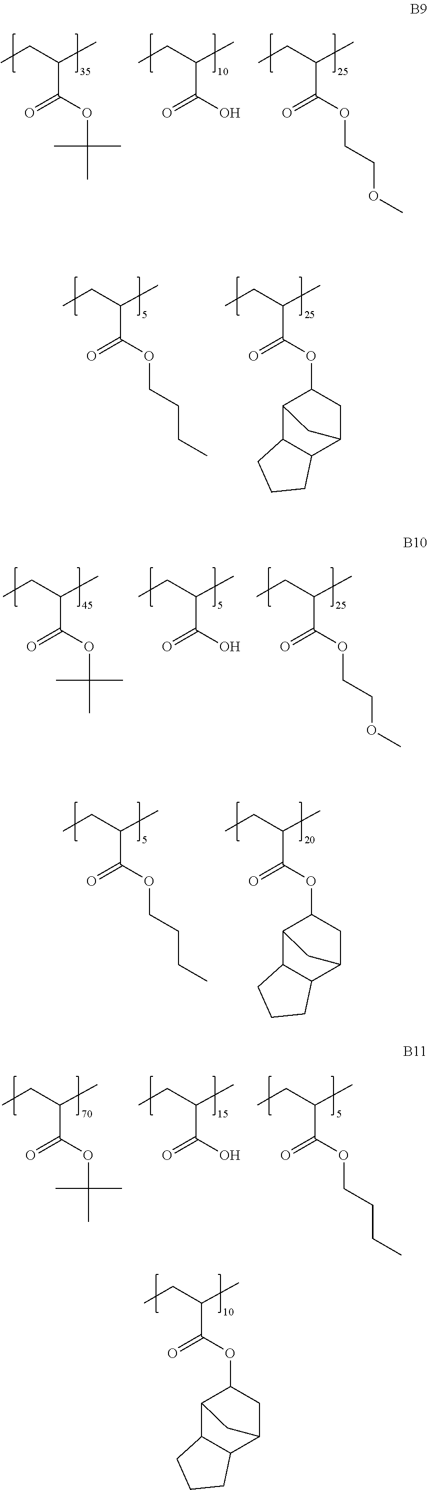

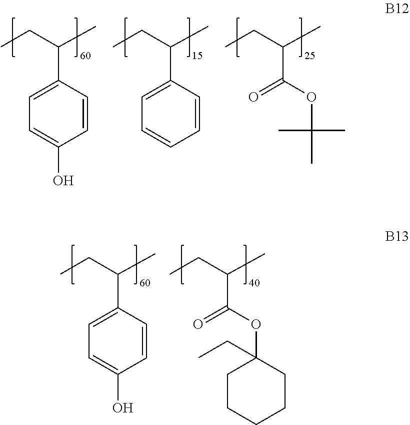

As the alkali-soluble resin (D), the following resins D1 and D2 were used. A mass average molecular weight Mw of D1 (polyhydroxystyrene resin) was 2,500. A mass average molecular weight Mw of D2 (novolac resin) was 6,500. A mass average molecular weight Mw of D3 (polyhydroxystyrene resin) was 2,500. A mass average molecular weight Mw of D4 (polyhydroxystyrene resin) was 8,000.

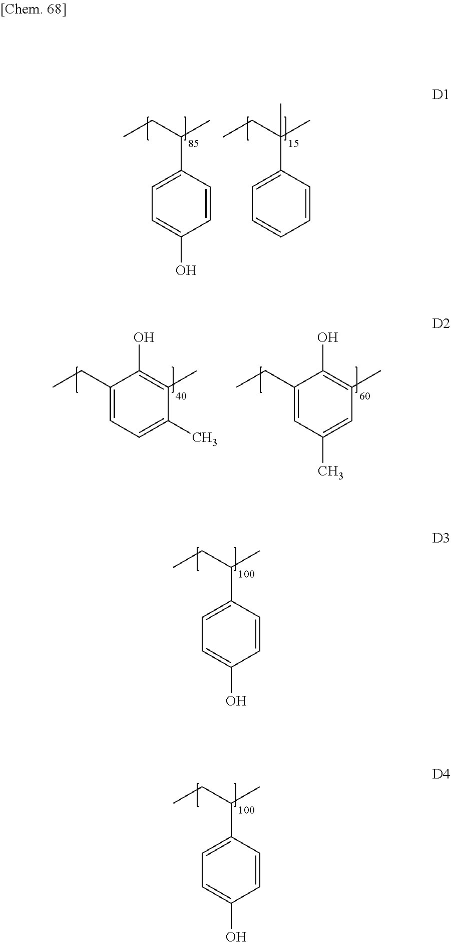

As the sulfur-containing compound (E), the following compound E1 was used.

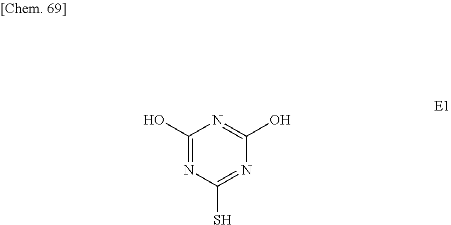

As the acid diffusion suppressing agent (F), the following F1 to F4 were used.
F1: adekastab LA63-P (manufactured by ADEKA Corporation)
F2: triamylamine
F3: 4-hydroxy-1,2,2,6,6-pentamethylpiperidine
F4: 2,6-diphenylpyridine

The acid generating agent (A), the resin (B), the alkali-soluble resin (D), and the acid diffusion suppressing agent (F), each in the amount and type described in Tables 1 to 3; 0.05 parts by mass of E1 (sulfur-containing compound (E)); 0.35 parts by mass of tri-n-octyl borate (Lewis acid compound (C)); and 0.05 parts by mass of a surfactant (BYK310, manufactured by BYK-Chemie) were solved in a mixed solvent of 3-methoxybutyl acetate (MA) and propylene glycol monomethyl ether acetate (PM) (MA/PM=6/4 (volume ratio)) so that the solid content concentration was 40% by mass to obtain photosensitive compositions of Examples and Comparative Examples.

With regard to each of the photosensitive compositions of the Examples and the Comparative Examples, it was confirmed whether or not the requirement 1 described above was satisfied. Specific methods are described below.

First, a photosensitive composition (chemically amplified positive-type photosensitive composition) was applied to a substrate (copper substrate) having a copper layer formed on a surface thereof by a sputtering method to form a resin film having a thickness of 8.5 μm (step 1). The substrate having the resin film formed was heated at 140° C. for 300 seconds (Step 2). A part of the heated resin film was scraped off, the scraped off resin film was dissolved in propylene glycol monomethyl ether acetate (PM) so as to have a solid content concentration of 20% by mass, then, acetonitrile having a mass 15 times the mass of the scraped off resin film was added, and a solution obtained by removing a precipitate was determined as a test liquid 1 (step 3). Further, the photosensitive composition (chemically amplified positive-type photosensitive composition) was diluted with propylene glycol monomethyl ether acetate (PM) so that the solid content concentration was 20% by mass, then, acetonitrile having a mass 15 times the mass of the solid content of the photosensitive composition (chemically amplified positive-type photosensitive composition) was added, and a solution obtained by removing a precipitate was determined as a test liquid 2. The test liquid 2 and the test liquid 1 obtained in step 3 were analyzed by liquid chromatography and a decomposition ratio (%) of the acid generating agent (A) represented by the following formula (a) was determined (step 4). Quantification of the acid generating agent (A) by liquid chromatography was performed by an external standard method using the acid generating agent (A) in each photosensitive composition as a standard substance.

$$decomposition ratio ( \% ) of acid generating agent ( A ) = ( 1 - ( x / y ) ) \times 100 \qquad ( a )$$

(in the formula (a), x is a content (mass %) of the acid generating agent (A) in the resin film and is obtained from the analysis result of the test liquid 1; and y is a content (mass %) of the acid generating agent (A) in the solid content of the photosensitive composition (chemically amplified positive-type photosensitive composition) and is obtained from the analysis result of the test liquid 2). The determined decomposition ratios (%) of the acid generating agent (A) represented by the formula (a) are shown in the column of “acid generating agent decomposition ratio (%)” in Tables 1 to 3.

### [Evaluation of Shape] Evaluation of Undercut and Footing of Resist Pattern Cross Section

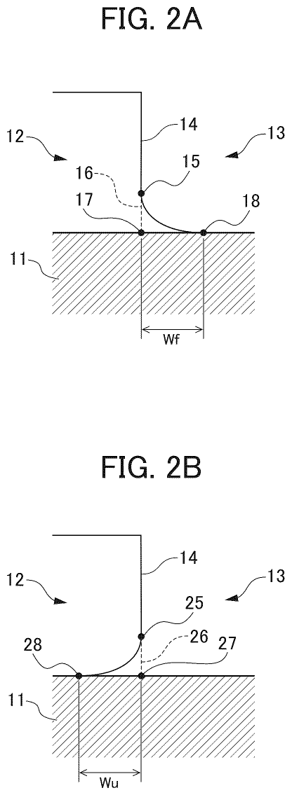

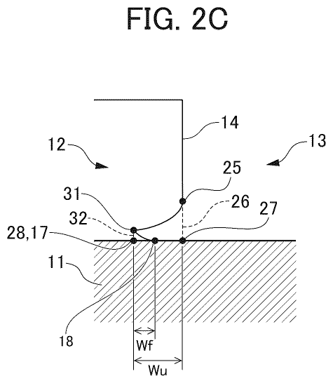

Each of the photosensitive compositions of the Examples and the Comparative Examples was applied on an 8-inch diameter copper substrate (substrate having a copper layer formed on a surface thereof by sputtering) to form a photosensitive layer having a thickness of 8.5 μm. Next, the photosensitive layer was pre-baked at 140° C. for 300 seconds. After the pre-baking, using a mask having a line-and-space pattern with a line width of 2 μm and a space width of 2 μm and an exposure device NSR-2205i14E (manufactured by Nikon Corporation, NA=0.50, o=0.64) were used to perform pattern exposure with an i-line (wavelength: 365 nm). An exposure amount was set so that a pattern width (a width of the resist portion) Wm of the intermediate portion in the thickness direction of the substrate in the resist pattern cross section was 2 μm. Then, the substrate was placed on a hot plate and was subjected to post-exposure bake (PEB) at 90° C. for 90 seconds. Thereafter, an aqueous 2.38% by weight solution of tetramethylammonium hydroxide (developing solution, NMD-3, manufactured by Tokyo Ohka Kogyo Co., Ltd.) was added dropwise to the exposed photosensitive composition layer, and then the substrate was allowed to stand at 23° C. for 30 seconds. This operation was repeated two times in total. Subsequently, the surface of the resist pattern was washed with running water, and then blown with nitrogen to obtain a resist pattern. The cross-sectional shape of this resist pattern obtained was observed under a scanning electron microscope to evaluate the undercut and the footing of the resist pattern. FIGS. 2A to 2C are view schematically showing a cross section parallel to the thickness direction of the substrate, with regard to the resist pattern of which footing and undercut were observed with a scanning electron microscope in the Examples and the Comparative Examples.

### <Footing Evaluation>

The cross-sectional shape of the obtained resist pattern was observed with a scanning electron microscope, and a footing amount was measured as follows. In FIG. 2A, a resist pattern having a resist portion 12 and a nonresist portion 13 was formed on a substrate 11. Firstly, on a side wall 14 which was an interface between the resist portion 12 and the nonresist portion 13, a inflection point 15 at which footing started on the side wall 14 was determined. A perpendicular line 16 was drawn down from the inflection point 15 to a surface of the substrate 11, and an intersection of the perpendicular line 16 with the surface of the substrate 11 was determined as a footing starting point 17. Furthermore, an intersection of a curve on the side wall 14 with the surface of the substrate 11 was determined as a footing end point 18. A width Wf between the thus-determined footing starting point 17 and footing end point 18 was determined as the footing amount. The footing amount was a value measured for any one of side walls 14 in any one of nonresist portions in the resist pattern. From the value of the thus-determined footing amount, a degree of the footing was evaluated according to the following criteria.

### <Undercut Evaluation>

The cross-sectional shape of the obtained resist pattern was observed with a scanning electron microscope, and an undercut amount was measured as follows. In FIG. 2B, a resist pattern including a resist portion 12 and a nonresist portion 13 was formed on a substrate 11. First, a inflection point 25 at which the undercut started on a side wall 14 was determined on the side wall 14 which was the interface between the resist portion 12 and the nonresist portion 13. A perpendicular line 26 was drawn down from the inflection point 25 to a surface of the substrate 11, and an intersection of the perpendicular line 26 with the surface of the substrate 11 was determined as a undercut starting point 27. Furthermore, an intersection of a curve on the side wall 14 with the surface of the substrate 11 was determined as an undercut end point 28. A width Wu between the thus-determined undercut starting point 27 and undercut end point 28 was determined as the undercut amount. From the value of the thus-determined undercut amount, a degree of the undercut was evaluated according to the following criteria.

In the evaluation of footing and undercut, as shown in FIG. 2C, when the resist pattern had undercut and footing, a point at which the nonresist portion 13 extends into the inside of the resist portion 12 most was determined as a point 31 at which the undercut ended and footing started. A perpendicular line 32 was drawn from the point 31 toward the surface of the substrate 11, and an intersection point of the perpendicular line 32 with the surface of the substrate 11 was determined as an undercut end point 28 and a footing starting point 17.

### <Evaluation Criteria>

A case where the undercut amount Wu (an extension amount of the resist pattern on the substrate surface side) was more than 0.25 μm was determined as o, a case where the undercut amount Wu was 0.20 μm or more and 0.25 μm or less was determined as O, and a case where the undercut amount Wu was less than 0.20 μm was determined as X. In addition, a case where the footing amount Wf (an amount of protrusion of the resist pattern to the nonresist portion on the substrate surface) was less than 0.01 μm was determined as o, a case where the footing amount Wf was 0.01 μm or more and 0.02 μm or less was determined as O, and a case where the footing amount Wf was more than 0.02 μm was determined as X.

TABLE 1

| | | | | Acid | | | |
|---|---|---|---|---|---|---|---|
| | | Alkali- | Acid | diffusion | Acid | | |
| | | soluble | generating | suppressing | generating | | |
| | Resin (B) | resin (D) | agent (A) | agent (F) | agent | | |
| | Type/part(s) | Type/part(s) | Type/part(s) | Type/part(s) | decomposition | Shape evaluation | |
| | by mass | by mass | by mass | by mass | ratio (%) | Undercut | Footing |
| Example 1 | B1/50 | D1/20 | A1/1 | F1/0.3 | 4 | ⊙ | ⊙ |
| Example 2 | | D2/30 | A2/1 | | 8 | ⊙ | ⊙ |
| Example 3 | | | A3/1 | | 5 | ⊙ | ⊙ |
| Example 4 | | | A4/1 | | 7 | ⊙ | ⊙ |
| Example 5 | | | A5/1 | | 4 | ⊙ | ⊙ |
| Example 6 | | | A6/1 | | 1 | ◯ | ⊙ |
| Example 7 | | | A7/1 | | 8 | ⊙ | ⊙ |
| Example 8 | | | A8/1 | | 5 | ⊙ | ⊙ |
| Example 9 | | | A9/1 | | 7 | ⊙ | ⊙ |
| Example 10 | | | A7/0.5 | | 4 | ⊙ | ⊙ |
| | | | A10/1 | | | | |
| Example 11 | | | A6/1 | | 5 | ⊙ | ⊙ |
| | | | A11/0.1 | | | | |
| Example 12 | B1/50 | D1/20 | A1/1 | F1/0.3 | 9 | ⊙ | ◯ |
| | | D2/30 | | | | | |
| Example 13 | B1/50 | D1/20 | A1/1 | F3/0.3 | 7 | ⊙ | ⊙ |
| | | D2/30 | | | | | |
| Example 14 | B1/60 | D1/20 | | F1/0.3 | 4 | ⊙ | ⊙ |
| | | D2/20 | | | | | |
| Example 15 | B1/40 | D1/20 | | | 4 | ⊙ | ⊙ |
| | | D2/40 | | | | | |
| Example 16 | B1/50 | D2/30 | | | 4 | ◯ | ◯ |
| | B12/20 | | | | | | |
| Example 17 | B2/50 | D1/20 | | | 4 | ⊙ | ⊙ |
| Example 18 | B3/50 | D2/30 | | | 4 | ⊙ | ⊙ |
| Example 19 | B4/50 | | | | 4 | ⊙ | ⊙ |
| Example 20 | B5/50 | | | | 4 | ◯ | ⊙ |
| Example 21 | B6/50 | | | | 4 | ⊙ | ⊙ |
| Example 22 | B7/50 | | | | 4 | ⊙ | ⊙ |
| Example 23 | B8/50 | | | | 4 | ⊙ | ⊙ |

TABLE 2

| | | | | Acid | | | |
|---|---|---|---|---|---|---|---|
| | | Alkali- | Acid | diffusion | Acid | | |
| | | soluble | generating | suppressing | generating | | |
| | Resin (B) | resin (D) | agent (A) | agent (F) | agent | | |
| | Type/part(s) | Type/part(s) | Type/part(s) | Type/part(s) | decomposition | Shape evaluation | |
| | by mass | by mass | by mass | by mass | ratio (%) | Undercut | Footing |
| Example 24 | B2/90 | D1/10 | A1/1 | F1/0.3 | 4 | ⊙ | ⊙ |
| Example 25 | B2/80 | D1/20 | | | 4 | ⊙ | ⊙ |
| Example 26 | B2/75 | — | | | 4 | ◯ | ◯ |
| | B12/25 | | | | | | |
| Example 27 | B2/75 | — | | | 4 | ◯ | ◯ |
| | B13/25 | | | | | | |
| Example 28 | B2/60 | D1/20 | | | 4 | ◯ | ◯ |
| | B12/20 | | | | | | |
| Example 29 | B2/55 | — | | | 4 | ◯ | ◯ |
| | B12/45 | | | | | | |
| Example 30 | B1/50 | D2/45 | | | 4 | ⊙ | ⊙ |
| | | D3/5 | | | | | |
| Example 31 | B1/50 | D2/40 | | | 4 | ⊙ | ⊙ |
| | | D3/10 | | | | | |
| Example 32 | B1/50 | D2/40 | | | 4 | ⊙ | ⊙ |
| | | D4/10 | | | | | |
| Example 33 | B1/50 | D2/30 | | | 4 | ⊙ | ⊙ |
| | | D3/20 | | | | | |
| Example 34 | B1/50 | D2/30 | | | 4 | ◯ | ◯ |
| | B12/10 | D3/10 | | | | | |

TABLE 3

| | | | | Acid | | | |
|---|---|---|---|---|---|---|---|
| | | Alkali- | Acid | diffusion | Acid | | |
| | | soluble | generating | suppressing | generating | | |
| | Resin (B) | resin (D) | agent (A) | agent (F) | agent | | |
| | Type/part(s) | Type/part(s) | Type/part(s) | Type/part(s) | decomposition | Shape evaluation | |
| | by mass | by mass | by mass | by mass | ratio (%) | Undercut | Footing |
| Comparative | B9/50 | D1/20 | A10/1 | F1/0.3 | 0 | X | X |
| Example 1 | | D2/30 | | | | | |
| Comparative | B10/50 | | | | 0 | X | X |
| Example 2 | | | | | | | |
| Comparative | B11/50 | | | | 0 | X | X |
| Example 3 | | | | | | | |
| Comparative | B1/50 | | | | 0 | X | ⊙ |
| Example 4 | | | | | | | |
| Comparative | B2/50 | | | | 0 | X | ⊙ |
| Example 5 | | | | | | | |
| Comparative | B3/50 | | | | 0 | X | ⊙ |
| Example 6 | | | | | | | |
| Comparative | B4/50 | | | | 0 | X | ⊙ |
| Example 7 | | | | | | | |
| Comparative | B5/50 | | | | 0 | X | ◯ |
| Example 8 | | | | | | | |
| Comparative | B6/50 | | | | 0 | X | ⊙ |
| Example 9 | | | | | | | |
| Comparative | B7/50 | | | | 0 | X | ⊙ |
| Example 10 | | | | | | | |
| Comparative | B8/50 | | | | 0 | X | ⊙ |
| Example 11 | | | | | | | |
| Comparative | B1/50 | | A2/1 | F4/0.3 | 0 | X | ◯ |
| Example 12 | | | | | | | |
| Comparative | | | A11/1 | | 20 | Detachment | Detachment |
| Example 13 | | | | | | | |
| Comparative | | | A10/0.4 | | 12 | Detachment | Detachment |
| Example 14 | | | A11/0.6 | | | | |
| Comparative | | | A1/0.1 | | 0.5 | X | ◯ |
| Example 15 | | | A10/1 | | | | |
| Comparative | B9/50 | | A1/1 | F1/0.3 | 4 | ◯ | X |
| Example 16 | | | | | | | |

According to Examples 1 to 34, it can be seen that a photosensitive composition including the acid generating agent (A) that generates an acid by irradiation with an active ray or radiation, the resin (B) having an alkali solubility that increases under action of an acid, the sulfur-containing compound (E) containing a sulfur atom capable of coordinating with a metal layer of a substrate, the acid diffusion suppressing agent (F), and the organic solvent(S), with the resin (B) comprising an acrylic resin (B3) containing the specific constituent unit (B3-1), with the photosensitive composition satisfying the the requirement 1 (that is, the decomposition ratio (%) of the acid generating agent (A) determined by the steps 1 to 5 is more than 0.5 and less than 10), could form, on a substrate having a metal layer on a surface thereof, a resist pattern having a cross-sectional shape in which a large undercut was formed and footing was suppressed.

On the other hand, according to Comparative Examples 1 to 16, it can be seen that a photosensitive composition that did not satisfy the requirement 1 or a photosensitive composition that did not include the acrylic resin (B3) containing the specific constituent unit (B3-1) as the resin (B) could not form a resist pattern having a cross-sectional shape in which a large undercut was formed and footing was suppressed. In Comparative Examples 13 and 14 where the photosensitive composition having the decomposition ratio (%) of the acid generating agent of the requirement 1 of more than 10 was used, probably because the alkali solubility of the acrylic resin (B3) in the vicinity of the substrate surface in the unexposed portion was too high, the resist pattern was detached off from the substrate during development, and a resist pattern having a cross-sectional shape in which a large undercut was formed and footing was suppressed could not be formed on a substrate having a metal layer on a surface thereof.

1. A chemically amplified positive-type photosensitive composition for forming a pattern serving as a template for a process of forming a plated article on a substrate having a metal layer on a surface thereof, the composition comprising:
an acid generating agent (A) that generates an acid by irradiation with an active ray or radiation;
a resin (B) having an alkali solubility that increases under action of an acid;
a sulfur-containing compound (E) containing a sulfur atom capable of coordinating with the metal layer;
an acid diffusion suppressing agent (F); and
an organic solvent(S),
wherein the resin (B) comprises an acrylic resin (B3); and
the acrylic resin (B3) comprises a constituent unit (B3-1) derived from an acid dissociable (meth)acrylic acid alicyclic ester;
wherein in the acid dissociable (meth)acrylic acid alicyclic ester, the alicyclic group comprises a tertiary carbon atom as a ring constituent element, and the tertiary carbon atom of the alicyclic group is bonded to an oxygen atom other than carbonyl oxygen in an ester group in the acid dissociable (meth)acrylic acid alicyclic ester to form a C—O bond; and
the following requirement 1 is satisfied:
[Requirement 1]
a decomposition ratio (%) of the acid generating agent (A) determined by the following steps 1) to 4) is more than 0.5 and less than 10:
1) a resin film having a thickness of 8.5 μm is formed by applying the chemically amplified positive-type photosensitive composition to a substrate having a copper layer formed on a surface thereof by sputtering;
2) the substrate having the resin film formed thereon is heated at 140° C. for 300 seconds;
3) a part of the resin film after the heating is scraped off, the scraped off resin film is dissolved in propylene glycol monomethyl ether acetate (PM) so as to have a solid content concentration of 20% by mass, then acetonitrile having a mass 15 times the mass of the scraped off resin film is added, and a solution obtained by removing a precipitate is used as a test liquid; and
4) the chemically amplified positive-type photosensitive composition is diluted with propylene glycol monomethyl ether acetate (PM) so as to have a solid content concentration of 20% by mass, then acetonitrile having a mass 15 times the mass of the solid content of the chemically amplified positive-type photosensitive composition is added, and a solution is obtained by removing a precipitate; the resulting solution and the test liquid are each analyzed by liquid chromatography to determine the decomposition ratio (%) of the acid generating agent (A) represented by the following formula (a):
decomposition ratio (%) of acid generating agent (A)=(1−(x/y))×100 (a)
(in the formula (a), x is a content (% by mass) of the acid generating agent (A) in the resin film, and
y is a content (% by mass) of the acid generating agent (A) in the solid content of the chemically amplified positive-type photosensitive composition).

2. The chemically amplified positive-type photosensitive composition according to claim 1, wherein the constituent unit derived from the acid dissociable (meth)acrylic acid alicyclic ester comprises a constituent unit represented by the following formula (b3-1): 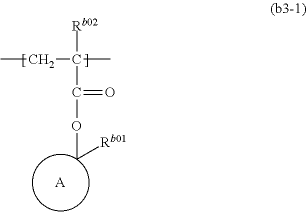
wherein ring A is a saturated aliphatic hydrocarbon ring, R^{b01} is an alkyl group having 1 to 12 carbon atoms or an arylalkyl group having 7 to 15 carbon atoms, and R^{b02} is a hydrogen atom or a methyl group).

3. A method of manufacturing a substrate with a template, the method comprising:
laminating a photosensitive layer comprising the chemically amplified positive-type photosensitive composition according to claim 1 on the substrate having a metal layer on a surface thereof:
heating the photosensitive layer;
irradiating the heated photosensitive layer position-selectively with an active ray or radiation; and
developing the photosensitive layer after the irradiation to form a template having a pattern shape for forming a plated article.

4. A method of manufacturing a plated article, comprising plating a substrate with the template produced according to claim 3 to form a plated article in the template.
